(19) United States
(12) Patent Application Publication
(10) Pub. No.: US 2024/0004288 A1
(43) Pub. Date: Jan. 4, 2024

(54) RADIATION-SENSITIVE RESIN COMPOSITION AND METHOD FOR FORMING PATTERN

(71) Applicant: JSR CORPORATION, Tokyo (JP)

(72) Inventor: Ken MARUYAMA, Tokyo (JP)

(73) Assignee: JSR CORPORATION, Tokyo (JP)

(21) Appl. No.: 18/025,989

(22) PCT Filed: Aug. 3, 2021
(86) PCT No.: PCT/JP2021/028755

§ 371 Date: Mar. 13, 2023

(30) Foreign Application Priority Data
Sep. 28, 2020 (JP) 2020-162155
Feb. 2, 2021 (JP) 2021-015280

(51) Int. Cl. G03F 7/004; C08F 220/18; C08F 220/28; G03F 7/039; G03F 7/038

(52) U.S. Cl. CPC G03F 7/0045; C08F 220/1807; C08F 220/1806; G03F 7/038; C08F 220/283; C08F 220/1802; G03F 7/039; C08F 220/1809

(57) ABSTRACT

Provided is a radiation-sensitive resin composition capable of exhibiting sensitivity and CDU performance at a sufficient level when a next-generation technology is applied, and a method for forming a pattern. A radiation-sensitive resin composition contains one or two or more onium salts containing an organic acid anion moiety and an onium cation moiety, a compound having a structure in which an alkoxycarbonyl group is bonded to a nitrogen atom, and a solvent, wherein at least part of the organic acid anion moiety in the onium salt contains an iodine-substituted aromatic ring structure, and at least part of the onium cation moiety contains a fluorine-substituted aromatic ring structure.

### BACKGROUND OF THE INVENTION

### Field of the Invention

The present invention relates to a radiation-sensitive resin composition and a method for forming a pattern.

### Description of the Related Art

A photolithography technology using a resist composition has been used for the fine circuit formation in a semiconductor device. As the representative procedure, for example, a resist pattern is formed on a substrate by generating an acid by irradiating the coating of the resist composition with a radioactive ray through a mask pattern, and then reacting in the presence of the acid as a catalyst to generate the difference of solubility of a resin into an alkaline or organic developer between an exposed part and a non-exposed part.

In the photolithography technology, pattern miniaturization is promoted by using short-wavelength radiation, such as ArF excimer laser or by combining such radiation with an immersion exposure method (liquid immersion lithography). As a next-generation technology, further short-wavelength radiation, such as an electron beam, an X-ray, and an extreme ultraviolet ray (EUV) is being utilized, and a resist material containing an acid generator with a benzene ring having enhanced radiation absorption efficiency is also being studied. (Patent Document 1)

### PRIOR ART DOCUMENT

### Patent Document

Patent Document 1: JP-A-2018-5224

### SUMMARY OF THE INVENTION

### Problems to be Solved by the Invention

Even in the above-described next generation technology, various resist performances equivalent to or higher than conventional performances are required in sensitivity and critical dimension uniformity (CDU) performance, which is an index of uniformity of a line width and a hole diameter, and the like.

An object of the present invention is to provide a radiation-sensitive resin composition capable of exhibiting sensitivity and CDU performance at a sufficient level when a next-generation technology is applied, and a method for forming a pattern.

### Means for Solving the Problems

As a result of intensive studies to solve the present problems, the present inventors have found that the above object can be achieved by adopting the following configurations, and have accomplished the present invention.

The present invention relates, in one embodiment, to a radiation-sensitive resin composition containing:
one or two or more onium salts containing an organic acid anion moiety and an onium cation moiety;
a compound having a structure in which an alkoxycarbonyl group is bonded to a nitrogen atom; and
a solvent;
wherein at least part of the organic acid anion moiety in the onium salt contains an iodine-substituted aromatic ring structure, and at least part of the onium cation moiety contains a fluorine-substituted aromatic ring structure.

With the radiation-sensitive resin composition, a resist film satisfying sensitivity and CDU performance can be constructed. The reason for this is not clear, but can be expected as follows. Absorption of radiation such as EUV having a wavelength of 13.5 nm by iodine atoms or fluorine atoms is very large, and this makes the radiation-sensitive resin composition highly sensitive. The iodine-substituted aromatic ring structure contained in at least part of the organic acid anion moiety in the onium salt can reduce acid diffusion owing to the largeness of the molecular weight of the iodine atom. Furthermore, the compound having a structure in which an alkoxycarbonyl group is bonded to a nitrogen atom exerts an appropriate quencher function and can control the acid diffusion. It is presumed that the resist performance can be exhibited by the combination of these actions.

The present invention relates, in another embodiment, to a method for forming a pattern, including:
directly or indirectly applying the radiation-sensitive resin composition to a substrate to form a resist film;
exposing the resist film to light; and
developing the exposed resist film with a developer.

Since the above-described radiation-sensitive resin composition superior in sensitivity and CDU performance is used in the method for forming a pattern, a high-quality resist pattern can efficiently be formed by the method.

### MODE FOR CARRYING OUT THE INVENTION

Hereinbelow, embodiments of the present invention will specifically be described, but the present invention is not limited to these embodiments.

### <<Radiation-Sensitive Resin Composition>>

The radiation-sensitive resin composition (hereinafter also simply referred to as “composition”) according to the present embodiment contains one or two or more prescribed onium salts, and further contains a compound and a solvent. In addition, the composition contains a resin, as necessary. The composition may further contain other optional components as long as the effects of the present invention are not impaired. When the radiation-sensitive resin composition contains the prescribed onium salt and compound, the radiation-sensitive resin composition can be provided with high levels of sensitivity and CDU performance to a resulting resist film.

### <Onium Salt>

The onium salt is a component that contains an organic acid anion moiety and an onium cation moiety and generates an acid through exposure to light. When at least part of the organic acid anion moiety in the onium salt contains an iodine-substituted aromatic ring structure and at least part of the onium cation moiety in the onium salt contains a fluorine-substituted aromatic ring structure, it is possible to achieve increased sensitivity due to improvement in acid generation efficiency and exhibition of CDU performance due to acid diffusion controllability.

While the mode of incorporation of the onium salt in the radiation-sensitive resin composition is not particularly limited, the onium salt is at least one selected from the group consisting of a radiation-sensitive acid generating resin containing a structural unit having the organic acid anion moiety and the onium cation moiety, a radiation-sensitive acid generator containing the organic acid anion moiety and the onium cation moiety, and an acid diffusion controlling agent containing the organic acid anion moiety and the onium cation moiety and being to generate an acid having a pKa higher than that of an acid to be generated from the radiation-sensitive acid generator through irradiation with radiation. Differences between these functions will be described below.

The acid generated through the exposure to the onium salt is considered to have two functions in the radiation-sensitive resin composition depending on the strength of the acid. Examples of the first function include a function that causes the acid generated through the exposure to dissociate an acid-dissociable group of a structural unit when the resin contains the structural unit having the acid-dissociable group, to generate a carboxy group or the like. An onium salt having the first function is referred to as a radiation-sensitive acid generator. Examples of the second function include a function that controls, by salt exchange, the diffusion of the acid generated from the radiation-sensitive acid generator in the unexposed area without substantially dissociating the acid-dissociable group of the resin under a pattern formation condition using the radiation-sensitive resin composition. An onium salt having the second function is referred to as an acid diffusion controlling agent. The acid generated from the acid diffusion controlling agent can be said to be an acid relatively weaker (acid having a higher pKa) than the acid to be generated from the radiation-sensitive acid generator. Whether an onium salt functions as a radiation-sensitive acid generator or an acid diffusion controlling agent depends on the energy required for dissociating the acid-dissociable group of the resin and the acidity of the onium salt. The mode of incorporation of the radiation-sensitive acid generator in the radiation-sensitive resin composition may be a mode in which the onium salt structure is present alone as a compound (released from a polymer), a mode in which the onium salt structure is incorporated as a part of a polymer, or both of these modes. A form in which an onium salt structure is incorporated as a part of a polymer is particularly referred to as a radiation-sensitive acid generating resin.

When the radiation-sensitive resin composition contains the radiation-sensitive acid generator or a radiation-sensitive acid generating resin, the polarity of the resin in an exposed area increases, and as a result, when the developer is an aqueous alkaline solution, the resin in the exposed area is soluble in the developer, and on the other hand, when the developer is an organic solvent, the resin in the exposed area is hardly soluble in the developer.

When the radiation-sensitive resin composition contains the acid diffusion controlling agent, diffusion of an acid in an unexposed area can be controlled, and a resist pattern further superior in pattern developability and CDU performance can be formed.

In the radiation-sensitive resin composition, the organic acid anion moiety in at least one selected from the group consisting of the radiation-sensitive acid generating resin, the radiation-sensitive acid generator, and the acid diffusion controlling agent should contain the iodine-substituted aromatic ring structure. In addition, the onium cation moiety in at least one selected from the group consisting of the radiation-sensitive acid generating resin, the radiation-sensitive acid generator, and the acid diffusion controlling agent should contain the fluorine-substituted aromatic ring structure. Therefore, the iodine-substituted aromatic ring structure and the fluorine-substituted aromatic ring structure may be present in the same compound, or may be present in different compounds.

Even in any mode of incorporation of the onium salt, the organic acid anion moiety preferably has at least one type of anion selected from the group consisting of a sulfonate anion, a carboxylate anion, and a sulfonimide anion. The onium cation is preferably at least one selected from the group consisting of a sulfonium cation and an iodonium cation. When the onium salt has a combination of these structures, the above-described function can be efficiently exhibited.

Examples of the acid to be generated through the exposure include acids that generate sulfonic acid, carboxylic acid, and sulfonimide through exposure with correspondence to the organic acid anion.

Examples of an onium salt that affords a sulfonic acid through exposure include:
(1) a compound in which one or more fluorine atoms or fluorinated hydrocarbon groups are bonded to a carbon atom adjacent to a sulfonate anion, and
(2) a compound in which neither fluorine atom nor fluorinated hydrocarbon group is bonded to a carbon atom adjacent to a sulfonate anion.

Examples of an onium salt that affords a carboxylic acid through exposure include:
(3) a compound in which one or more fluorine atoms or fluorinated hydrocarbon groups are bonded to a carbon atom adjacent to a carboxylate anion, and
(4) a compound in which neither fluorine atom nor fluorinated hydrocarbon group is bonded to a carbon atom adjacent to a carboxylate anion.

Among them, as the radiation-sensitive acid generator or the radiation-sensitive acid generating resin, those corresponding to the above (1) are preferable. As the acid diffusion controlling agent, those corresponding to the above (2), (3), or (4) are preferable, and those corresponding to the above (2) or (4) are particularly preferable.

### <Radiation-Sensitive Acid Generating Resin>

The radiation-sensitive acid generating resin contains a structural unit having an organic acid anion moiety and an onium cation moiety. The radiation-sensitive acid generating resin preferably contains a structural unit represented by the following formula (a1) (hereinafter also referred to as “structural unit a1”) or a structural unit represented by the following formula (a2) (hereinafter also referred to as “structural unit a2”).

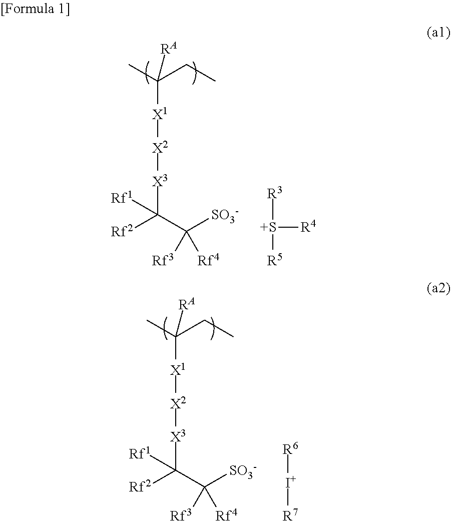

In the formulas, R^{A} is a hydrogen atom or a methyl group. X¹ is a single bond or an ester group. X² is a linear, branched or cyclic alkylene group having 1 to 12 carbon atoms, or an arylene group having 6 to 10 carbon atoms, or a combination thereof, and some of the methylene groups constituting the alkylene group may be replaced by an ether group, an ester group, or a lactone ring-containing group. X² contains an iodine-substituted aromatic ring structure. X³ is a single bond, an ether group, an ester group, or a linear, branched or cyclic alkylene group having 1 to 12 carbon atoms, and some of the methylene groups constituting the alkylene group may be replaced by an ether group or an ester group. Rf¹ to Rf⁴ are each independently a hydrogen atom, a fluorine atom, or a trifluoromethyl group, and at least one of Rf¹ to Rf⁴ is a fluorine atom or a fluorinated hydrocarbon group. R³ to R⁷ are each independently a monovalent hydrocarbon group having 1 to carbon atoms and optionally containing a heteroatom, and R³ and R⁴ may be bonded to each other to form a ring together with the sulfur atom to which they are bonded. At least one of R³ to R⁵ and at least one of R⁶ to R⁷ each contain a fluorine-substituted aromatic ring structure.

As the monovalent hydrocarbon group having 1 to 20 carbon atoms and optionally containing a heteroatom in R³ to R⁷, an alkyl group having 1 to 12 carbon atoms, a cycloalkyl group having 3 to 12 carbon atoms, or an aryl group having 6 to 20 carbon atoms is preferable, and some or all of the hydrogen atoms of these groups may be replaced by a hydroxy group, a carboxy group, a halogen atom, an oxo group, a cyano group, an amide group, a nitro group, a sultone group, a sulfone group, or a sulfonium salt-containing group, and some of the methylene groups constituting these groups may be replaced by an ether group, an ester group, a carbonyl group, a carbonate group, or a sulfonic acid ester group.

The structural unit a1 and the structural unit a2 are preferably represented by the following formulas (a1-1) and (a2-1), respectively.

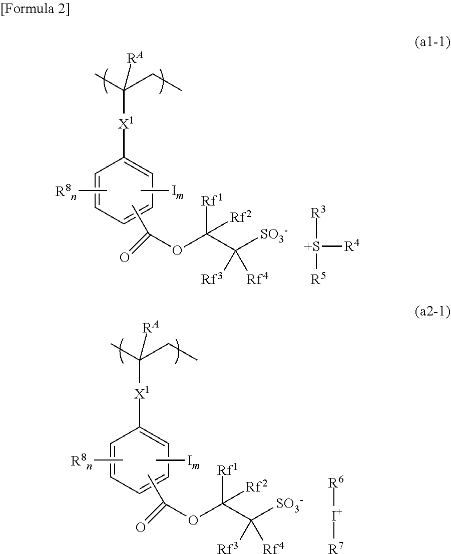

In the formulas, R^{A}, R³ to R⁷, Rf¹ to Rf⁴, and X¹ have the same meanings as the formula (a1) or (a2). R⁸ is a linear, branched or cyclic alkyl group having 1 to 4 carbon atoms, a halogen atom other than iodine, a hydroxy group, a linear, branched or cyclic alkoxy group having 1 to 4 carbon atoms, or a linear, branched or cyclic alkoxycarbonyl group having 2 to carbon atoms. m is an integer of 0 to 4 n is an integer of 0 to 3.

Examples of the organic acid anion moiety of the monomer that affords the structural unit a1 or the structural unit a2 include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in the formulas shown below are replaced by an atom or group other than an iodine atom such as a hydrogen atom or other substituent.

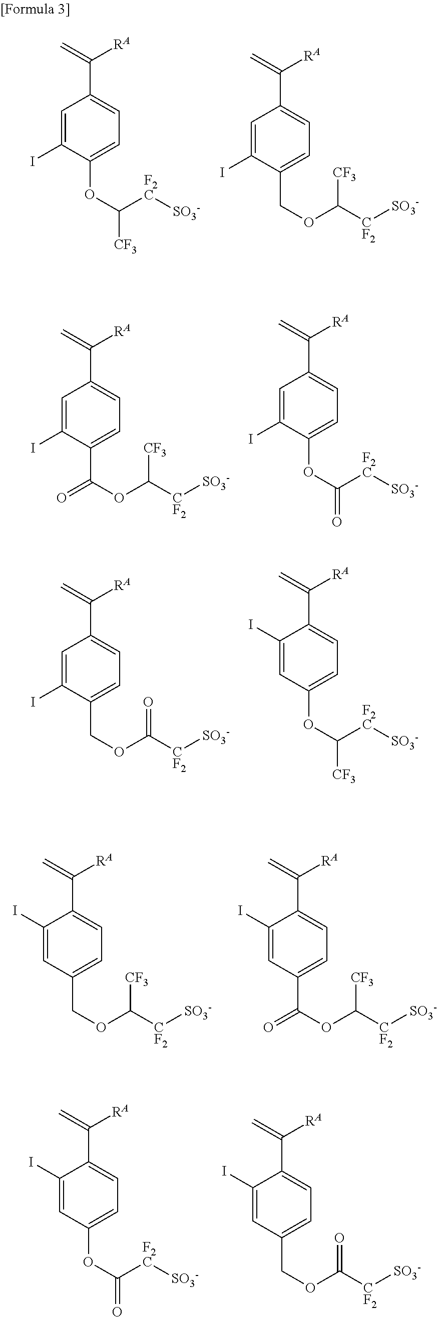

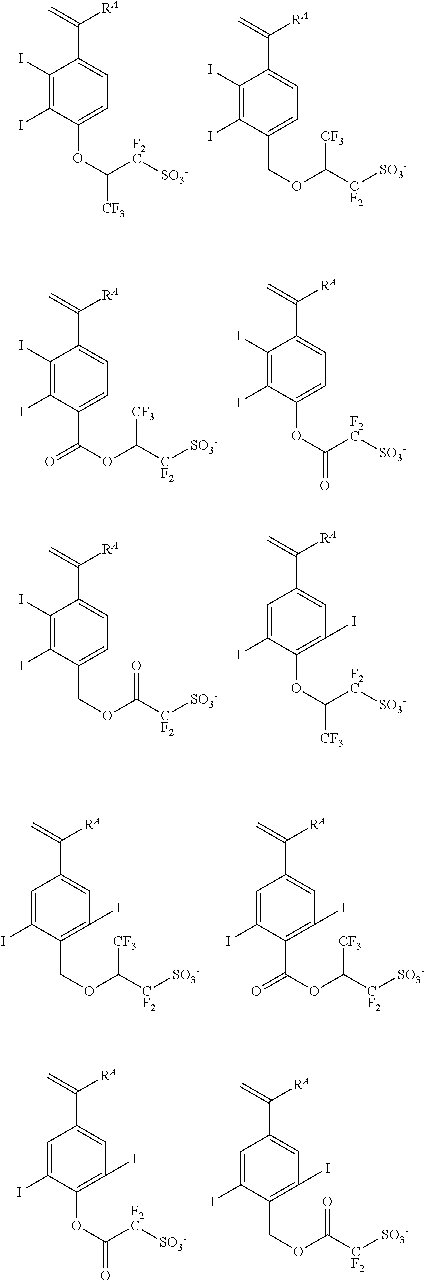

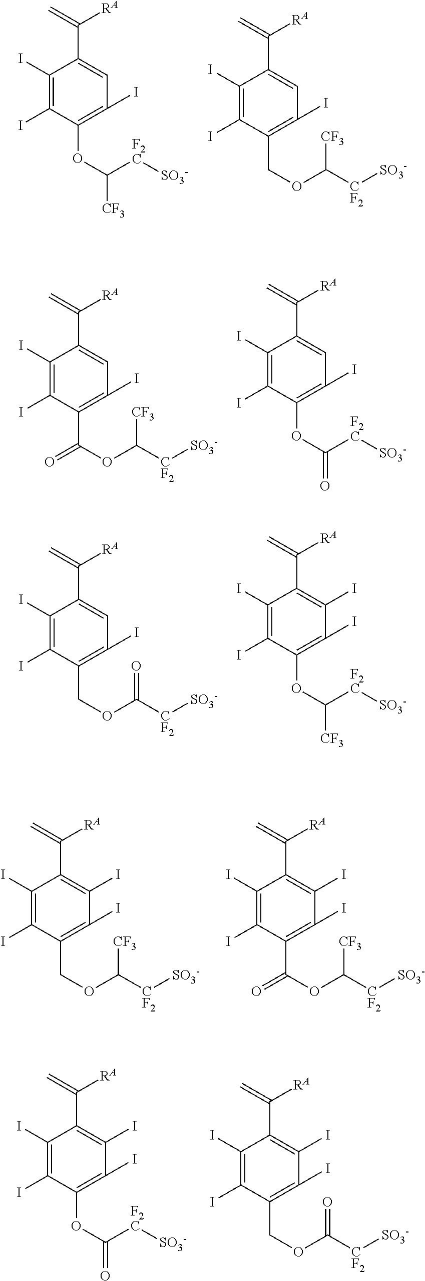

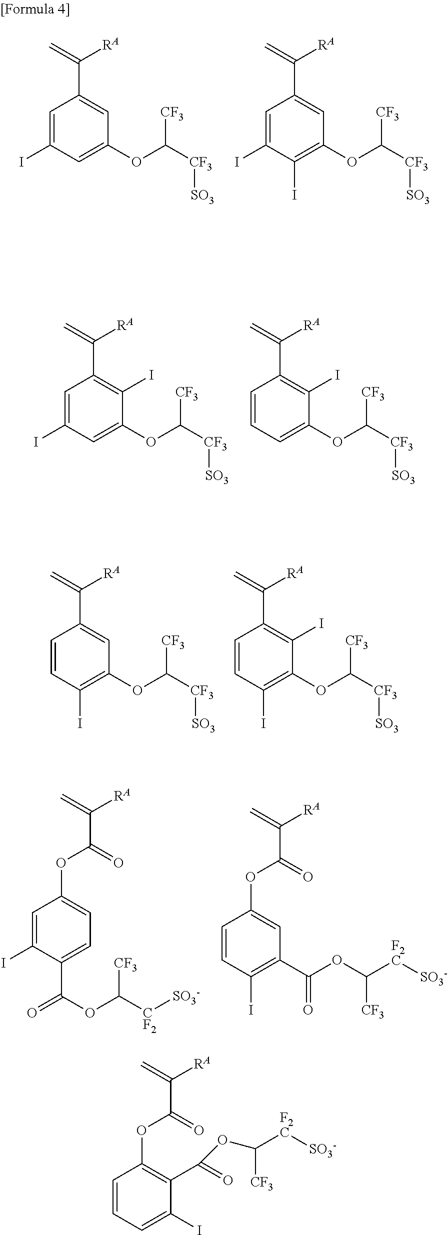

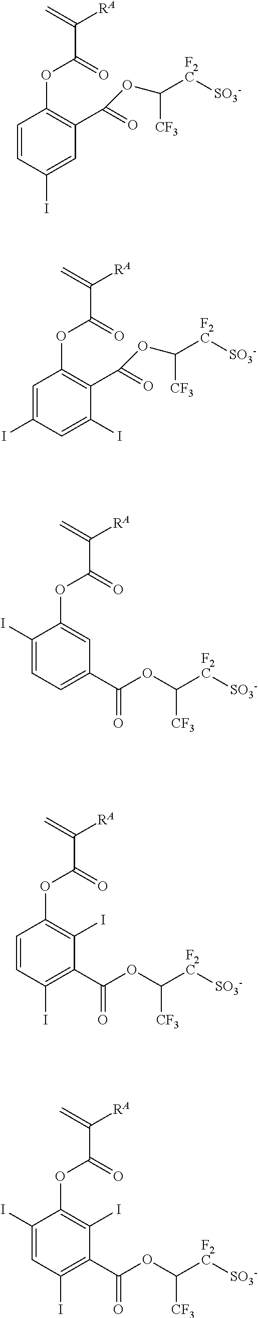

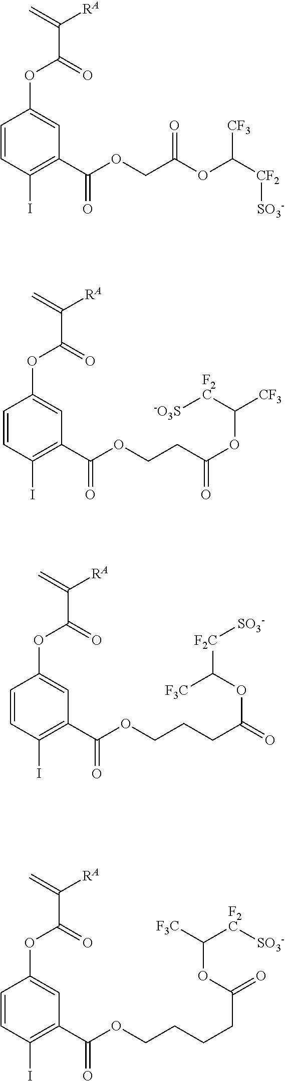

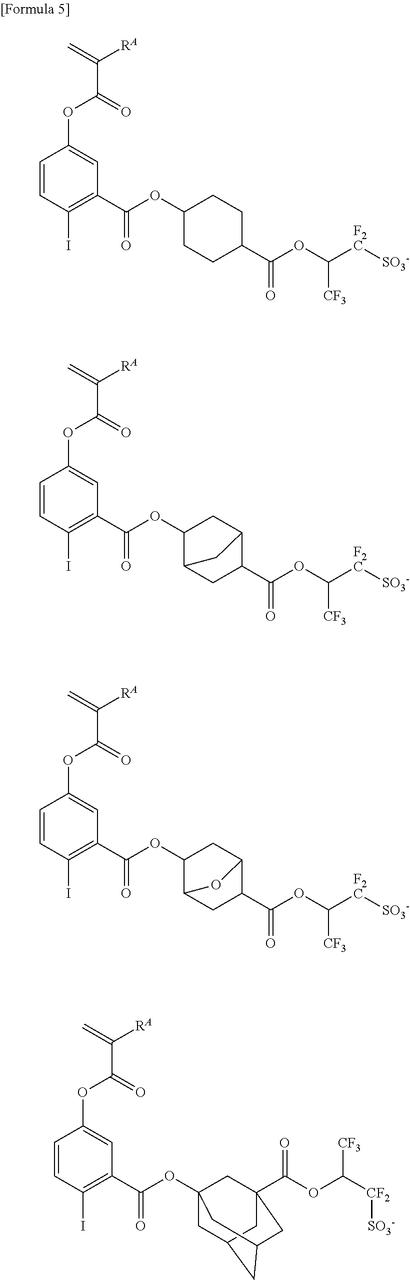

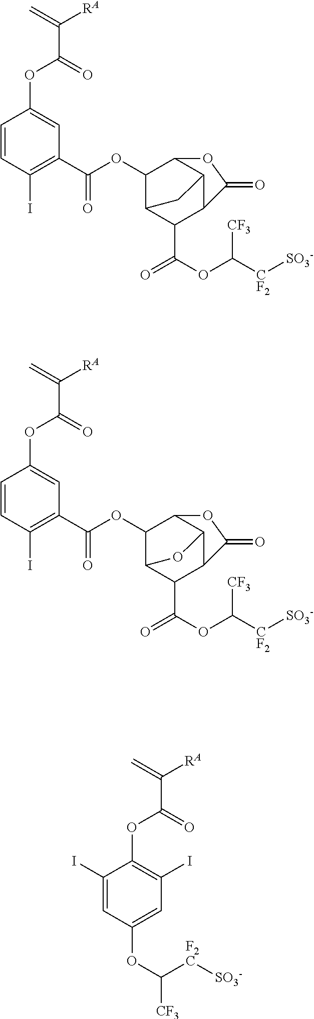

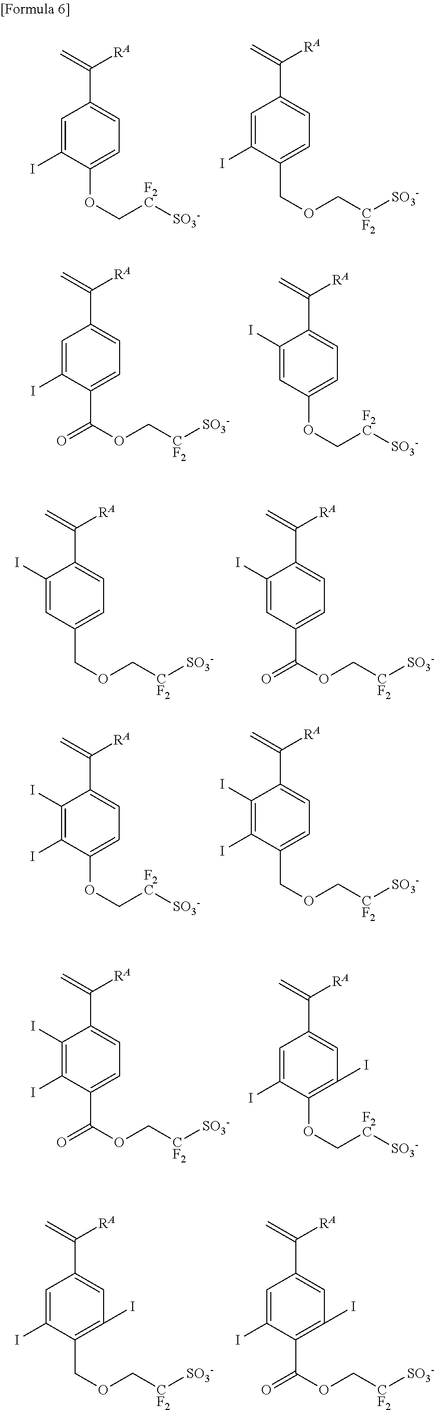

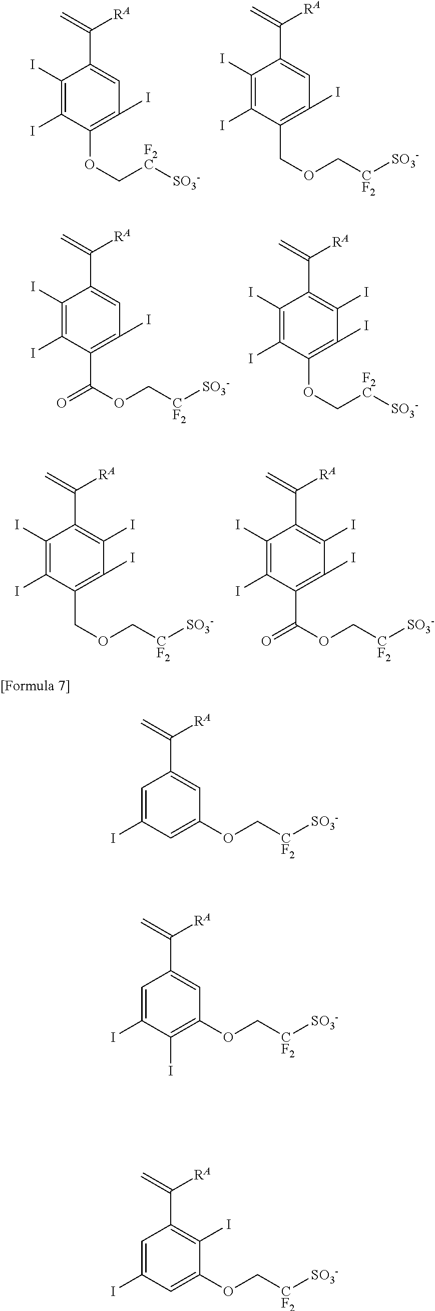

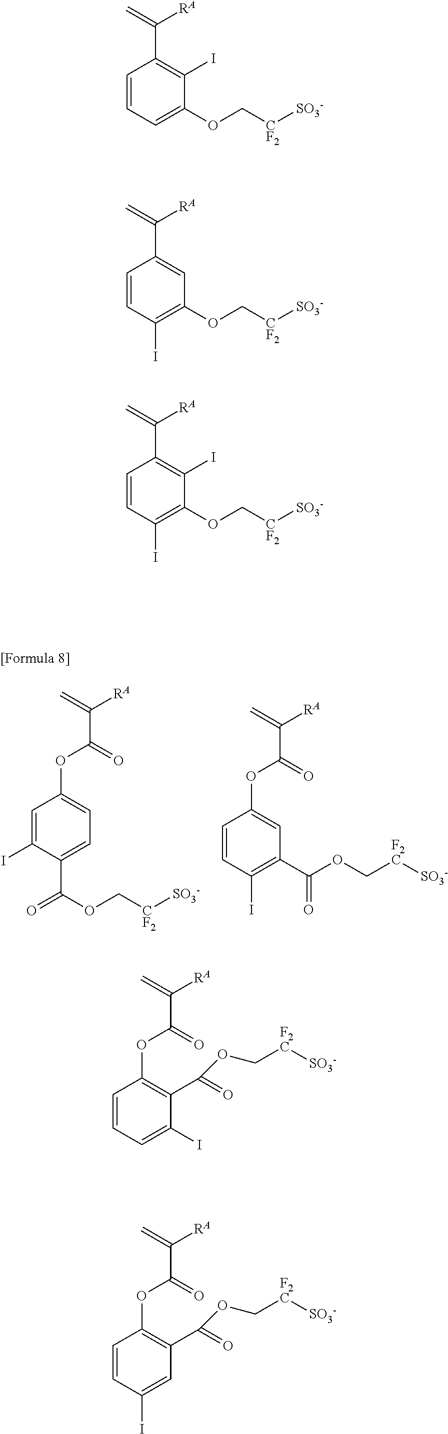

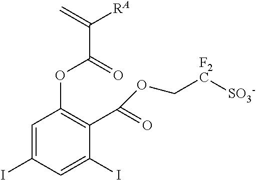

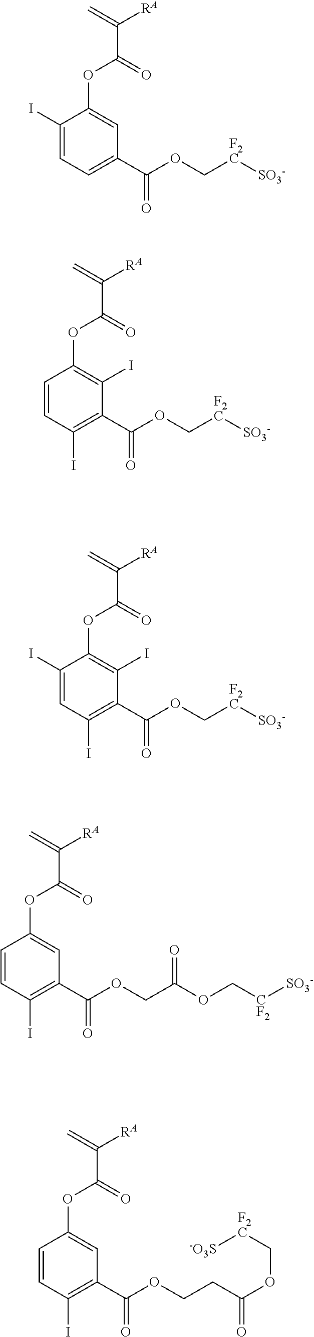

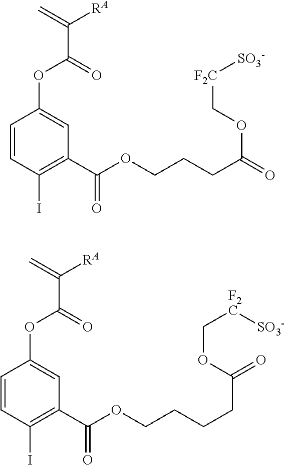

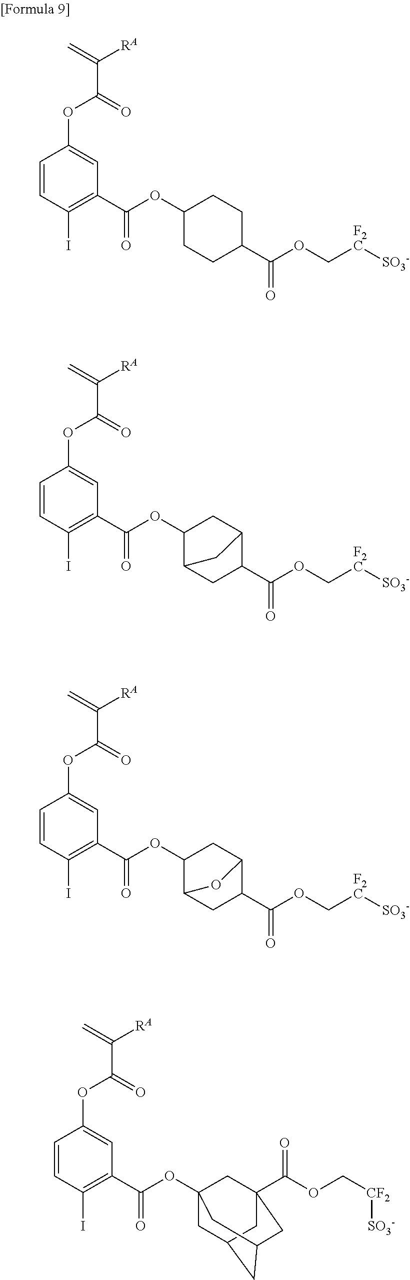

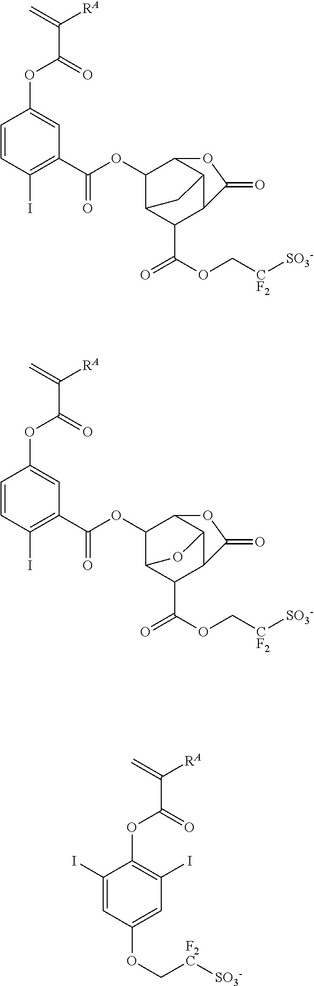

The onium cation moiety of the structural unit a1 is preferably represented by the following formula (Q-1).

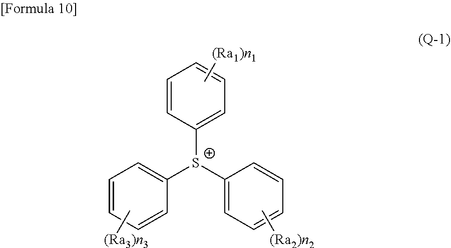

In the formula (Q-1), Ra1 and Ra2 each independently represent a substituent. n1 represents an integer of 0 to 5, and when n1 is 2 or more, the plurality of Ra1s may be the same or different. n2 represents an integer of 0 to 5, and when n2 is 2 or more, the plurality of Ra2s may be the same or different. n3 represents an integer of 0 to 5, and when n3 is 2 or more, the plurality of Ra3s may be the same or different. Ra3 represents a fluorine atom or a group having one or more fluorine atoms. Ra1 and Ra2 may be linked to each other to form a ring. When n1 is 2 or more, a plurality of Ra1's may be linked to each other to form a ring. When n2 is 2 or more, a plurality of Ra2's may be linked to each other to form a ring. When n1 is 1 or more and n2 is 1 or more, Ra1 and Ra2 may be linked to each other to form a ring (namely, a heterocyclic ring containing a sulfur atom).

The substituent represented by Ra1 and Ra2 is preferably an alkyl group, a cycloalkyl group, an alkoxy group, a cycloalkyloxy group, an alkoxycarbonyl group, an alkylsulfonyl group, a hydroxy group, a halogen atom, or a halogenated hydrocarbon group.

The alkyl group as Ra1 and Ra2 may be either a linear alkyl group or a branched alkyl group. The alkyl group is preferably one having 1 to 10 carbon atoms, and examples thereof include a methyl group, an ethyl group, a n-propyl group, an i-propyl group, a n-butyl group, a 2-methylpropyl group, a 1-methylpropyl group, a t-butyl group, a n-pentyl group, a neopentyl group, a n-hexyl group, a n-heptyl group, a n-octyl group, a 2-ethylhexyl group, a n-nonyl group, and a n-decyl group. Among them, a methyl group, an ethyl group, a n-butyl group, and a t-butyl group are particularly preferable.

Examples of the cycloalkyl group as Ra1 and Ra2 include monocyclic or polycyclic cycloalkyl groups (preferably cycloalkyl groups having 3 to 20 carbon atoms), and examples thereof include a cyclopropyl group, a cyclobutyl group, a cyclopentyl group, a cyclohexyl group, a cycloheptyl group, a cyclooctyl group, a cyclododecanyl group, a cyclopentenyl group, a cyclohexenyl group, and a cyclooctadienyl group. Among these, a cyclopropyl group, a cyclopentyl group, a cyclohexyl group, a cyclohexyl group, a cycloheptyl group, and a cyclooctyl group are particularly preferable.

Examples of the alkyl group moiety of the alkoxy group as Ra1 and Ra2 include those listed above as the alkyl group as Ra1 and Ra2. As the alkoxy group, a methoxy group, an ethoxy group, a n-propoxy group, and a n-butoxy group are particularly preferable.

Examples of the cycloalkyl group moiety of the cycloalkyloxy group as Ra1 and Ra2 include those listed above as the cycloalkyl group as Ra1 and Ra2. As the cycloalkyloxy group, a cyclopentyloxy group and a cyclohexyloxy group are particularly preferable.

Examples of the alkoxy group moiety of the alkoxycarbonyl group as Ra1 and Ra2 include those listed above as the alkoxy group as Ra1 and Ra2. As the alkoxycarbonyl group, a methoxycarbonyl group, an ethoxycarbonyl group, and a n-butoxycarbonyl group are particularly preferable.

Examples of the alkyl group moiety of the alkylsulfonyl group as Ra1 and Ra2 include those listed above as the alkyl group as Ra1 and Ra2. Examples of the cycloalkyl group moiety of the cycloalkylsulfonyl group as Ra1 and Ra2 include those listed above as the cycloalkyl group as Ra1 and Ra2. As the alkylsulfonyl group or the cycloalkylsulfonyl group, a methanesulfonyl group, an ethanesulfonyl group, a n-propanesulfonyl group, a n-butanesulfonyl group, a cyclopentanesulfonyl group, and a cyclohexanesulfonyl group are particularly preferable.

Each of the groups Ra1 and Ra2 may further have a substituent. Examples of the substituent include a halogen atom such as a fluorine atom (preferably a fluorine atom), a hydroxy group, a carboxy group, a cyano group, a nitro group, an alkoxy group, a cycloalkyloxy group, an alkoxyalkyl group, a cycloalkyloxyalkyl group, an alkoxycarbonyl group, a cycloalkyloxycarbonyl group, an alkoxycarbonyloxy group, and a cycloalkyloxycarbonyloxy group.

Examples of the halogen atom as Ra1 and Ra2 include a fluorine atom, a chlorine atom, a bromine atom, and an iodine atom, and a fluorine atom is preferable.

As the halogenated hydrocarbon group as Ra1 and Ra2, a halogenated alkyl group is preferable. Examples of the alkyl group and the halogen atom constituting the halogenated alkyl group include those described above. Among them, a fluorinated alkyl group is preferable, and CF₃ is more preferable.

As described above, Ra1 and Ra2 may be linked to each other to form a ring (namely, a heterocyclic ring containing a sulfur atom). In this case, it is preferable that Ra1 and Ra2 are bonded to each other to form a single bond or a divalent linking group. Examples of the divalent linking group include —COO—, —OCO—, —CO—, —O—, —S—, —SO—, —SO₂—, an alkylene group, a cycloalkylene group, an alkenylene group, and combinations of two or more thereof, and those having of 20 or less carbon atoms in total are preferable. When Ra1 and Ra2 are linked to each other to form a ring, it is preferable that Ra1 and Ra2 are bonded to each other to form —COO—, —OCO—, —CO—, —O—, —S—, —SO—, —SO₂—, or a single bond. Among them, it is more preferable to form —O—, —S—, or a single bond, and it is particularly preferable to form a single bond. When n1 is 2 or more, a plurality of Ra1's may be linked to each other to form a ring, and when n2 is 2 or more, a plurality of Ra2's may be linked to each other to form a ring. Examples thereof include an embodiment in which two Ra1's are linked to each other to form a naphthalene ring together with a benzene ring to which they are bonded.

Ra3 is a fluorine atom or a group having one or more fluorine atoms. Examples of the group having a fluorine atom include groups in which an alkyl group, a cycloalkyl group, an alkoxy group, a cycloalkyloxy group, an alkoxycarbonyl group, and an alkylsulfonyl group as Ra1 and Ra2 are substituted with a fluorine atom. Among them, fluorinated alkyl groups are suitable, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉ are more suitable, and CF₃ is particularly suitable.

Ra3 is preferably a fluorine atom or CF₃, and more preferably a fluorine atom.

n1 and n2 are each independently preferably an integer of 0 to 3, and preferably an integer of 0 to 2.

n3 is preferably an integer of 1 to 3, and more preferably 1 or 2.

(n1+n2+n3) is preferably an integer of 1 to 15, more preferably an integer of 1 to 9, still more preferably an integer of 2 to 6, and particularly preferably an integer of 3 to 6. When (n1+n2+n3) is 1, it is preferable that n3=1 and Ra3 is a fluorine atom or CF₃. When (n1+n2+n3) is 2, a combination in which n1=n3=1 and Ra1 and Ra3 are each independently a fluorine atom or CF₃ and a combination in which n3=2 and Ra3 is a fluorine atom or CF₃ are preferable. When (n1+n2+n3) is 3, a combination in which n1=n2=n3=1 and Ra1 to Ra3 are each independently a fluorine atom or CF₃ is preferable. When (n1+n2+n3) is 4, a combination in which n1=n3=2 and Ra1 and Ra3 are each independently a fluorine atom or CF₃ is preferable. When (n1+n2+n3) is 5, a combination in which n1=n2=1 and n3=3 and Ra1 to Ra3 are each independently a fluorine atom or CF₃, a combination in which n1=n2=2 and n3=1 and Ra1 to Ra3 are each independently a fluorine atom or CF₃, and a combination in which n3=5 and Ra3 are each independently a fluorine atom or CF₃ are preferable. When (n1+n2+n3) is 6, a combination in which n1=n2=n3=2 and Ra1 to Ra3 are each independently a fluorine atom or CF₃ is preferable.

Examples of such an onium cation moiety represented by the formula (Q-1) include those shown below. While all of those shown below are sulfonium cation moieties having a fluorine-substituted aromatic ring structure, onium cation moieties having no fluorine-substituted aromatic ring structure that can be suitably employed include structures in which the fluorine atoms or CF₃ in the formulas shown below are replaced by an atom or group other than a fluorine atom such as a hydrogen atom or other substituent.

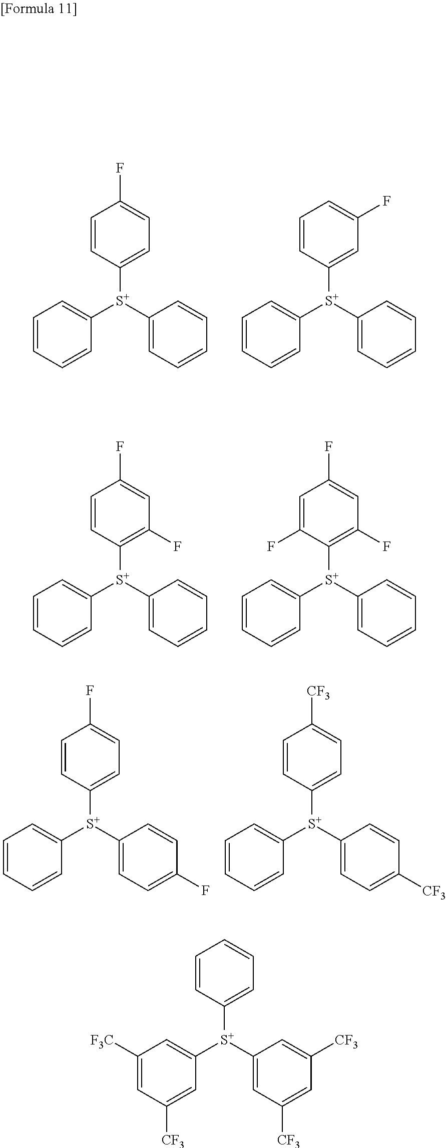

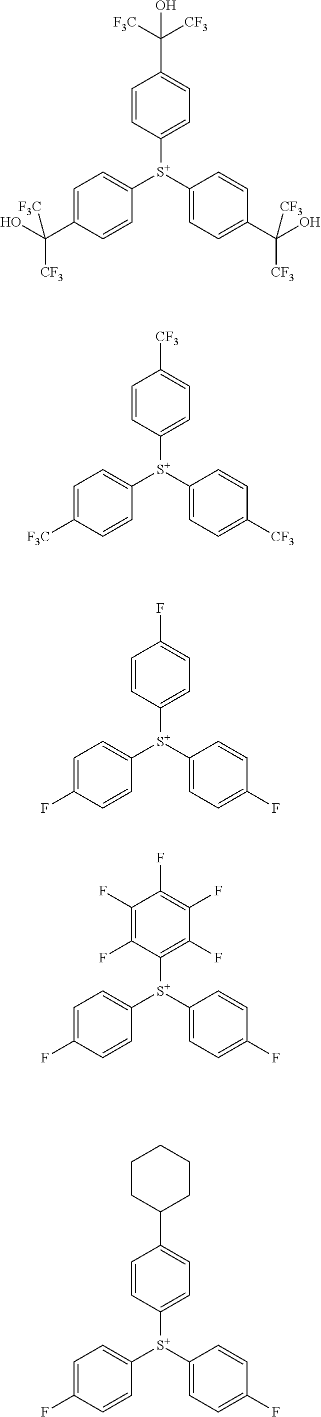 [SMILES: OC(c1ccc([S+](c2ccc(C(O)(C(F)(F)F)C(F)(F)F)cc2)c2ccc(C(O)(C(F)(F)F)C(F)(F)F)cc2)cc1)(C(F)(F)F)C(F)(F)F ; FC(F)(F)c1ccc([S+](c2ccc(C(F)(F)F)cc2)c2ccc(C(F)(F)F)cc2)cc1 ; Fc1ccc([S+](c2ccc(F)cc2)c2ccc(F)cc2)cc1 ; Fc1ccc([S+](c2ccc(F)cc2)c2c(F)c(F)c(F)c(F)c2F)cc1 ; Fc1ccc([S+](c2ccc(F)cc2)c2ccc(C3CCCCC3)cc2)cc1]

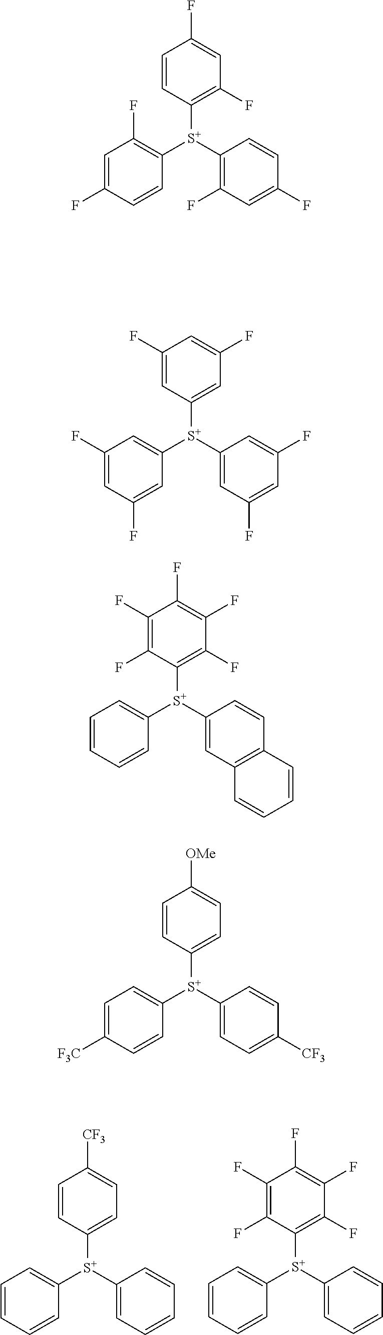 [SMILES: Fc1ccc([S+](c2ccc(F)cc2F)c2ccc(F)cc2F)c(F)c1 ; Fc1cc(F)cc([S+](c2cc(F)cc(F)c2)c2cc(F)cc(F)c2)c1 ; Fc1c(F)c(F)c([S+](c2ccccc2)c2ccc3ccccc3c2)c(F)c1F ; COc1ccc([S+](c2ccc(C(F)(F)F)cc2)c2ccc(C(F)(F)F)cc2)cc1 ; FC(F)(F)c1ccc([S+](c2ccccc2)c2ccccc2)cc1 ; Fc1c(F)c(F)c([S+](c2ccccc2)c2ccccc2)c(F)c1F]

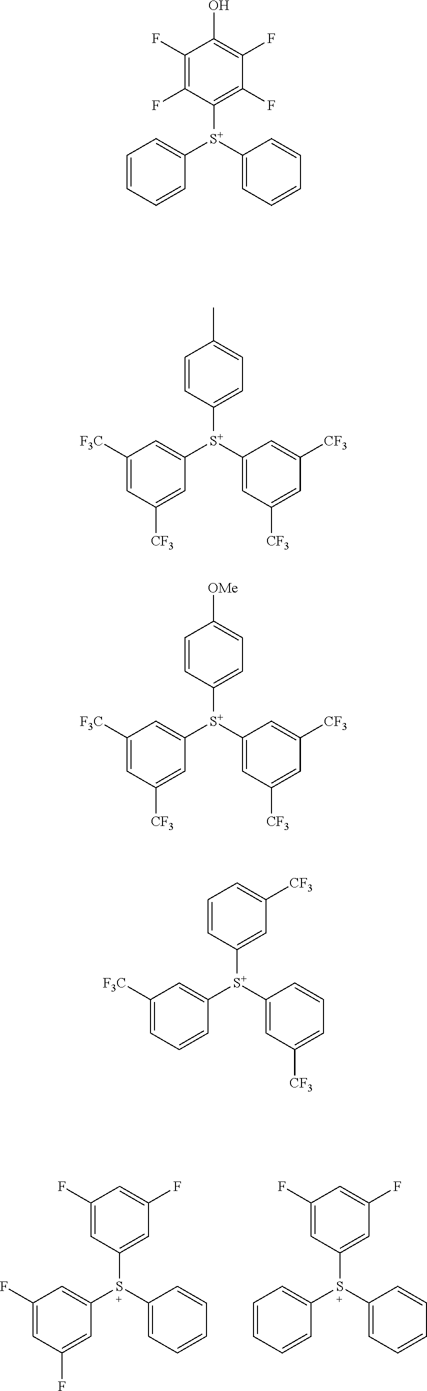

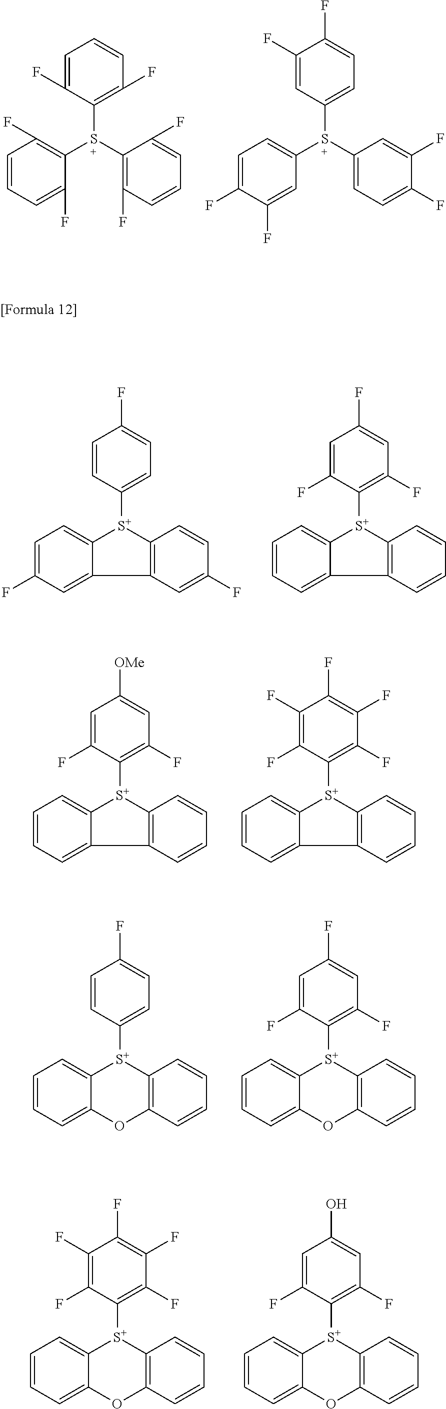

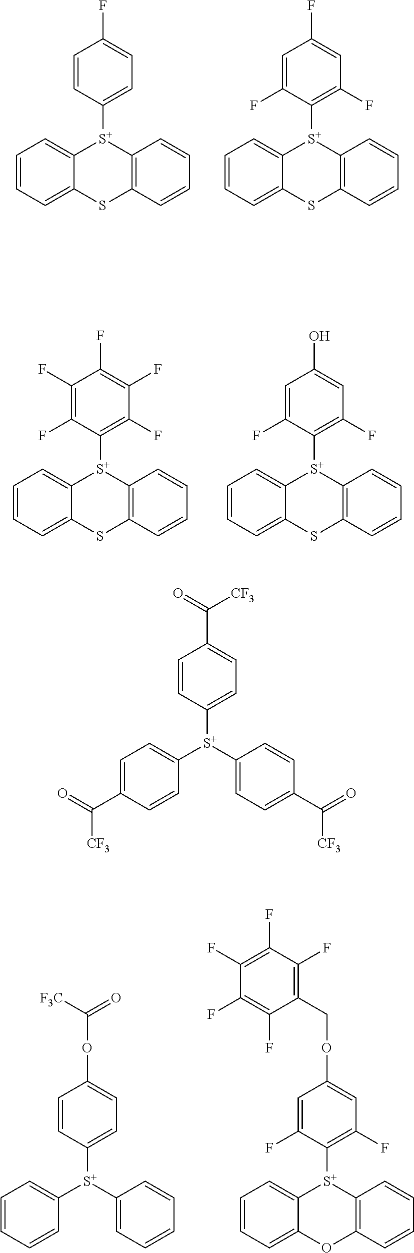

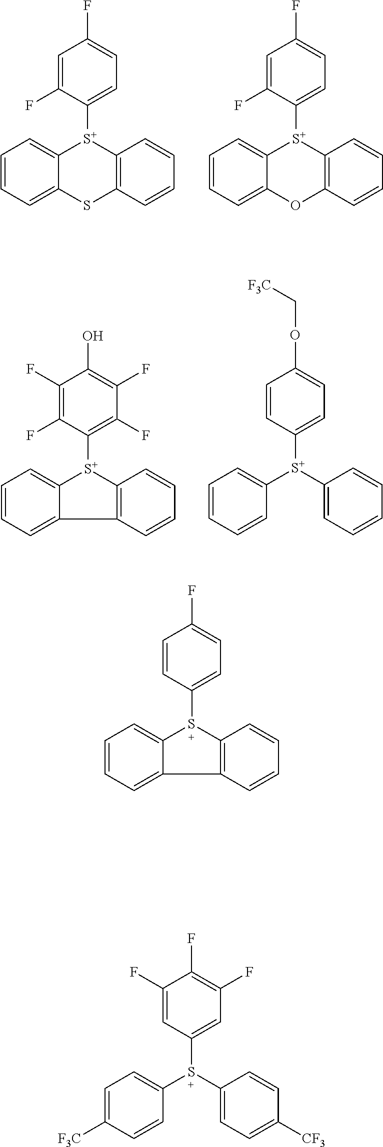

When the onium cation moiety of the structural unit a2 contains a fluorine-substituted aromatic ring structure, the onium cation moiety is preferably a diaryliodonium cation having one or more fluorine atoms. Among them, the onium cation moiety is preferably represented by the following formula (Q-2).

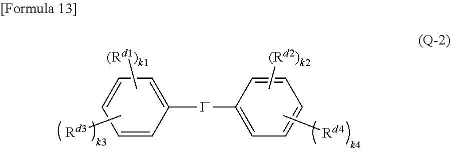

In the formula, R^{d1} and R^{d2} are each independently a substituted or unsubstituted linear or branched alkyl group, alkoxy group or alkoxycarbonyl group having 1 to 12 carbon atoms, a substituted or unsubstituted aromatic hydrocarbon group having 6 to 12 carbon atoms, or a nitro group; R^{d3} and R^{d4} are each independently a fluorine atom or a group having a fluorine atom; k1 and k2 are each independently an integer of 0 to 5, k3 and k4 are each independently an integer of 0 to 5, provided that (k1+k3) and (k2+k4) are each 5 or less, and (k3+k4) is an integer of 1 to 10; and when there are a plurality of R^{d1}'s to R^{d4} 's, the plurality of R^{d1}'s to R^{d4} 's may be the same or different, respectively.

Examples of the alkyl group, the alkoxy group, and the alkoxycarbonyl group represented by R^{d1} and R^{d2} and the group having a fluorine atom represented by R^{d3} and R^{d4} include the same groups as those represented by the above formula (Q-1).

Examples of the monovalent aromatic hydrocarbon groups having 6 to 12 carbon atoms include aryl groups such as a phenyl group, a tolyl group, a xylyl group, and a naphthyl group; and aralkyl groups such as a benzyl group and a phenethyl group.

Examples of the substituent of the respective groups include halogen atoms such as a fluorine atom, a chlorine atom, a bromine atom, and an iodine atom; a hydroxy group; a carboxy group; a cyano group; a nitro group; an alkyl group, an alkoxy group, an alkoxycarbonyl group, an alkoxycarbonyloxy group, an acyl group, an acyloxy group, or a group in which a hydrogen atom of these groups has been substituted with a halogen atom; and an oxo group (═O).

k1 and k2 are each preferably 0 to 2, and more preferably 0 or 1. k3 and k4 are each preferably 1 to 3, and more preferably 1 or 2. (k3+k4) is an integer of 1 to 10, preferably an integer of 1 to 6, more preferably an integer of 1 to 4, and still more preferably 1 or 2.

Examples of such an onium cation moiety represented by the formula (Q-2) include those shown below. While all of those shown below are iodonium cation moieties having a fluorine-substituted aromatic ring structure, onium cation moieties having no fluorine-substituted aromatic ring structure that can be suitably employed include structures in which the fluorine atoms or CF₃ in the formulas shown below are replaced by an atom or group other than a fluorine atom such as a hydrogen atom or other substituent.

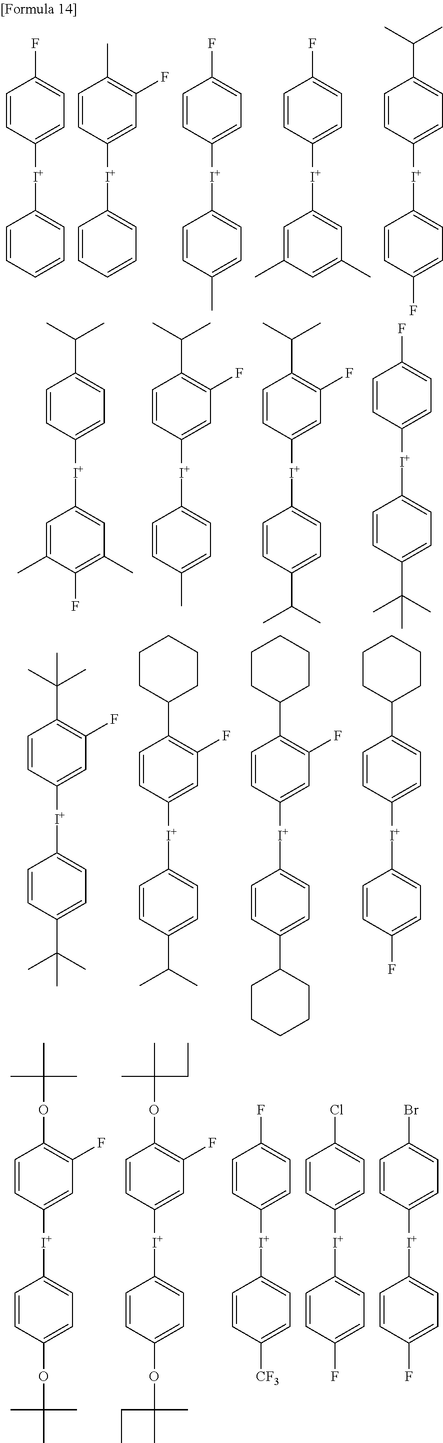

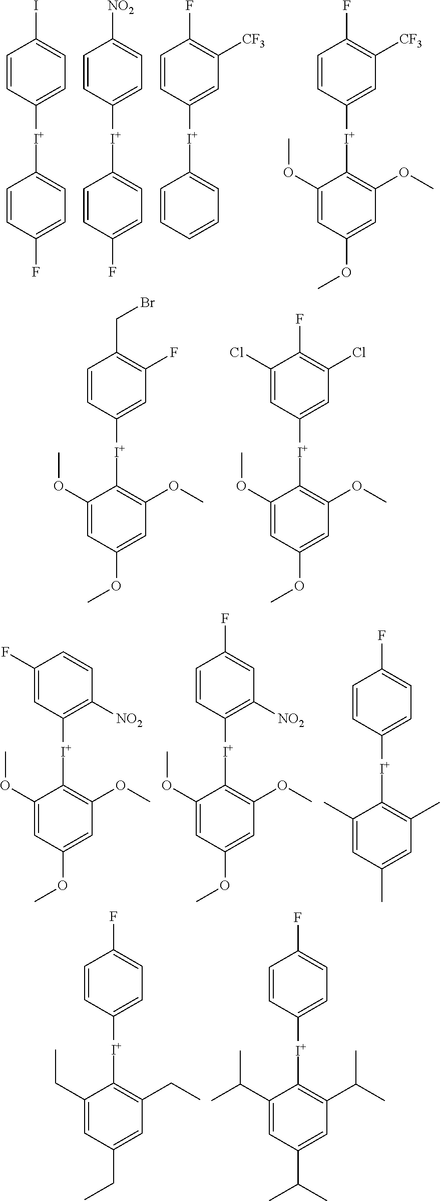

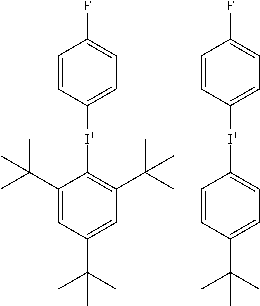 [SMILES: CC(C)(C)c1cc(C(C)(C)C)c([I+]c2ccc(F)cc2)c(C(C)(C)C)c1 ; CC(C)(C)c1ccc([I+]c2ccc(F)cc2)cc1]

The content of the structural unit a1 or the structural unit a2 (when a plurality of types of structural unit are contained, the total content thereof is taken) is preferably 2 mol % or more, more preferably 3 mol % or more, still more preferably 4 mol % or more, and particularly preferably 5 mol % or more based on all structural units constituting the radiation-sensitive acid generating resin. The content is preferably 30 mol % or less, more preferably 25 mol % or less, still more preferably 20 mol % or less, and particularly preferably 15 mol % or less. When the content of the structural unit a1 or the structural unit a2 is adjusted to within the above range, a function as an acid generator can be sufficiently exhibited.

The monomer that affords the structural unit a1 or a2 can be synthesized, for example, by the same method as that for the sulfonium salt having a polymerizable anion described in Japanese Patent No. 5201363.

The radiation-sensitive acid generating resin can also function as a base resin. At this time, the radiation-sensitive acid generating resin preferably contains a structural unit having an acid-dissociable group. The structural unit having an acid-dissociable group is preferably a structural unit represented by the following formula (b1) (hereinafter also referred to as structural unit b1) or a structural unit represented by the following formula (b2) (hereinafter also referred to as structural unit b2).

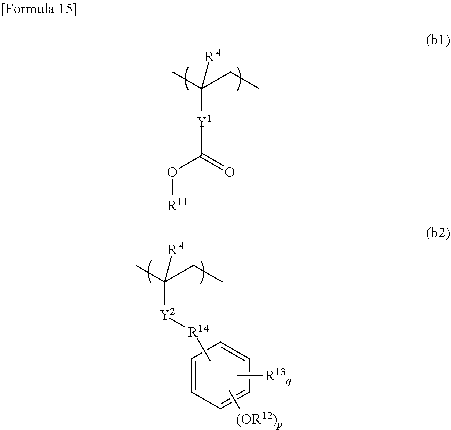

In the formulas, R^{A} is independently in each occurrence a hydrogen atom or a methyl group. Y¹ is a single bond, a phenylene group, or a naphthylene group, or a linking group having 1 to 12 carbon atoms containing at least one selected from an ester group and a lactone ring. Y² is a single bond or an ester group. R¹¹ and R¹² are each independently an acid-dissociable group. R¹³ is a halogen atom, a trifluoromethyl group, a cyano group, an alkyl or alkoxy group having 1 to 6 carbon atoms, or an acyl, acyloxy, or alkoxycarbonyl group having 2 to 7 carbon atoms. R¹⁴ is a single bond or an alkylene group having 1 to 6 carbon atoms, and some of the carbon atoms may be replaced by an ether group or an ester group. p is 1 or 2. q is an integer of 0 to 4.

Examples of the structural unit b1 include, but are not limited to, those shown below. In the following formulas, R^{A} and R¹¹ are the same as described above.

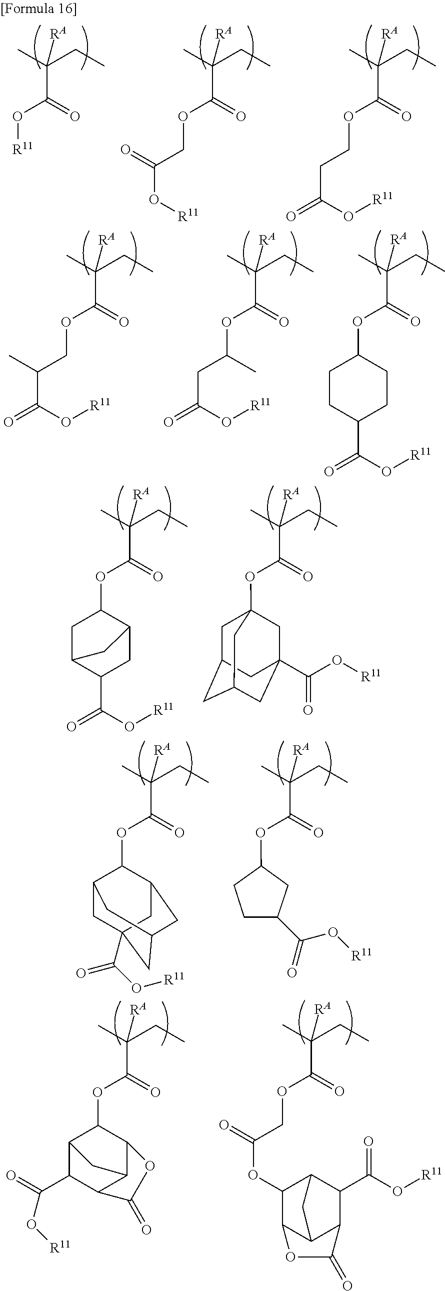

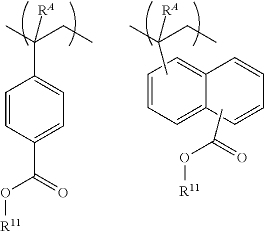

Examples of the structural unit b2 include, but are not limited to, those shown below. In the following formulas, R^{A} and R¹² are the same as described above.

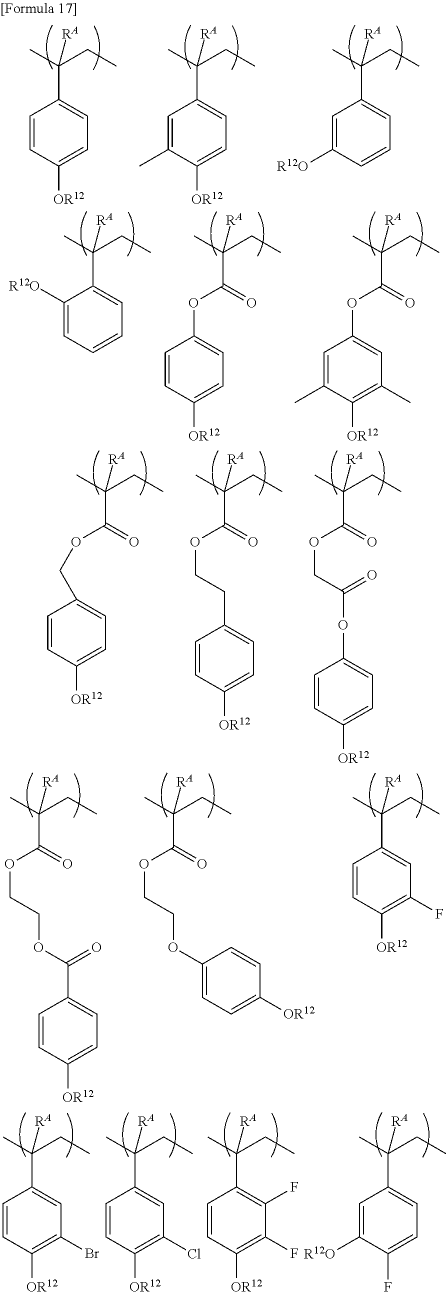

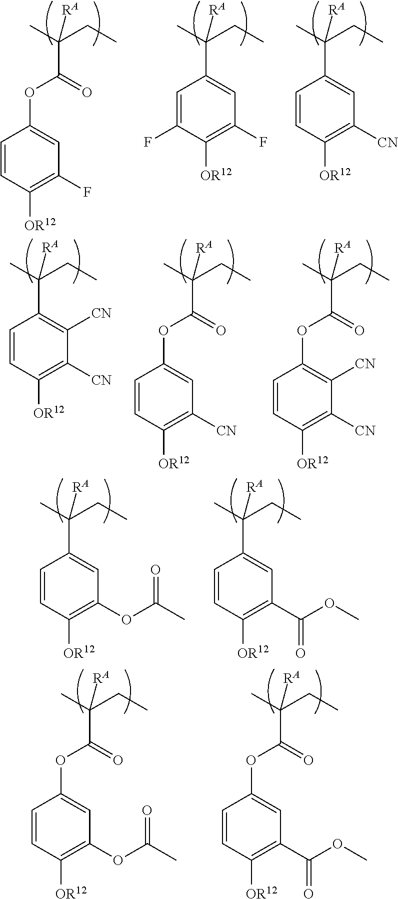

Examples of the acid-dissociable group represented by R¹¹ and R¹² in the formulas (b1) and (b2) include those described in JP-A-2013-80033 and JP-A-2013-83821.

Typically, examples of the acid-dissociable group include those represented by the following formulas (AL-1) to (AL-3).

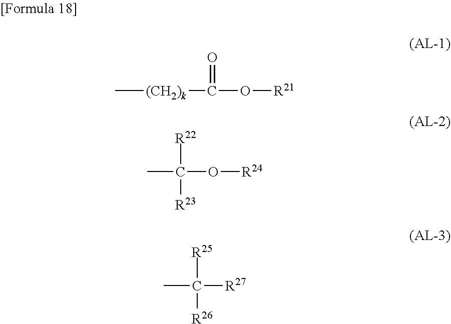

In the formulas (AL-1) and (AL-2), R²¹ and R²⁴ are a monovalent hydrocarbon group having 1 to 40, preferably 1 to 20 carbon atoms such as a branched or cyclic alkyl group, and may contain a heteroatom such as an oxygen atom, a sulfur atom, a nitrogen atom, or a fluorine atom. R²² and R²³ are each independently a hydrogen atom or a monovalent hydrocarbon group having 1 to 20 carbon atoms such as a linear, branched or cyclic alkyl group, and may contain a heteroatom such as an oxygen atom, a sulfur atom, a nitrogen atom, or a fluorine atom. Any two of R²², R²³, and R²⁴ may be bonded to each other to form a ring, especially, alicyclic ring, having 3 to 20 carbon atoms, preferably 4 to 16 carbon atoms, together with the carbon atom or the carbon atom and the oxygen atom to which they are bonded. k is an integer of 1 to 5.

In the formula (AL-3), R²⁵, R²⁶ and R²⁷ are each independently a monovalent hydrocarbon group having 1 to 20 carbon atoms such as a linear, branched or cyclic alkyl group, and may contain a heteroatom such as an oxygen atom, a sulfur atom, a nitrogen atom or a fluorine atom. Any two of R²⁵, R²⁶ and R²⁷ may be bonded to each other to form a ring, especially, alicyclic ring, having 3 to 20 carbon atoms, preferably 4 to 16 carbon atoms, together with the carbon atom to which they are bonded.

The content of the structural unit b1 or the structural unit b2 (when a plurality of types of structural unit are contained, the total content thereof is taken) is preferably mol % or more, more preferably 20 mol % or more, still more preferably 30 mol % or more, and particularly preferably 35 mol % or more based on all structural units constituting the radiation-sensitive acid generating resin. The content is preferably 80 mol % or less, more preferably 75 mol % or less, still more preferably 70 mol % or less, and particularly preferably 65 mol % or less. When the content of the structural unit b1 or the structural unit b2 is adjusted to within the above range, the pattern-forming performance of the radiation-sensitive resin composition can be further improved.

When the radiation-sensitive acid generating resin also functions as a base resin, the radiation-sensitive acid generating resin preferably further contains a structural unit c having a phenolic hydroxy group. Examples of the monomer to afford the structural unit c include, but are not limited to, those shown below. In the following formulas, R^{A} is the same as described above.

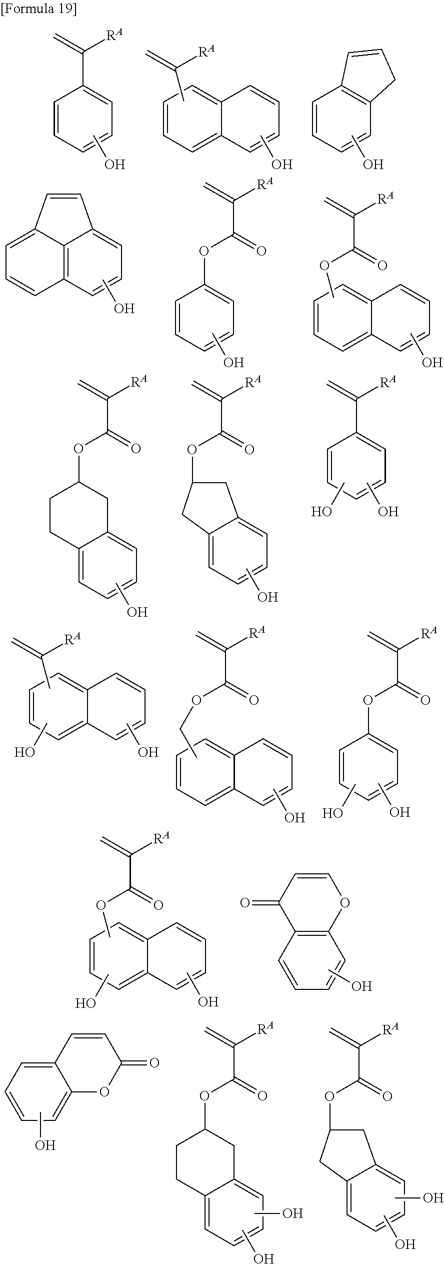

The content of the structural unit c (when a plurality of types of structural unit are contained, the total content thereof is taken) is preferably 5 mol % or more, more preferably 8 mol % or more, still more preferably 10 mol % or more, and particularly preferably 15 mol % or more based on all structural units constituting the radiation-sensitive acid generating resin. The content is preferably 50 mol % or less, more preferably 45 mol % or less, still more preferably 40 mol % or less, and particularly preferably 35 mol % or less. When the content of the structural unit c is adjusted to within the above range, the pattern-forming performance of the radiation-sensitive resin composition can be further improved.

When the radiation-sensitive acid generating resin also functions as a base resin, the radiation-sensitive acid generating resin may further contain a structural unit d containing an alcoholic hydroxy group, a carboxy group, a lactone ring, a sultone ring, an ether group, an ester group, a carbonyl group, or a cyano group as an adhesive group. Examples of the monomer to afford the structural unit d include, but are not limited to, those shown below. In the following formulas, R^{A} is the same as described above.

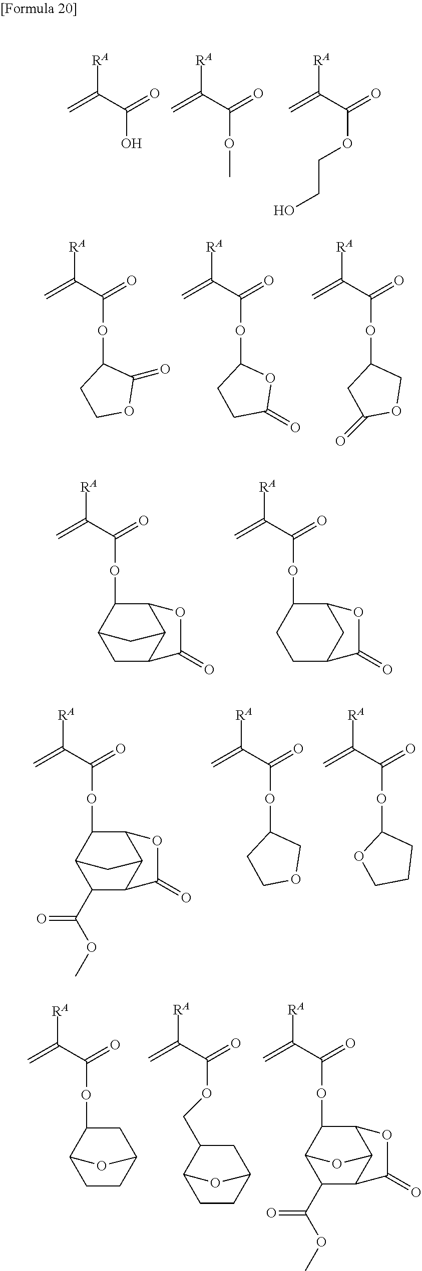

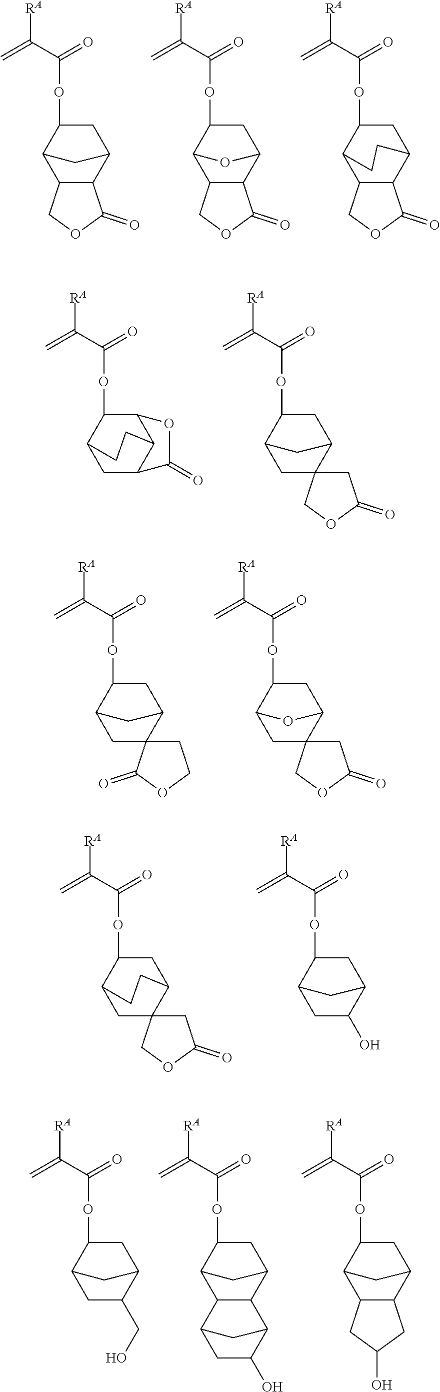

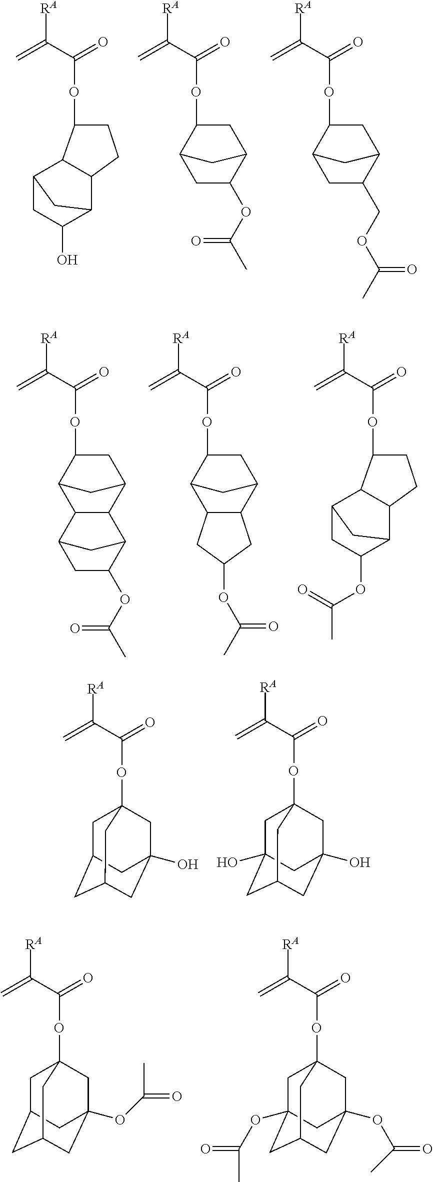

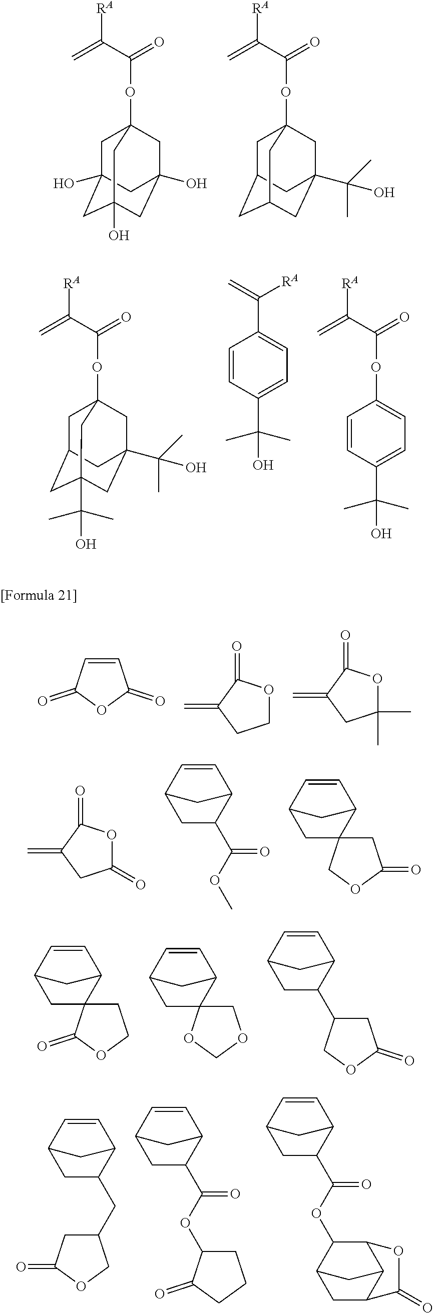

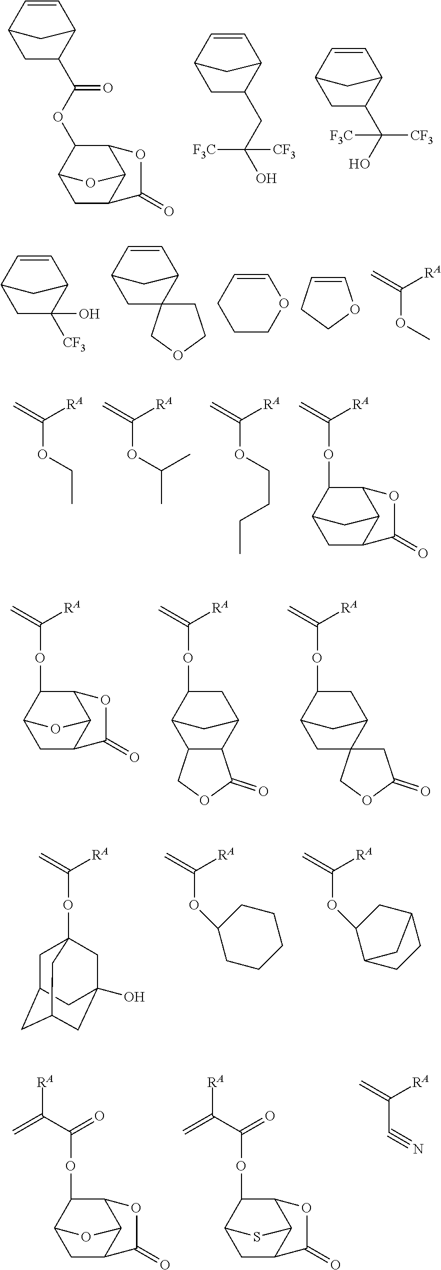

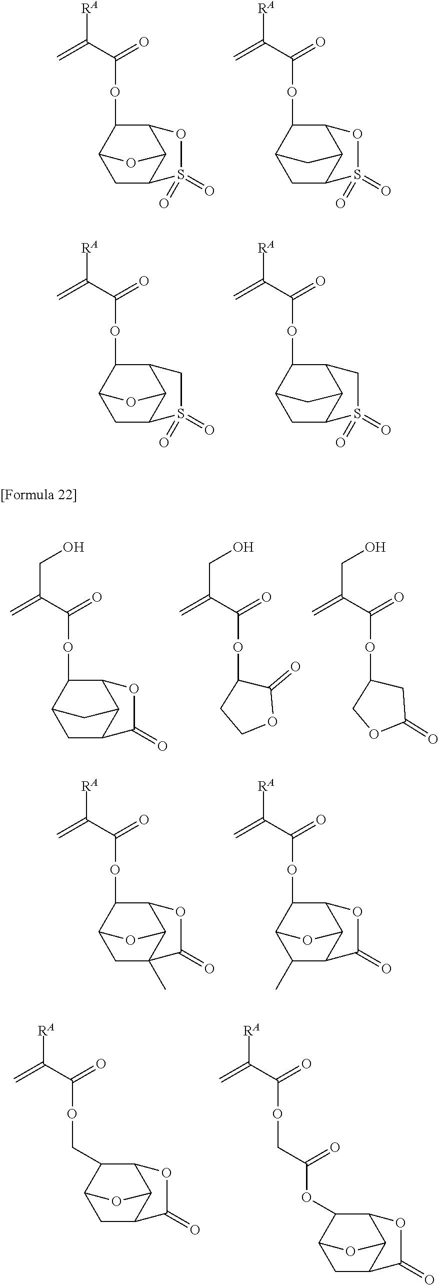

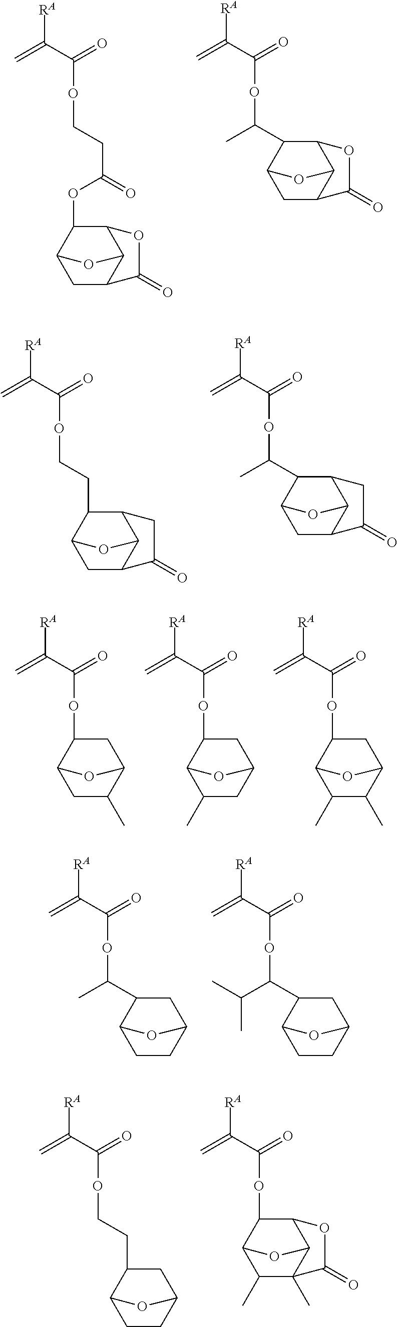

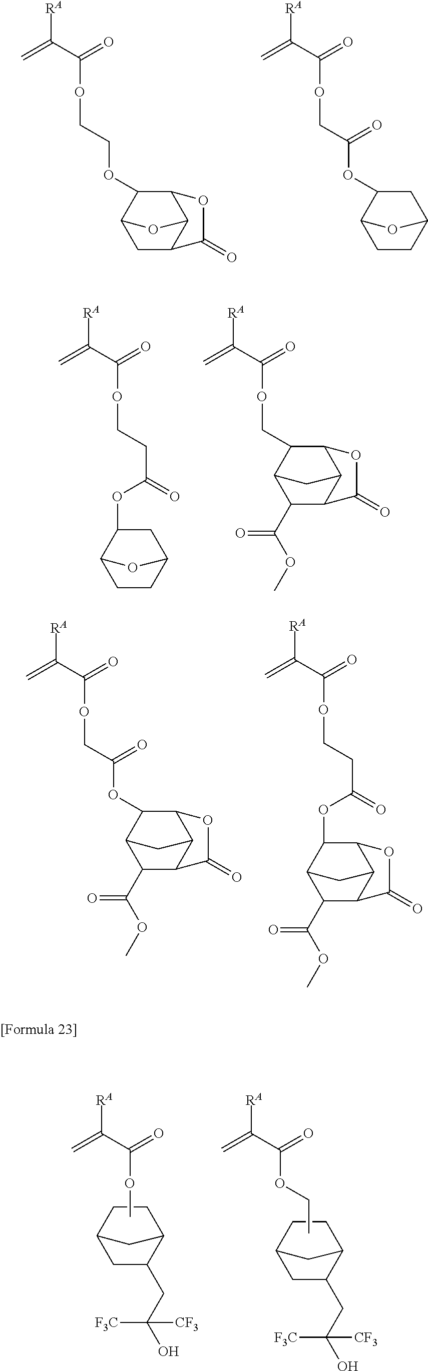

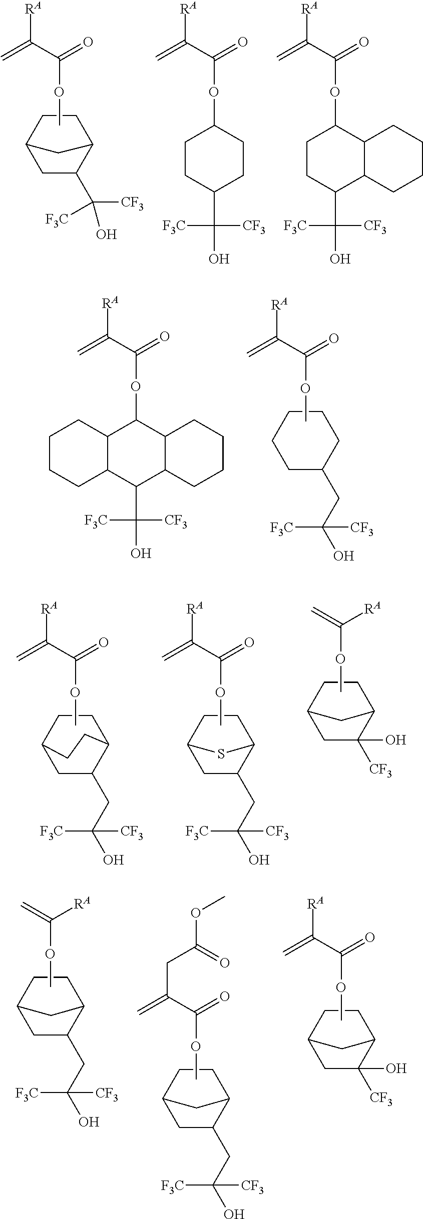

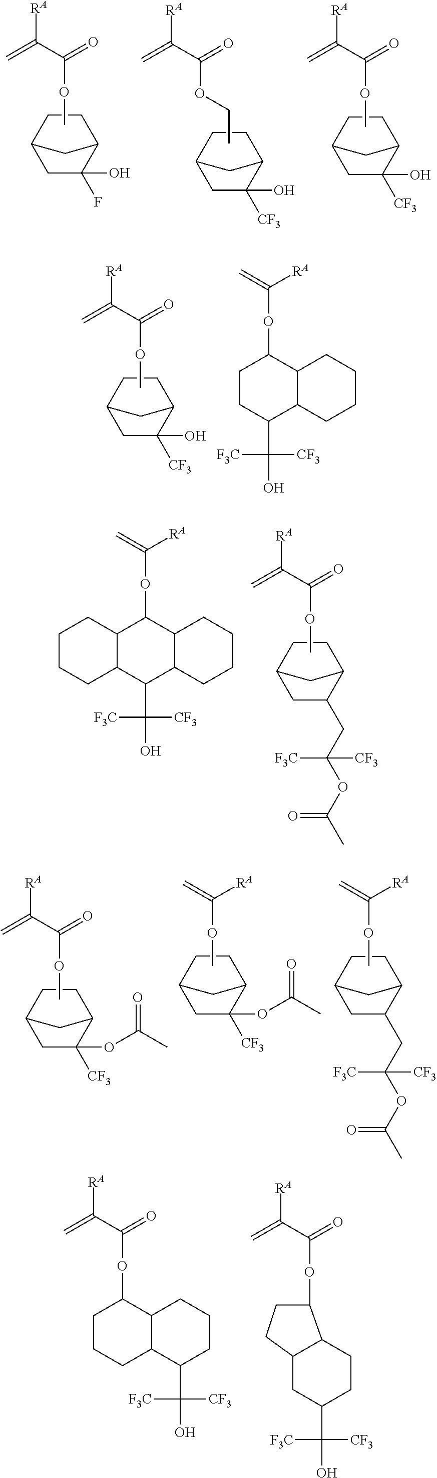

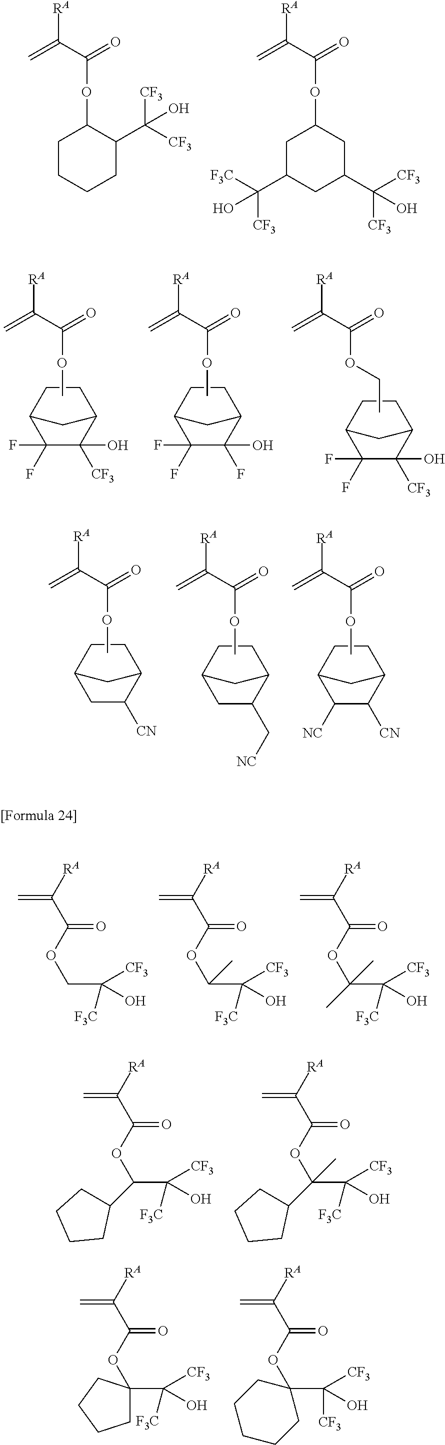

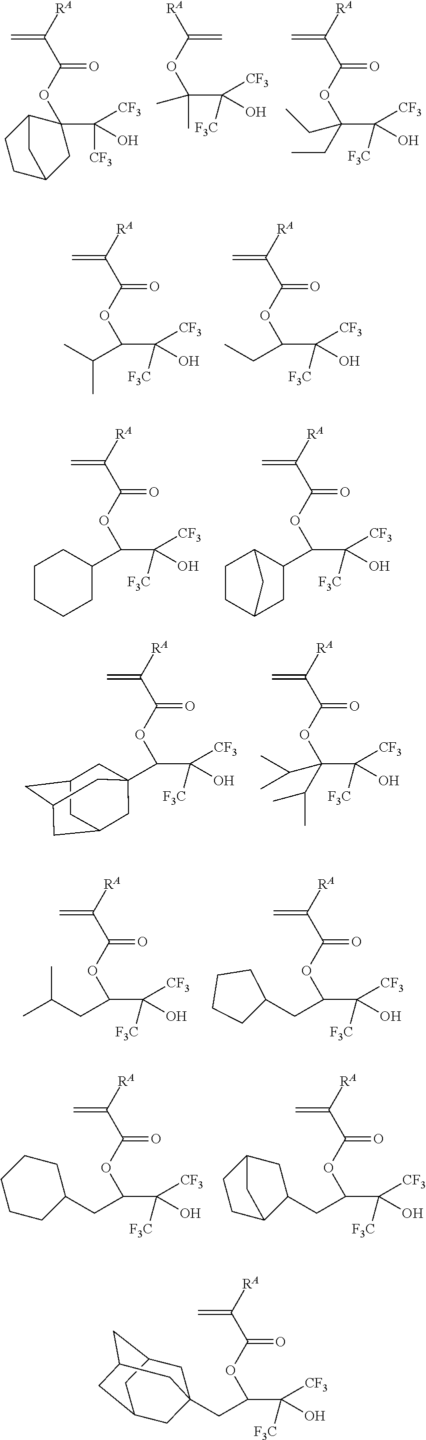

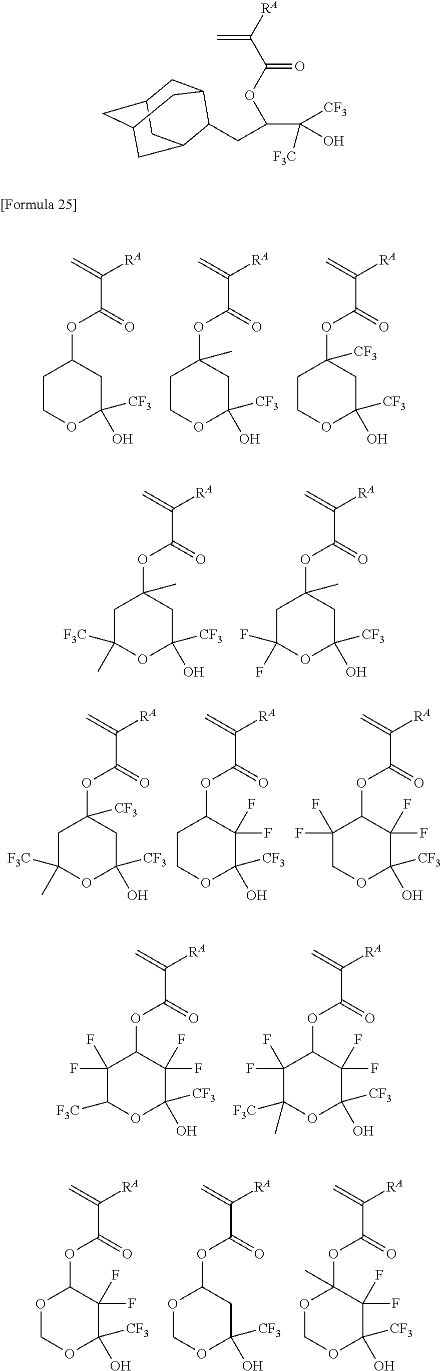

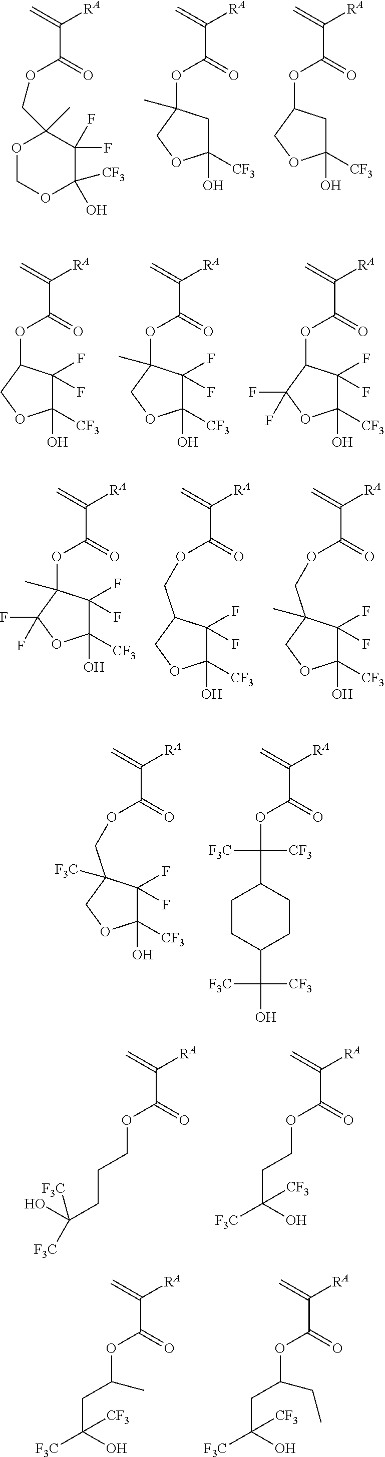

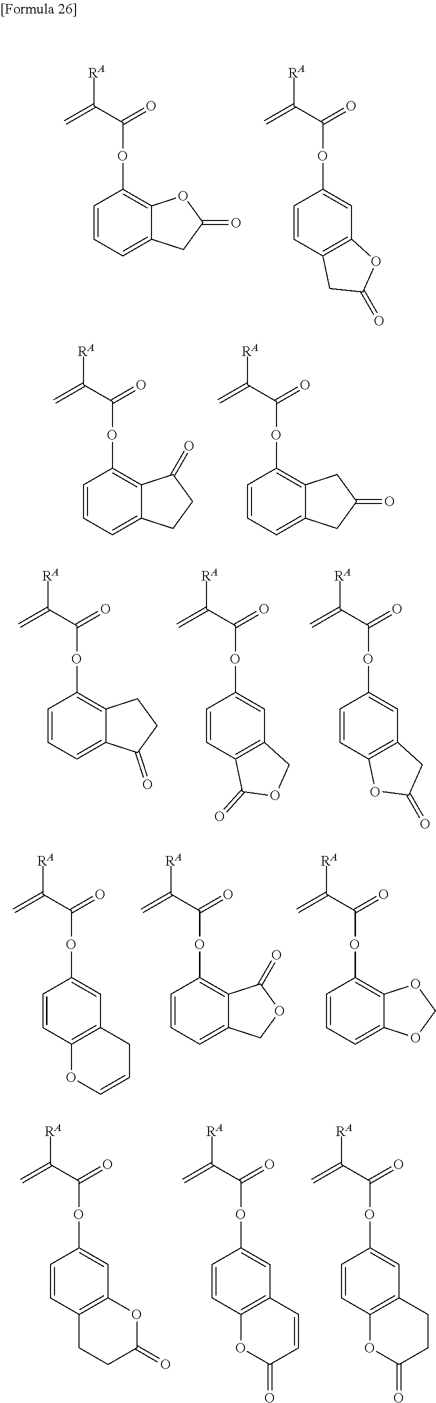

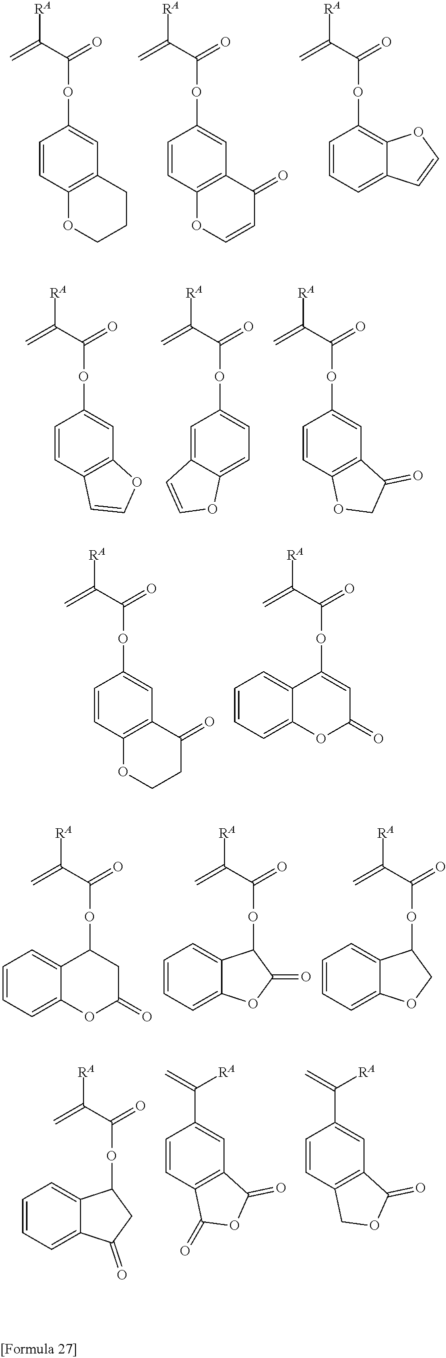

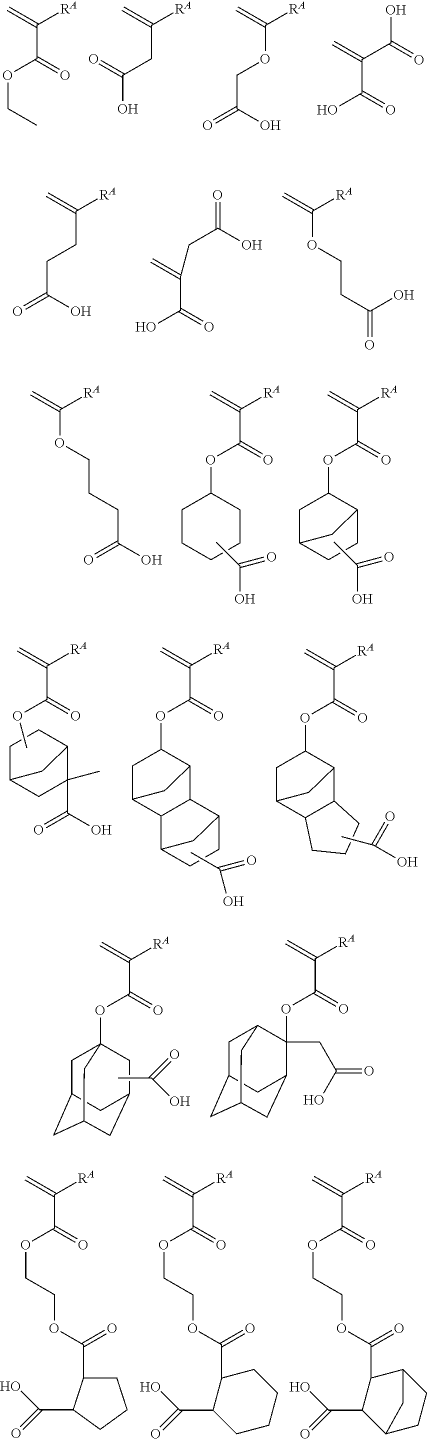

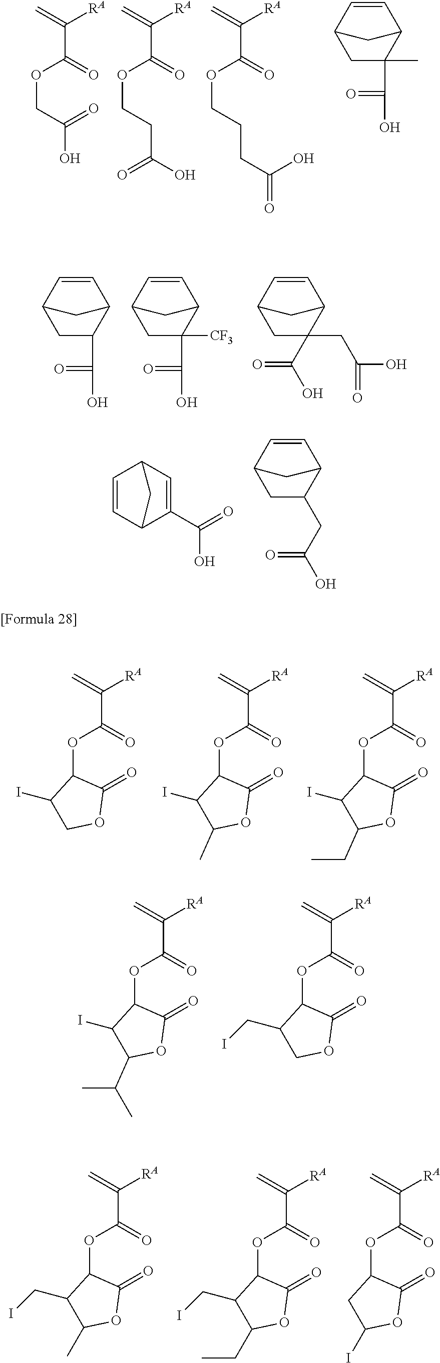

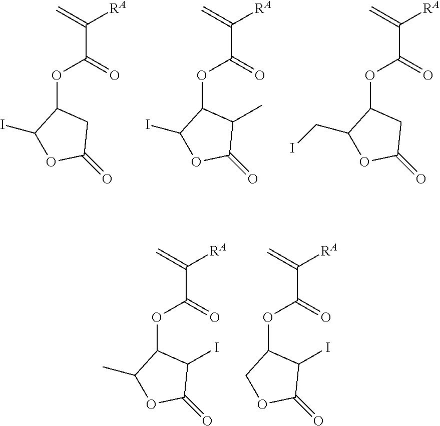

The content of the structural unit d (when a plurality of types of structural unit are contained, the total content thereof is taken) is preferably 5 mol % or more, more preferably 8 mol % or more, still more preferably 10 mol % or more, and particularly preferably 15 mol % or more based on all structural units constituting the radiation-sensitive acid generating resin. The content is preferably 60 mol % or less, more preferably 50 mol % or less, still more preferably 40 mol % or less, and particularly preferably 35 mol % or less. When the content of the structural unit d is adjusted to within the above range, the pattern adhesiveness can be further improved.

The radiation-sensitive acid generating resin can be synthesized, for example, by polymerizing monomers to afford the above-described structural units in an organic solvent by heating with addition of a radical polymerization initiator. In the polymerization, a known polymerization initiator can be used.

When hydroxystyrene or hydroxyvinylnaphthalene is copolymerized, acetoxystyrene or acetoxyvinylnaphthalene may be used instead of hydroxystyrene or hydroxyvinylnaphthalene, and an acetoxy group may be deprotected by the alkali hydrolysis after polymerization to form a hydroxystyrene unit or a hydroxyvinylnaphthalene unit.

The radiation-sensitive acid generating resin preferably has a polystyrene-equivalent weight average molecular weight (Mw) of 1,000 or more, more preferably 2,000 or more, as measured by gel permeation chromatography (GPC) using THF as a solvent. In addition, the Mw is preferably 50,000 or less, and more preferably 30,000 or less. When the Mw is in the above range, the pattern-forming performance and heat resistance of a resist material are good.

Furthermore, in a case where the radiation-sensitive acid generating resin has a wide molecular weight distribution (Mw/Mn), since a low molecular weight or high molecular weight polymer is present, there is a risk that foreign matters may be found on a pattern or the shape of the pattern may be deteriorated after exposure. Since the influence of Mw and molecular weight distribution tends to increase as the pattern rule becomes finer, in order to obtain a resist material suitably used for fine pattern dimensions, the molecular weight distribution of the radiation-sensitive acid generating resin is preferably a narrow dispersion of 1.0 to 2.0, particularly 1.0 to 1.7.

The radiation-sensitive acid generating resin may contain two or more polymers differing in composition ratio, Mw, and molecular weight distribution.

When the radiation-sensitive resin composition contains a radiation-sensitive acid generating resin, the content of the radiation-sensitive acid generating resin is preferably 75 mass % or more, more preferably 80 mass % or more, and still more preferably 85 mass % or more based on the amount of the radiation-sensitive resin composition excluding the solvent contained therein. The content is preferably 99 mass % or less, and more preferably 95 mass % or less.

### <Radiation-Sensitive Acid Generator>

The radiation-sensitive acid generator contains an organic acid anion moiety and an onium cation moiety. The radiation-sensitive acid generator is preferably represented by the following formula (A-1) or (A-2).

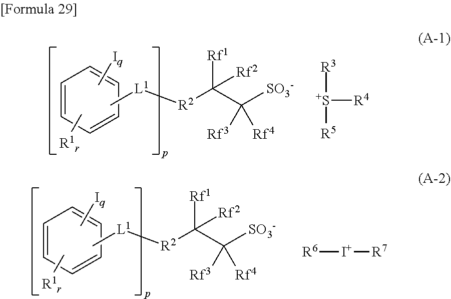

In the formulas (A-1) and (A-2), L 1 is a single bond, an ether linkage, an ester linkage, or an alkylene group having 1 to 6 carbon atoms and optionally containing an ether linkage or an ester linkage. The alkylene group may be linear, branched, or cyclic.

R¹ is a hydroxy group, a carboxy group, a fluorine atom, a chlorine atom, a bromine atom, or an amino group; or is an alkyl group having 1 to 20 carbon atoms, an alkoxy group having 1 to 20 carbon atoms, an alkoxycarbonyl group having 2 to 10 carbon atoms, an acyloxy group having 2 to 20 carbon atoms, or an alkylsulfonyloxy group having 1 to 20 carbon atoms, each optionally containing a fluorine atom, a chlorine atom, a bromine atom, a hydroxy group, an amino group, or an alkoxy group having 1 to 10 carbon atoms; or is —NR⁸—C(═O)—R⁹ or —NR⁸—C(═O)—O—R⁹, wherein R⁸ is a hydrogen atom or an alkyl group having 1 to 6 carbon atoms and optionally containing a halogen atom, a hydroxy group, an alkoxy group having 1 to 6 carbon atoms, an acyl group having 2 to 6 carbon atoms, or an acyloxy group having 2 to 6 carbon atoms, and R⁹ is an alkyl group having 1 to 16 carbon atoms, an alkenyl group having 2 to 16 carbon atoms, or an aryl group having 6 to 12 carbon atoms and optionally contains a halogen atom, a hydroxy group, an alkoxy group having 1 to 6 carbon atoms, an acyl group having 2 to 6 carbon atoms, or an acyloxy group having 2 to 6 carbon atoms. The alkyl group, alkoxy group, alkoxycarbonyl group, acyloxy group, acyl group, and alkenyl group may be linear, branched, or cyclic.

Among them, R¹ is preferably a hydroxy group, —NR⁸—C(═O)—R⁹, a fluorine atom, a chlorine atom, a bromine atom, a methyl group, a methoxy group, or the like.

R² is a single bond or a divalent linking group having 1 to 20 carbon atoms when p is 1, and is a trivalent or tetravalent linking group having 1 to 20 carbon atoms when p is 2 or 3, and the linking groups may contain an oxygen atom, a sulfur atom, or a nitrogen atom.

Rf¹ to Rf⁴ are each independently a hydrogen atom, a fluorine atom, or a trifluoromethyl group, and at least one of Rf¹ to Rf⁴ is a fluorine atom or a trifluoromethyl group. Rf¹ and Rf² may be combined to form a carbonyl group. In particular, both Rf³ and Rf⁴ are preferably fluorine atoms.

R³, R⁴, R⁵, R⁶, and R⁷ are each independently a monovalent hydrocarbon group having 1 to 20 carbon atoms and optionally containing a heteroatom. When the onium cation moiety of the radiation-sensitive acid generator has fluorine, at least one of R³, R⁴, and R⁵ contains one or more fluorine atoms, and at least one of R⁶ and R⁷ contains one or more fluorine atoms. Any two of R³, R⁴, and R⁵ may be bonded to each other to form a ring together with the sulfur atom to which they are bonded. The monovalent hydrocarbon group may be linear, branched, or cyclic, and examples thereof include an alkyl group having 1 to 12 carbon atoms, an alkenyl group having 2 to 12 carbon atoms, an alkynyl group having 2 to 12 carbon atoms, an aryl group having 6 to 20 carbon atoms, and an aralkyl group having 7 to 12 carbon atoms. Some or all of the hydrogen atoms of these groups may be replaced by a hydroxy group, a carboxy group, a halogen atom, a cyano group, an amide group, a nitro group, a mercapto group, a sultone group, a sulfone group, or a sulfonium salt-containing group, and some of the carbon atoms of these groups may be replaced by an ether linkage, an ester linkage, a carbonyl group, a carbonate group, or a sulfonic acid ester linkage.

p is an integer satisfying 1≤p≤3. q and r are integers satisfying 0≤q≤5, 0≤r≤3, and 0≤q+r≤5. is preferably an integer satisfying 1≤q≤3, and more preferably 2 or 3. r is preferably an integer satisfying 0≤r≤2.

Examples of the organic acid anion moiety of the radiation-sensitive acid generators represented by the formulas (A-1) and (A-2) include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in the formulas shown below are replaced by an atom or group other than an iodine atom such as a hydrogen atom or other substituent.

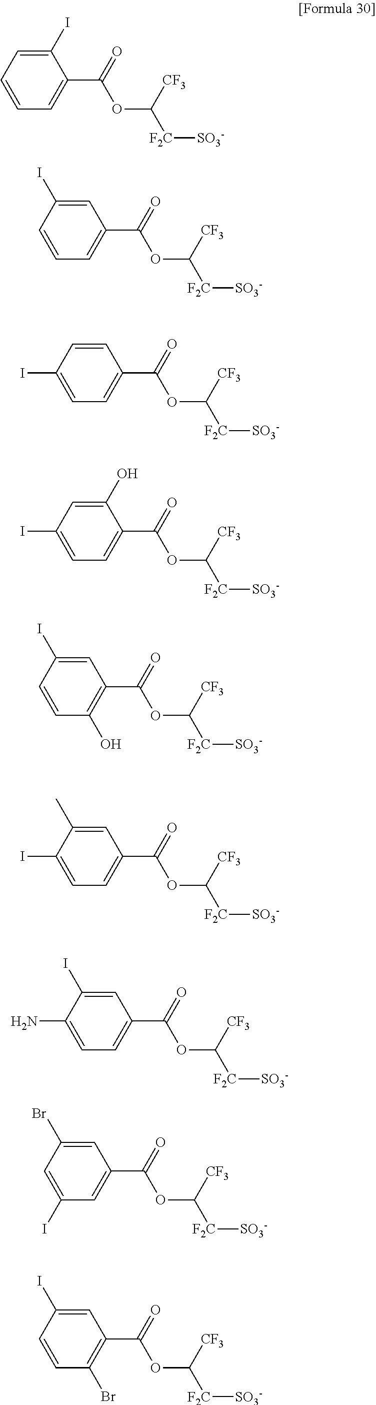

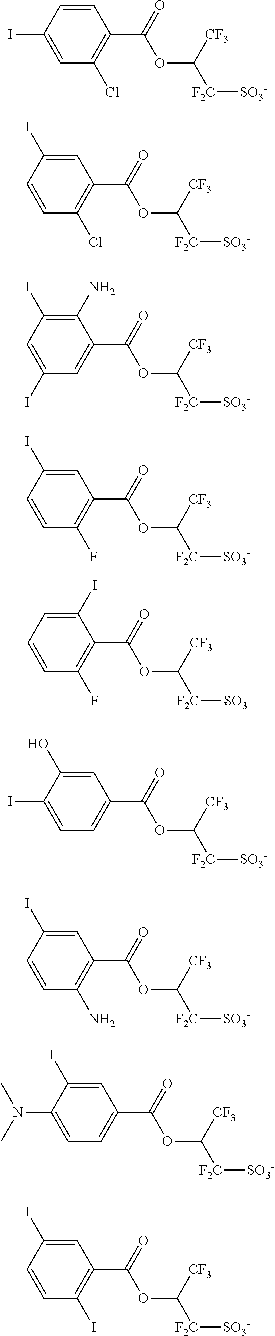

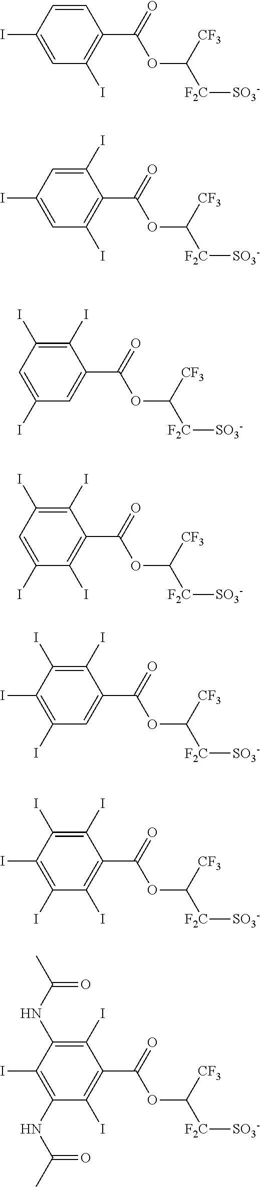

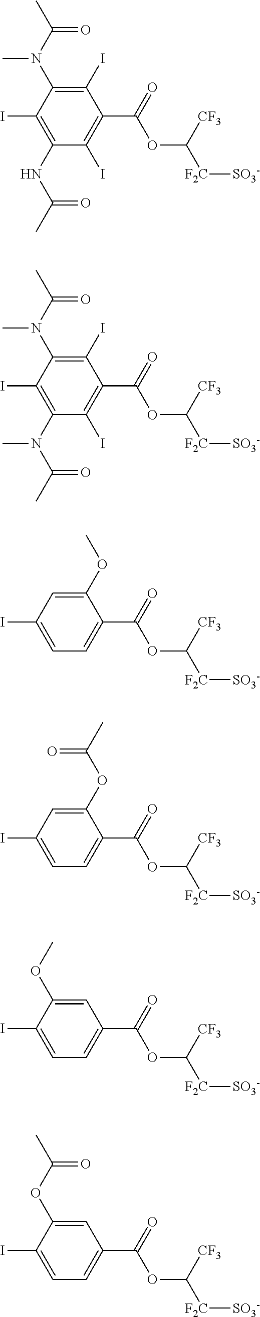

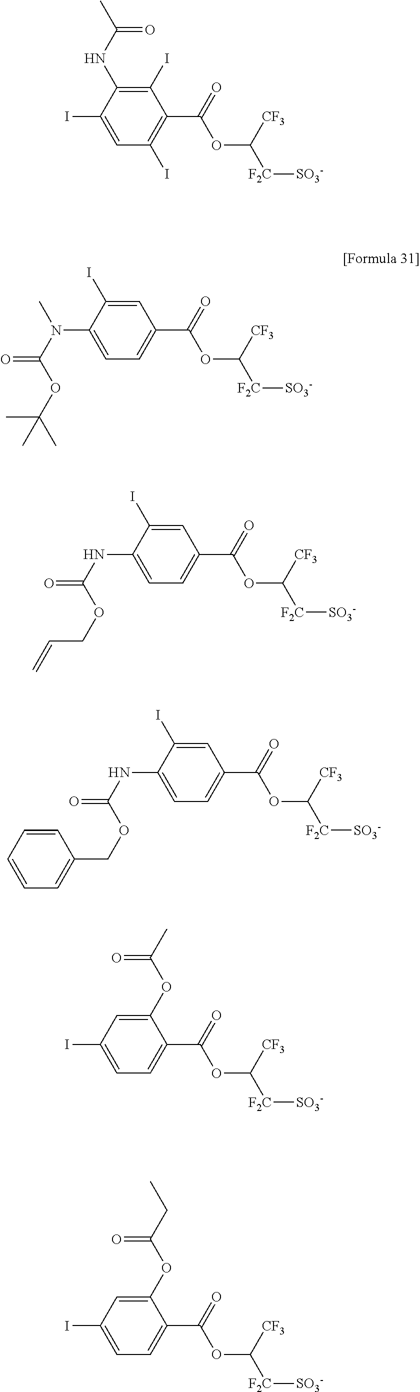

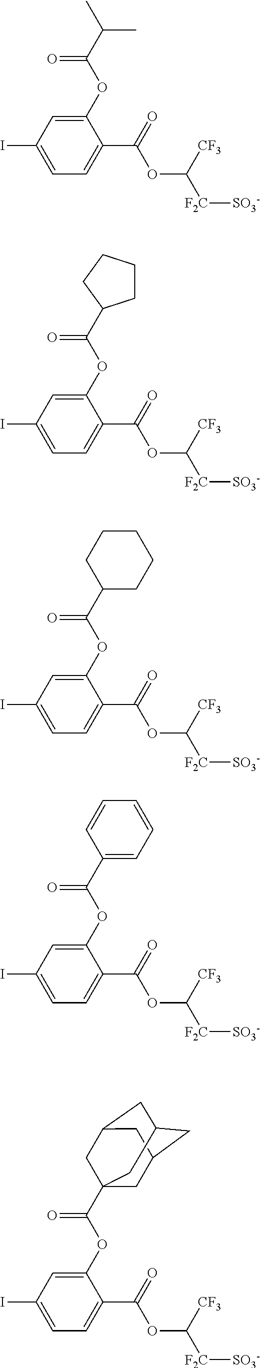

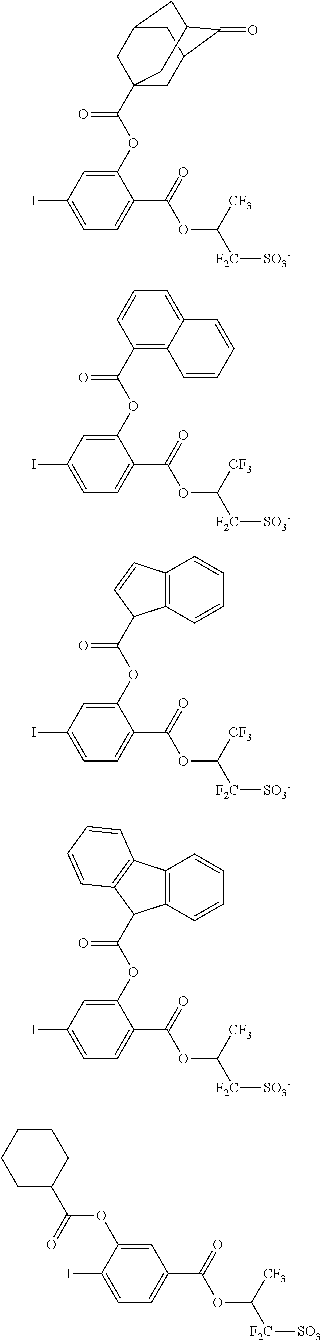

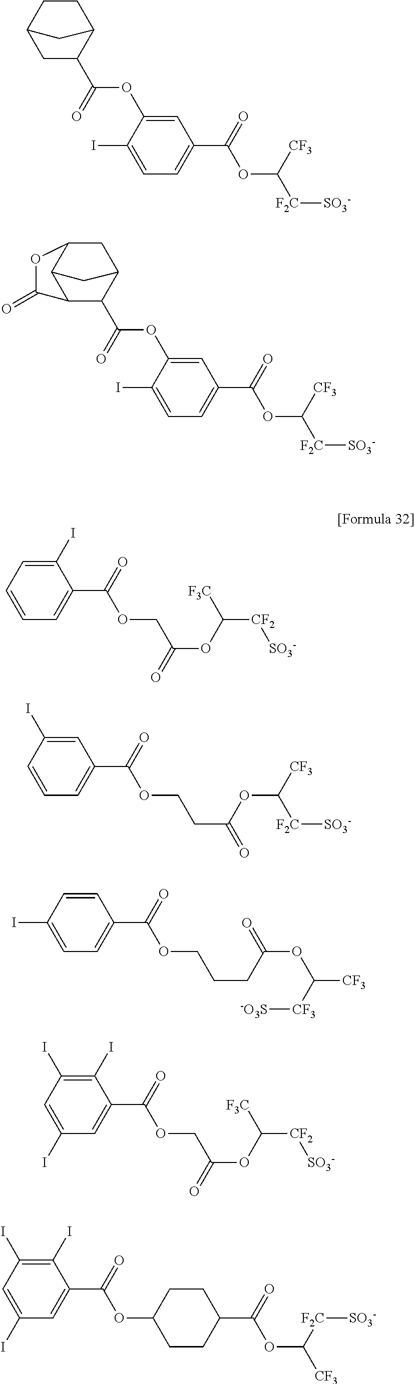

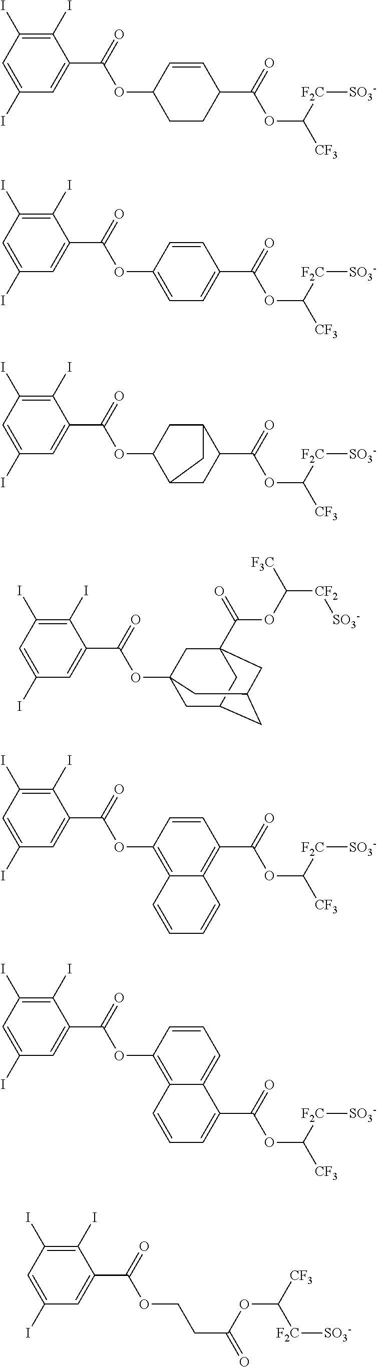

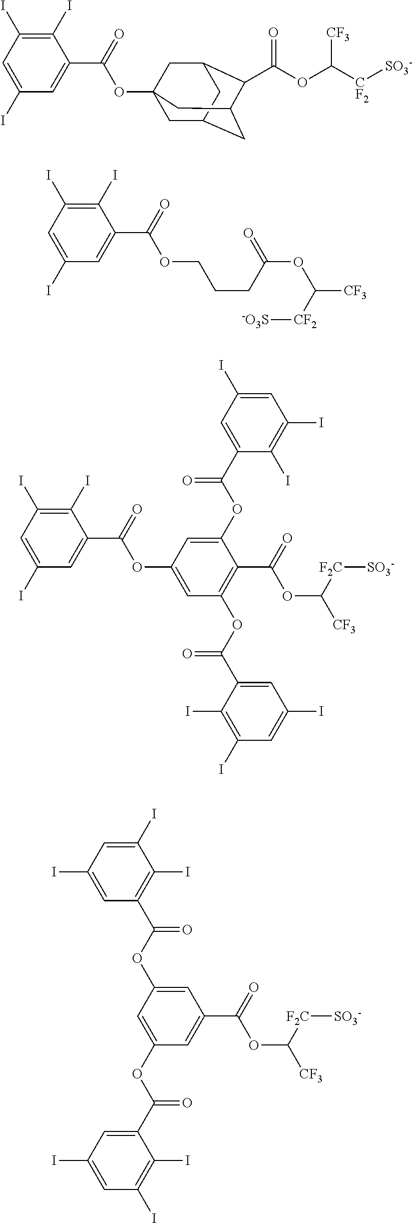

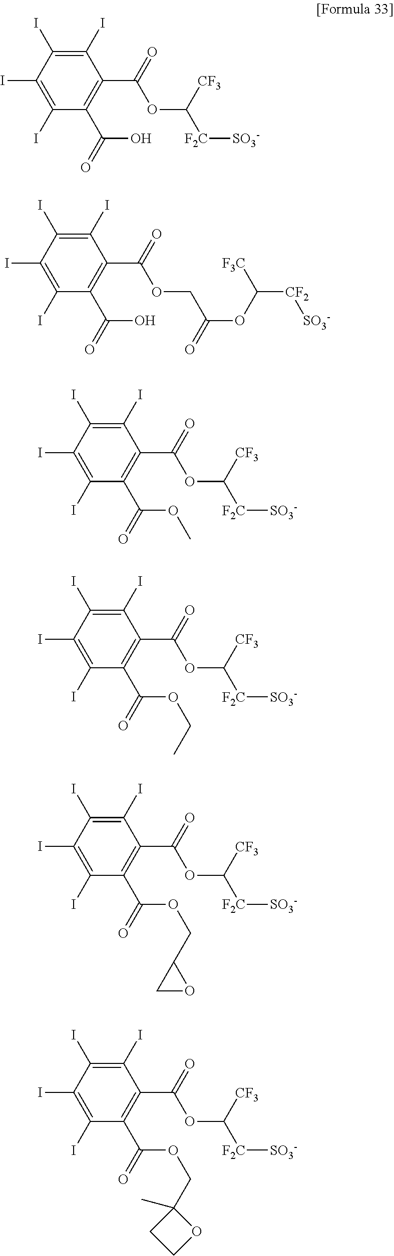

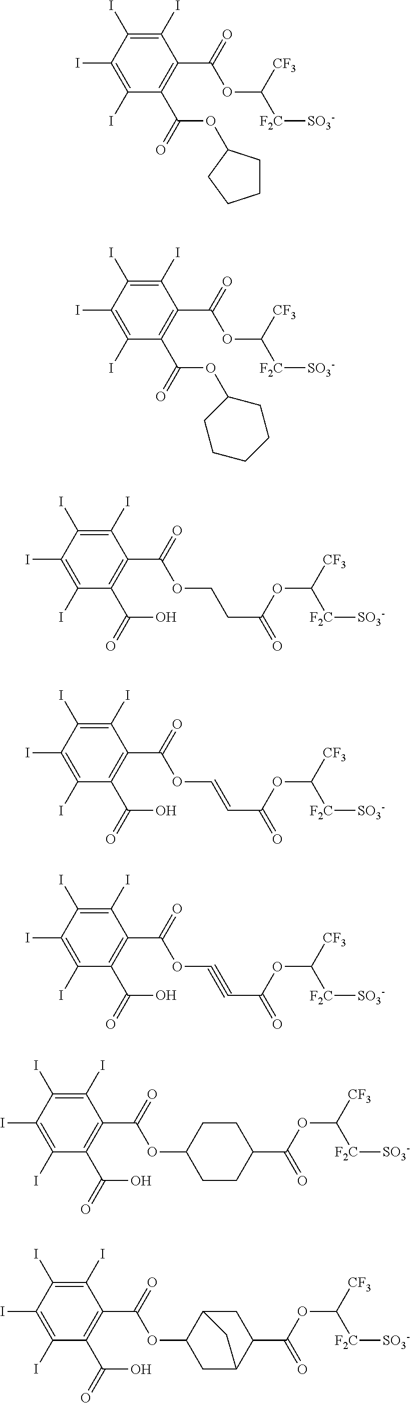

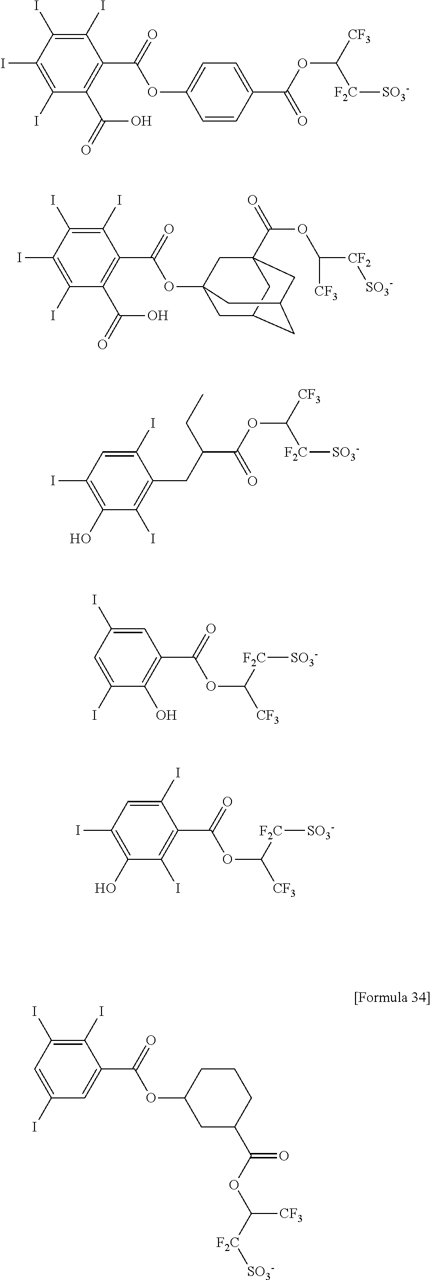

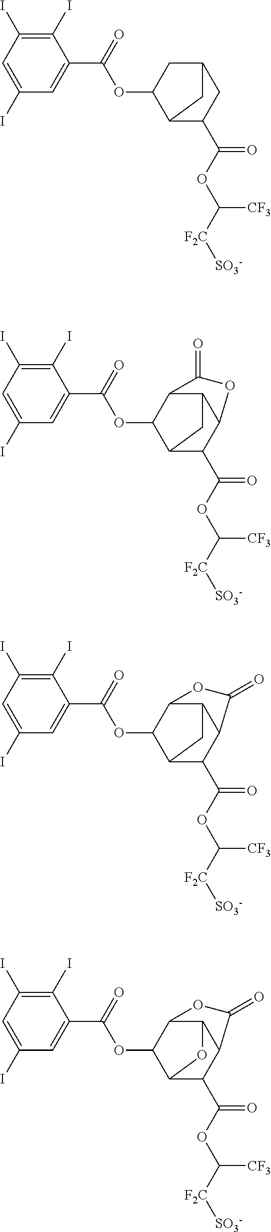

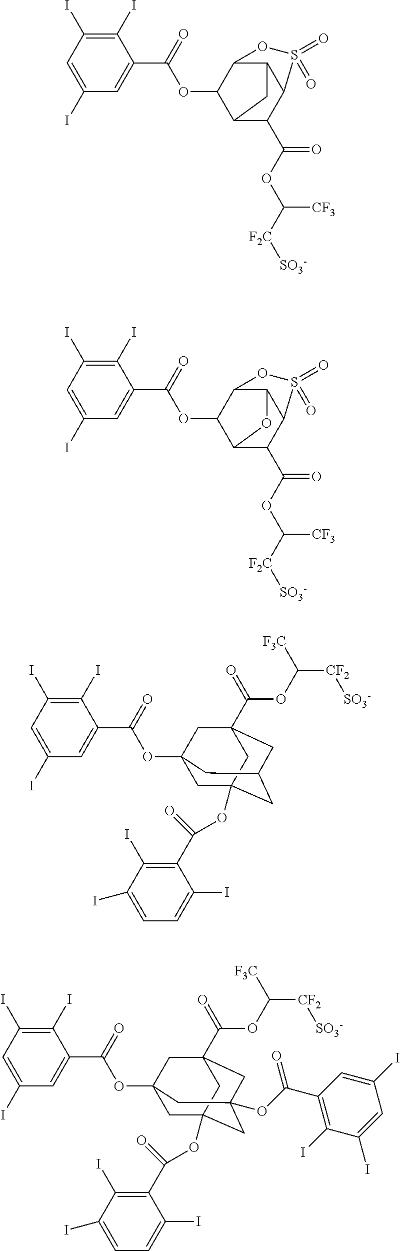

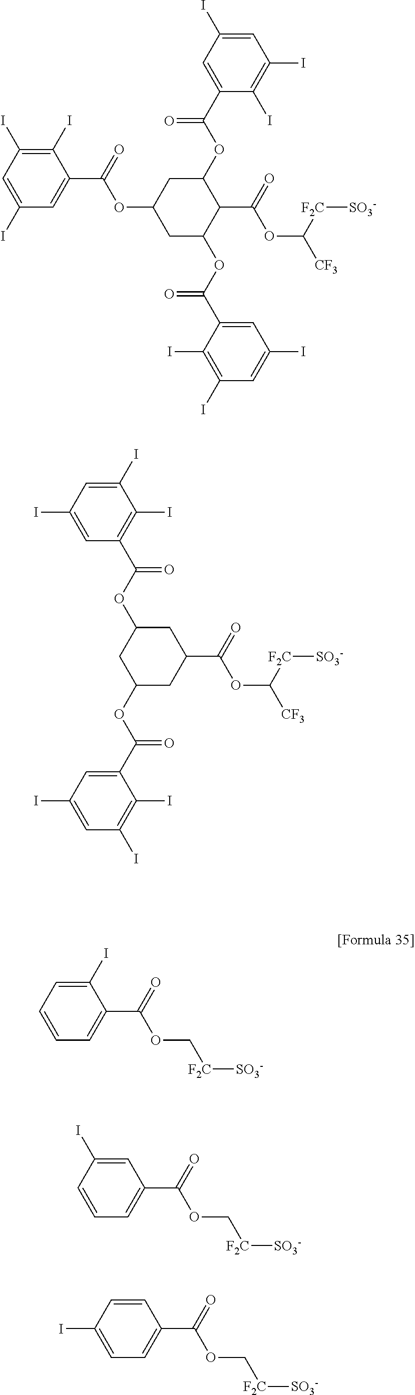

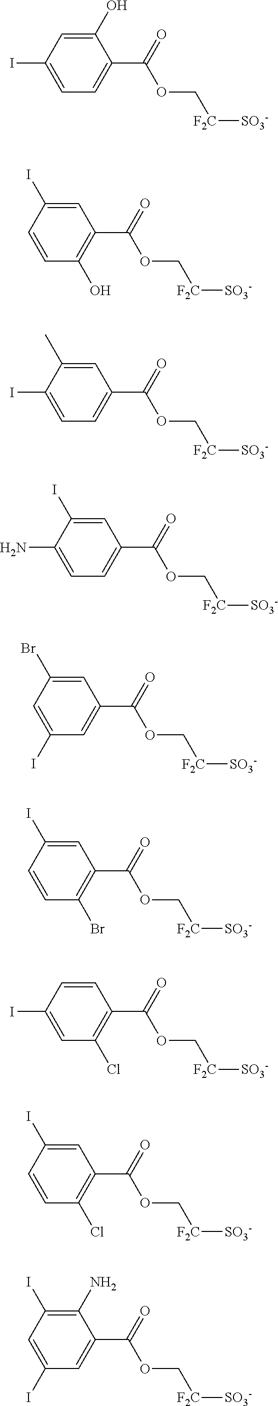

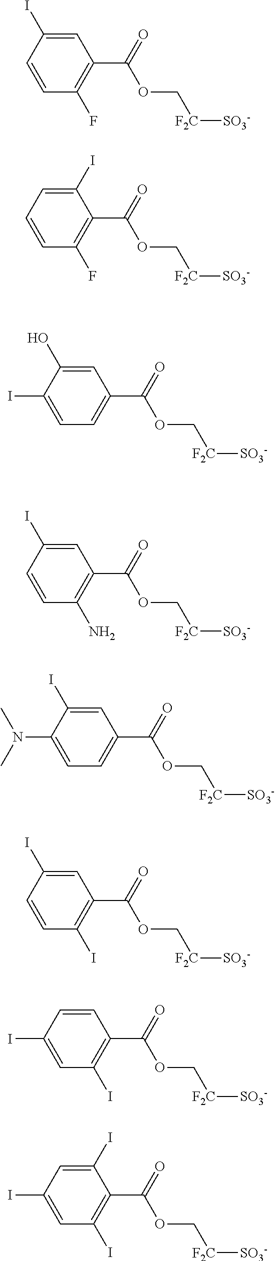

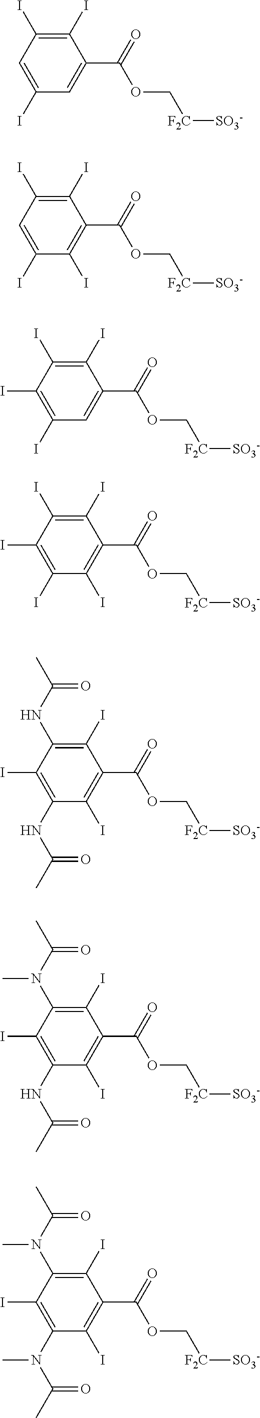

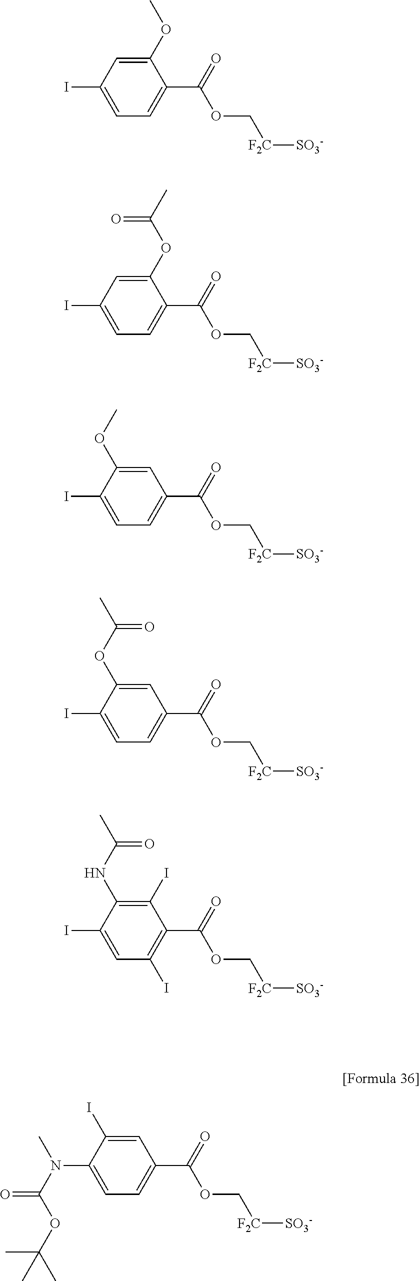

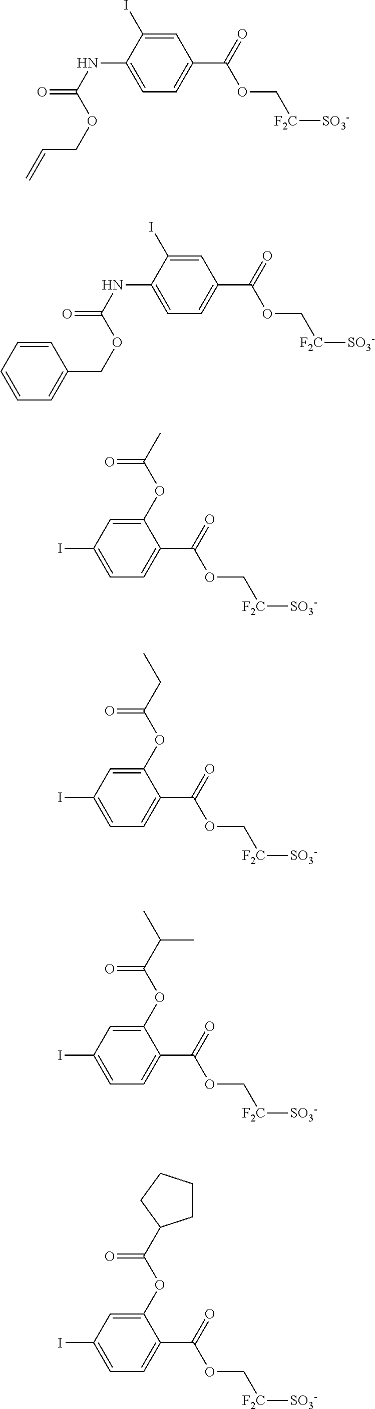

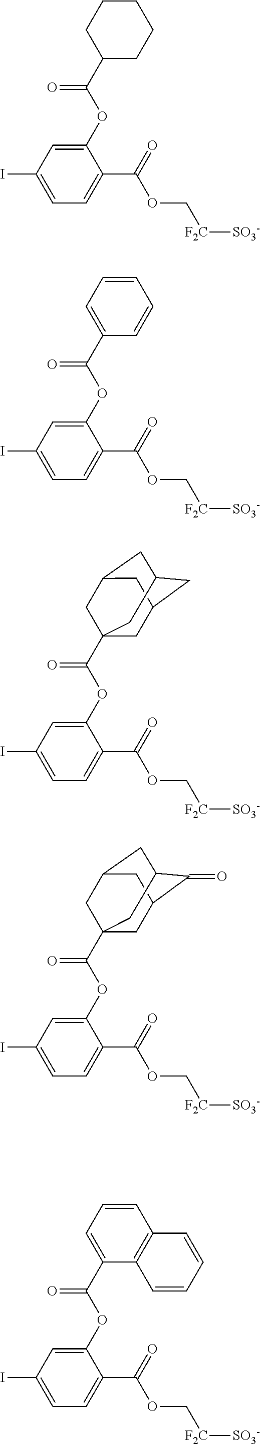

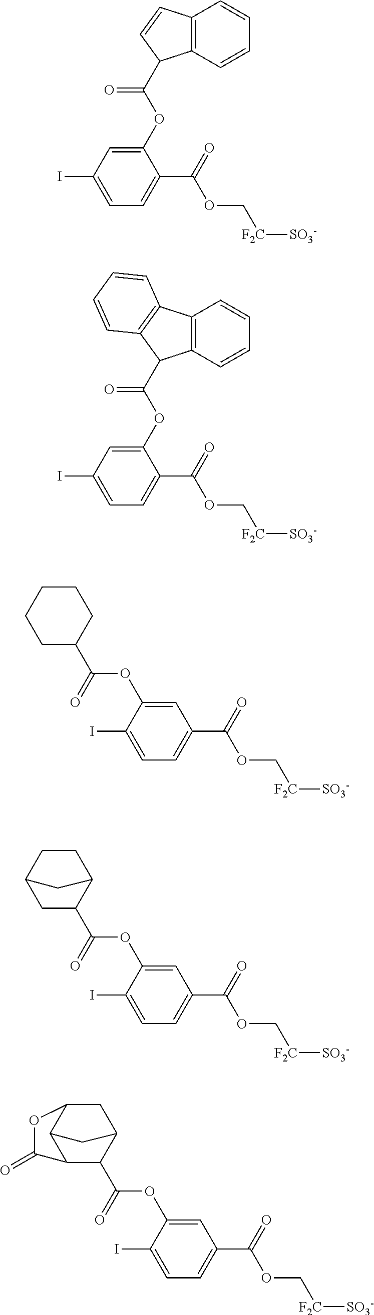

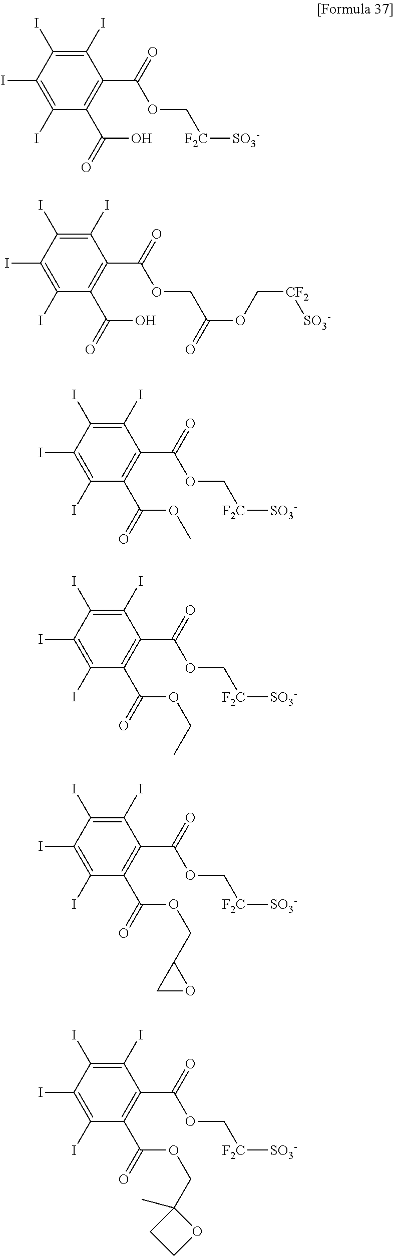

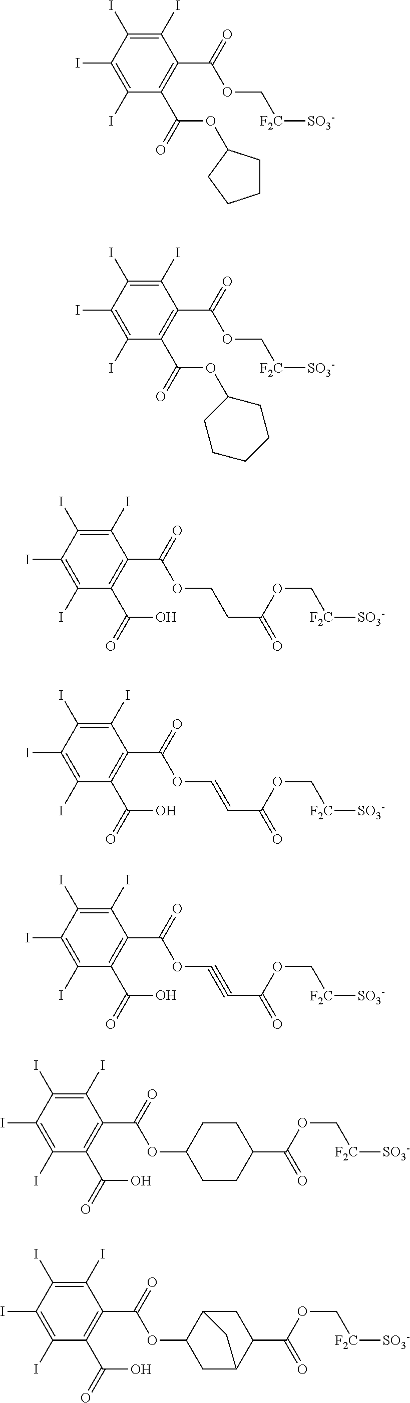

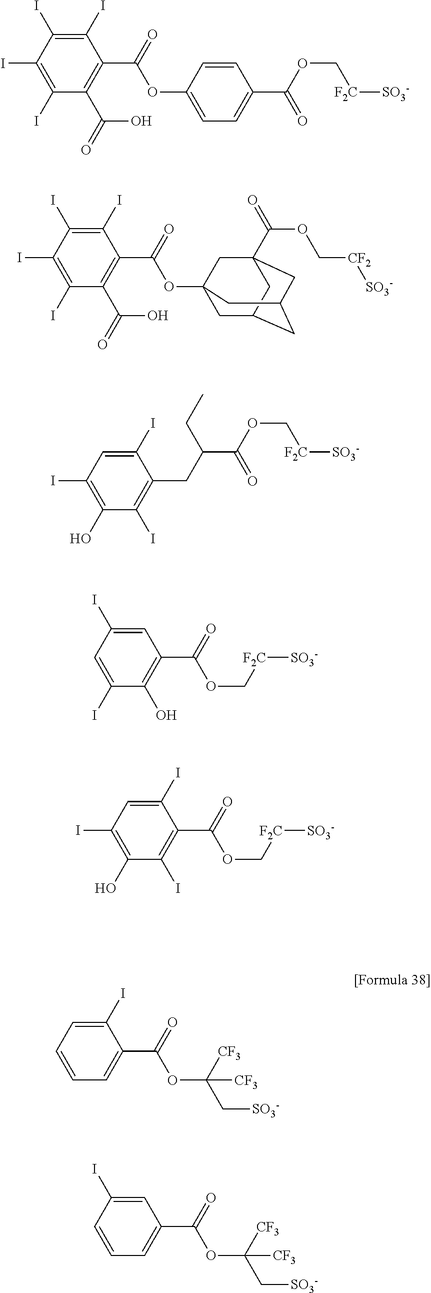

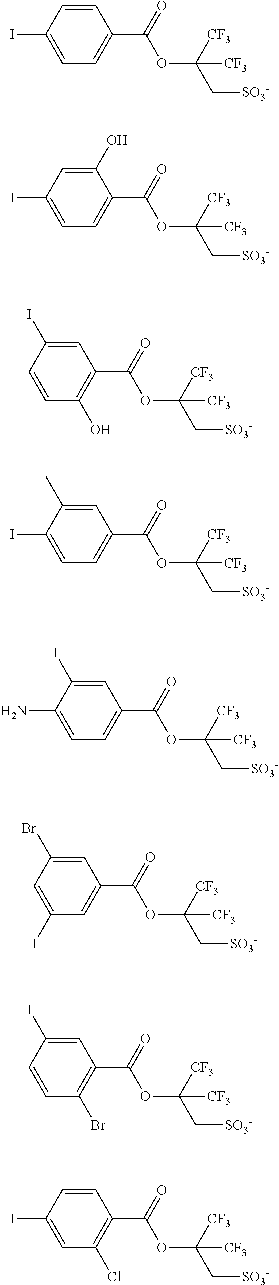

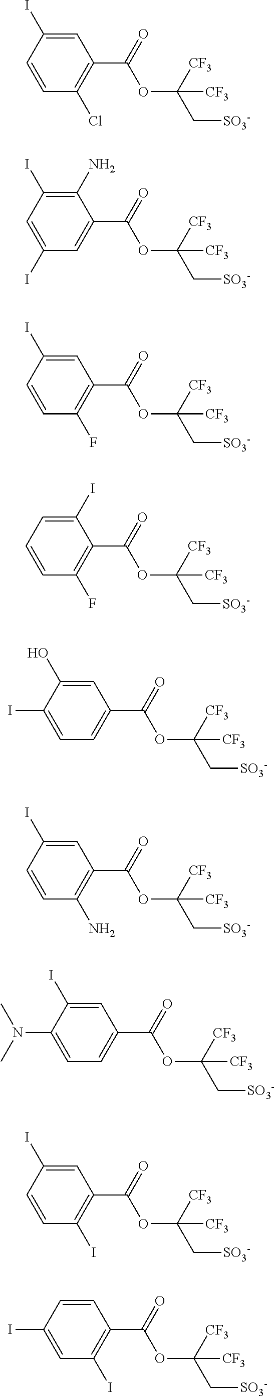

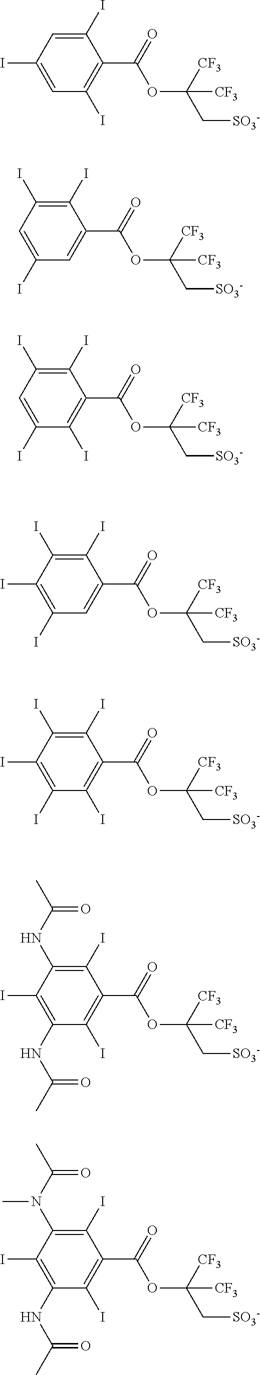

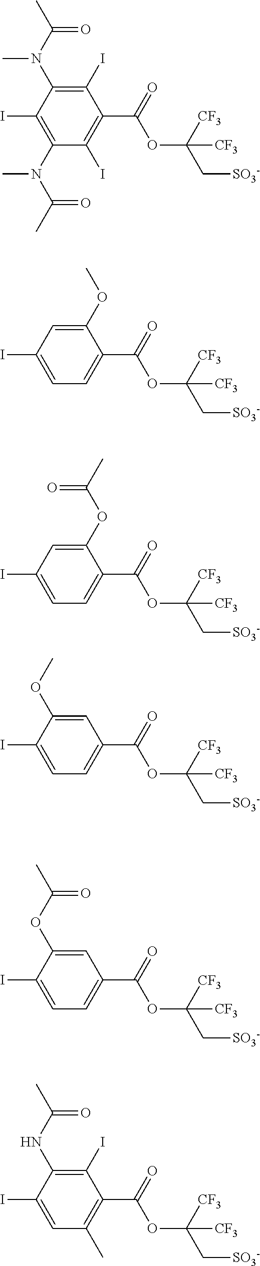

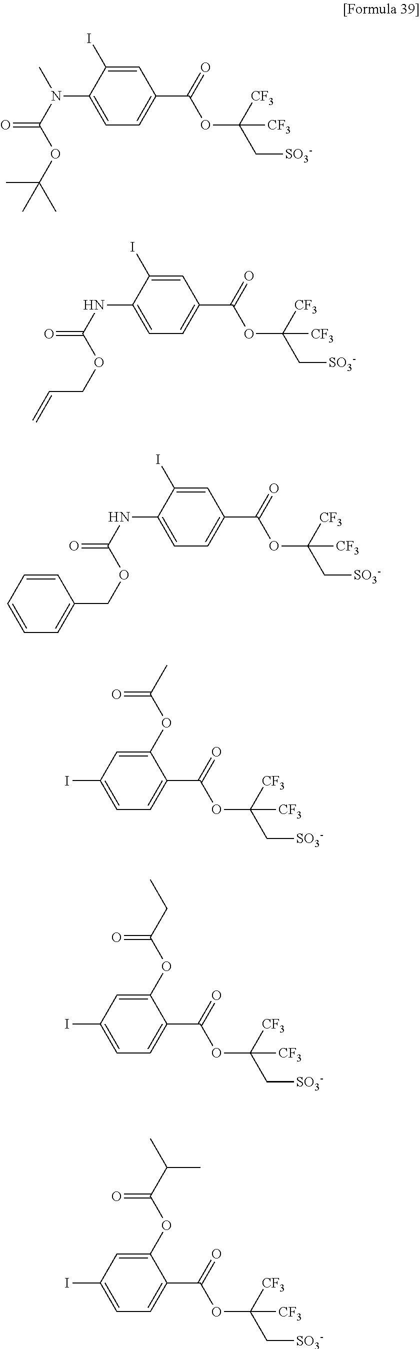

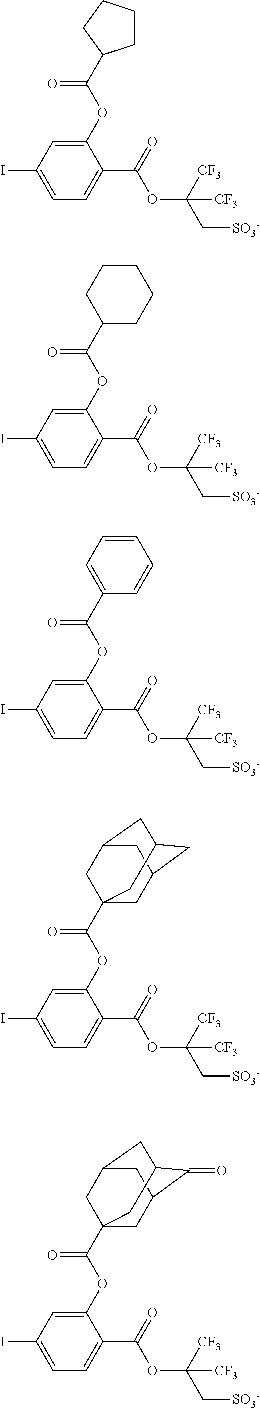

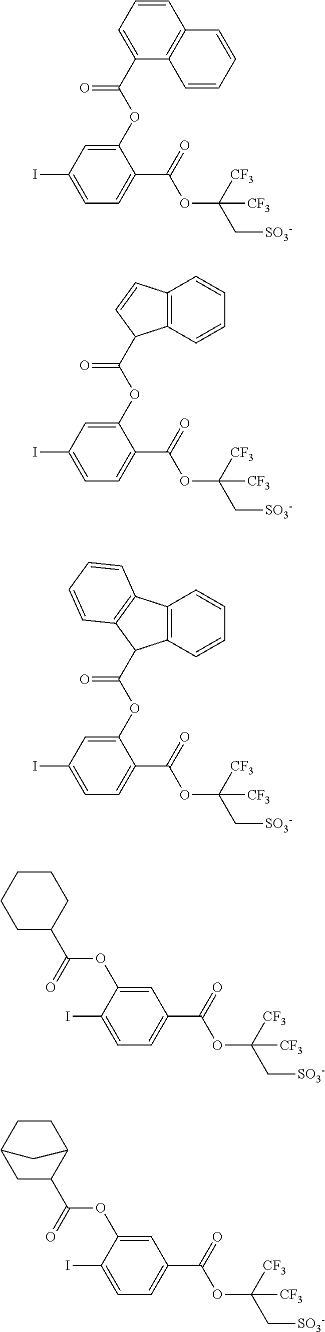

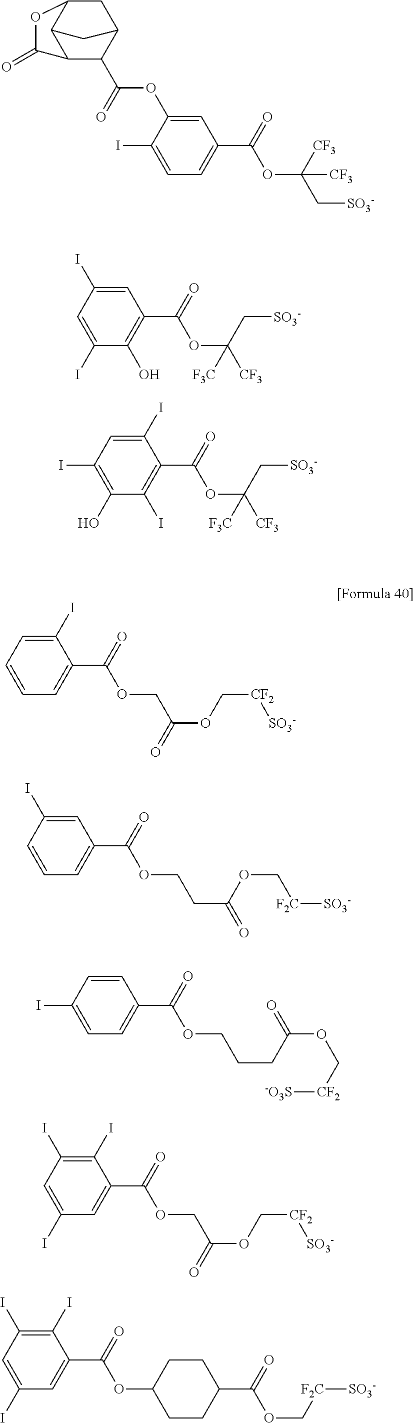

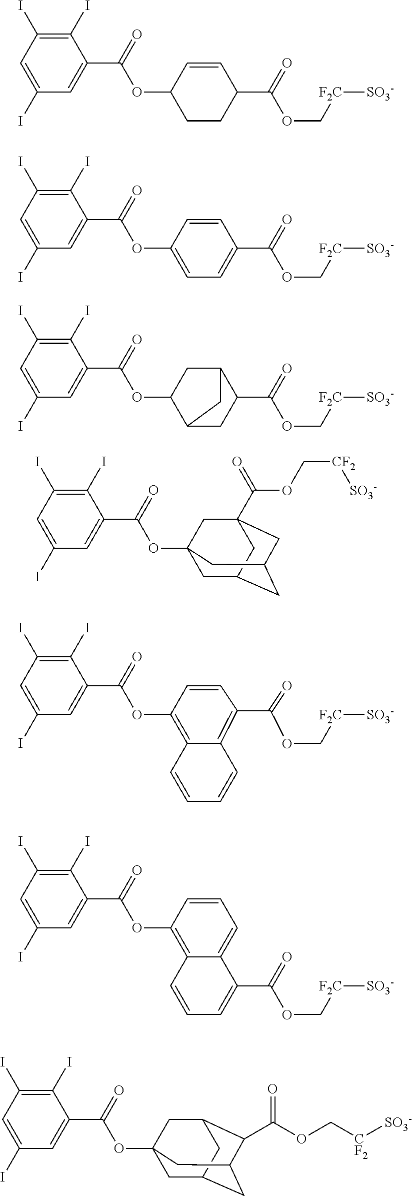

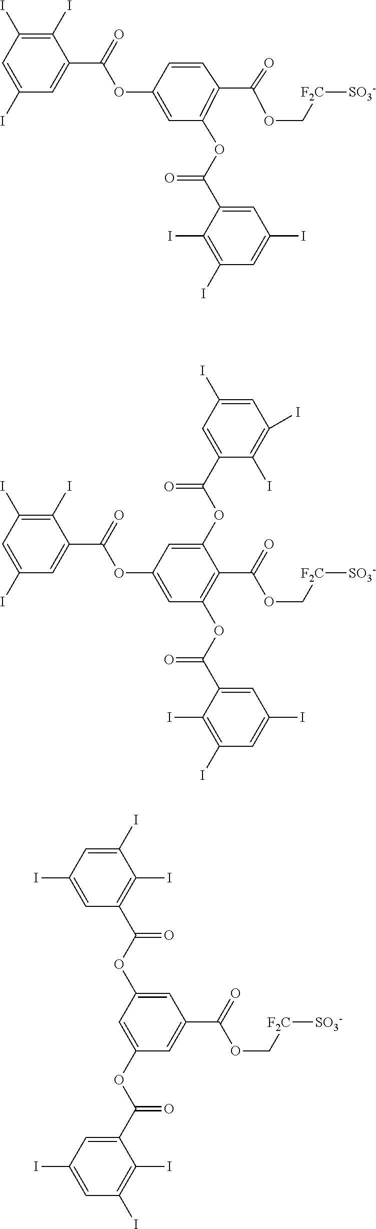

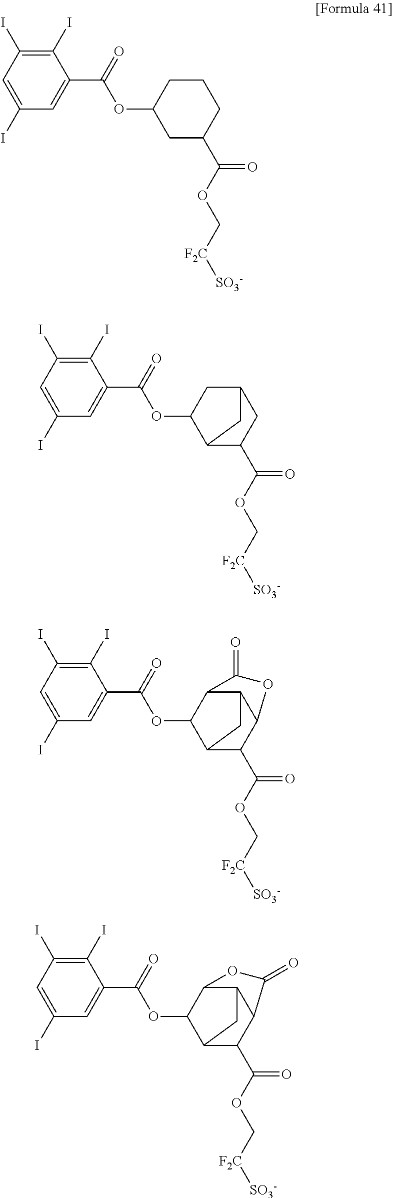

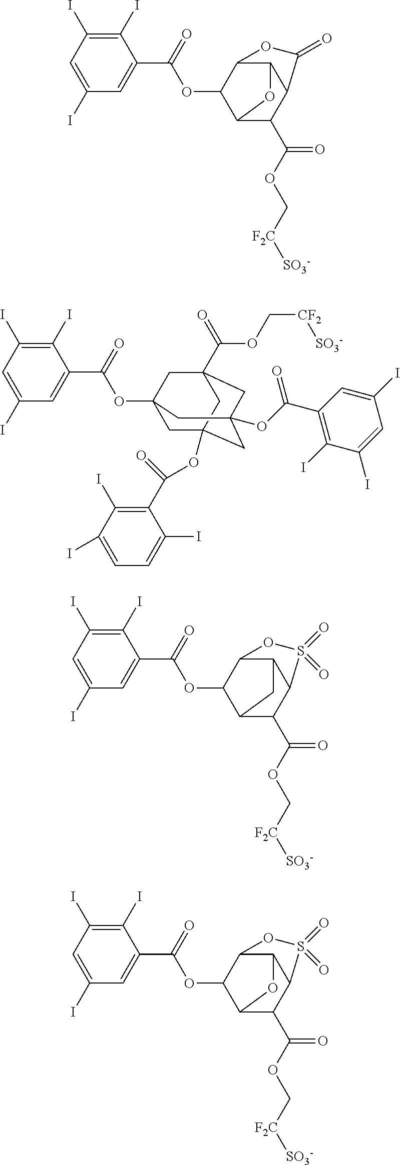

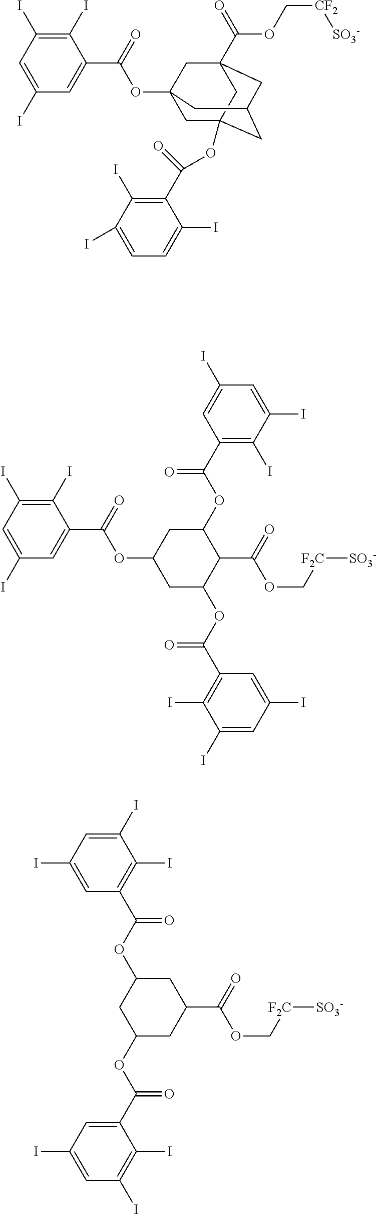

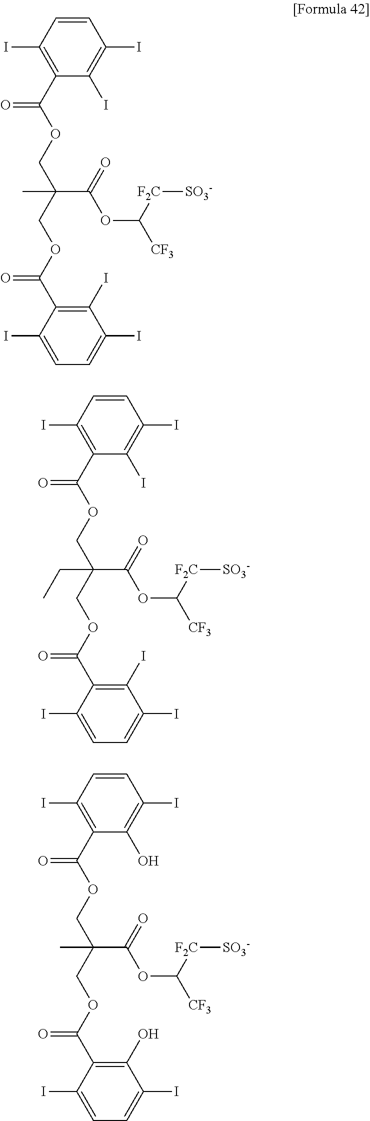

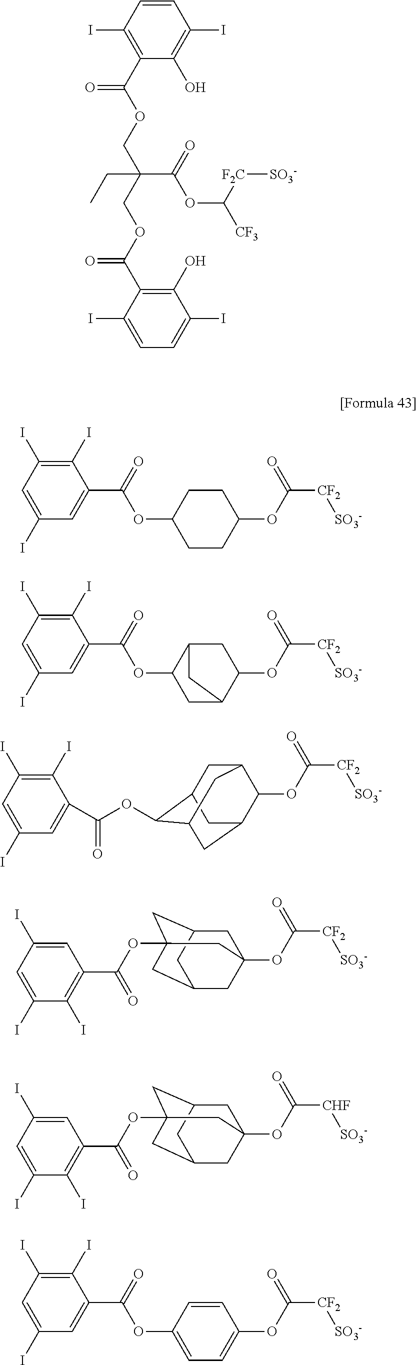

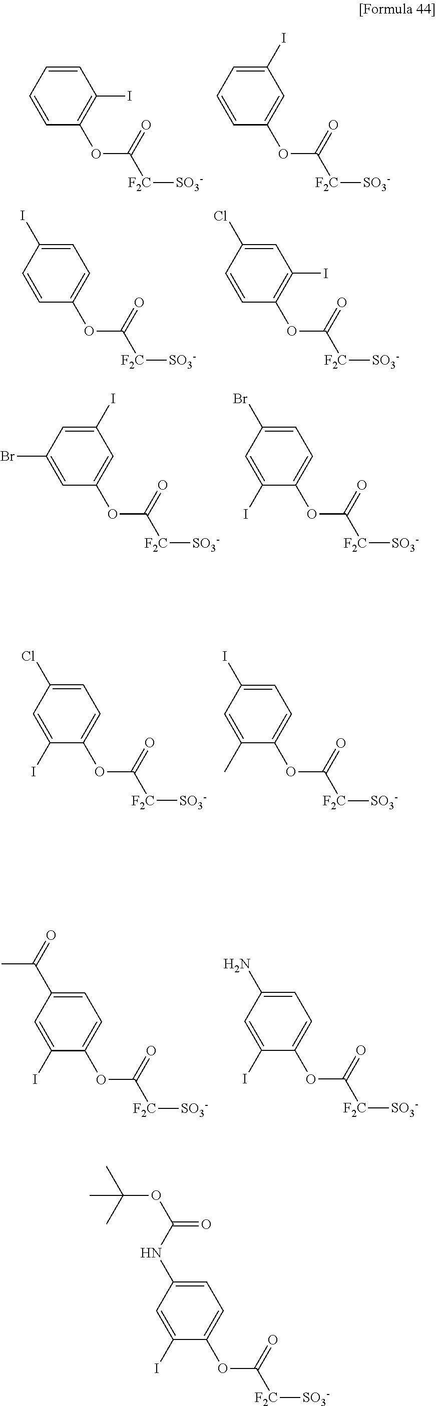

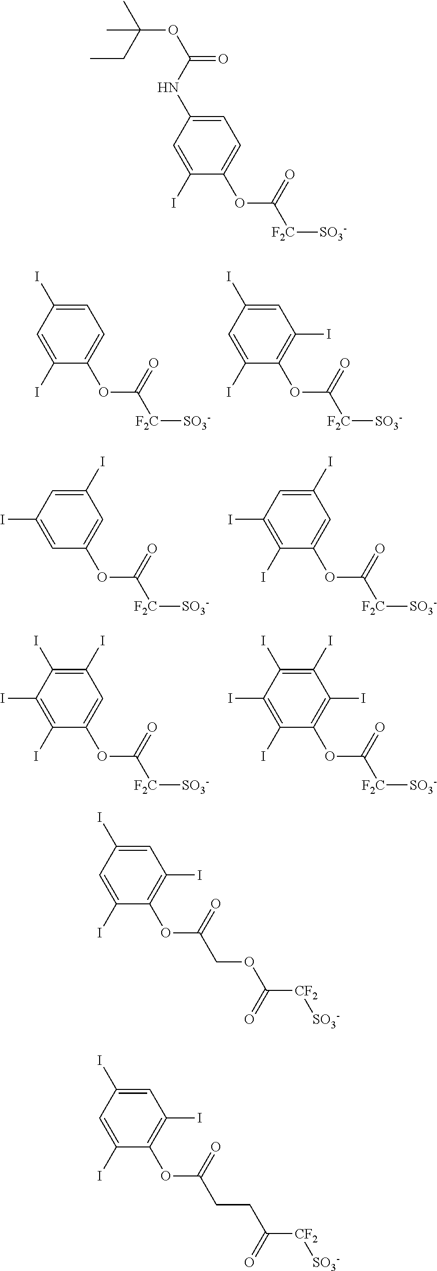

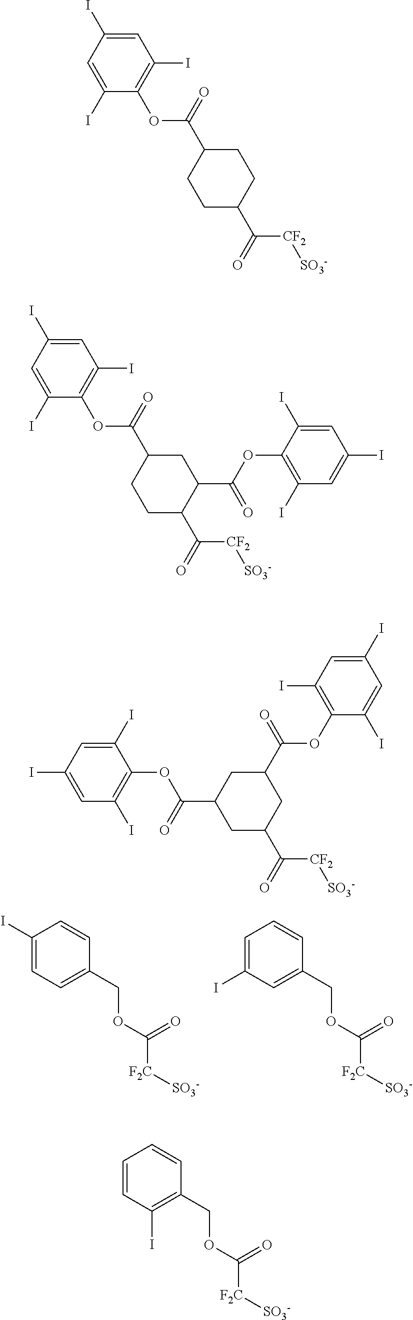

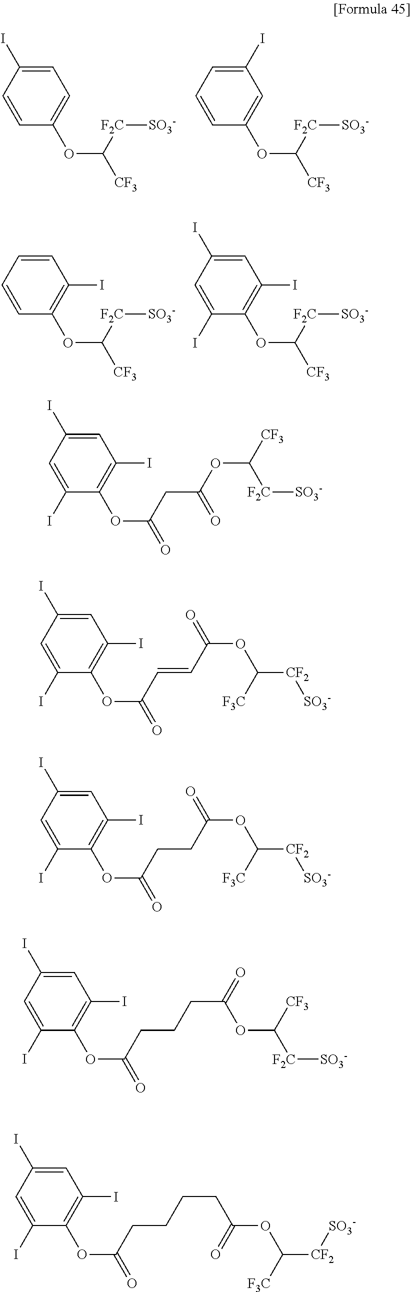

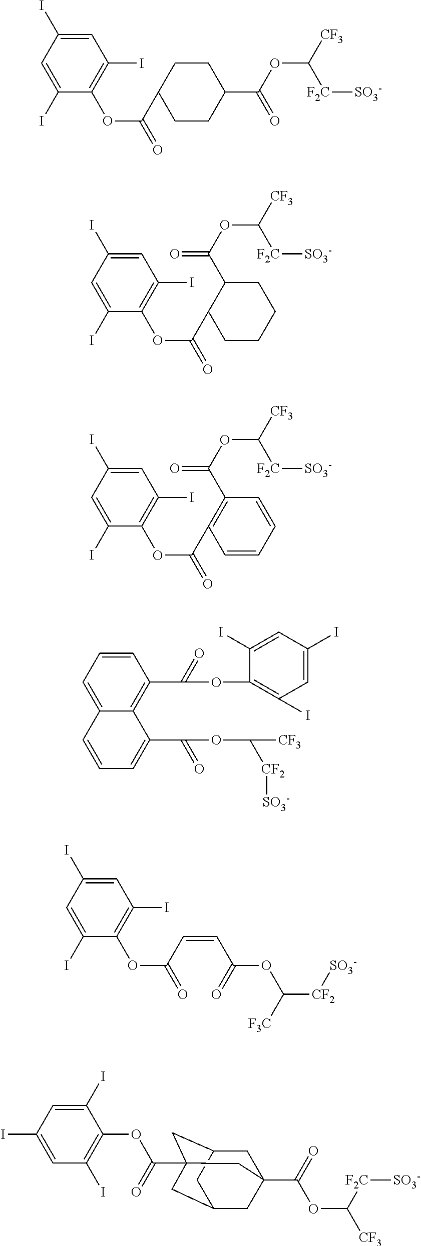

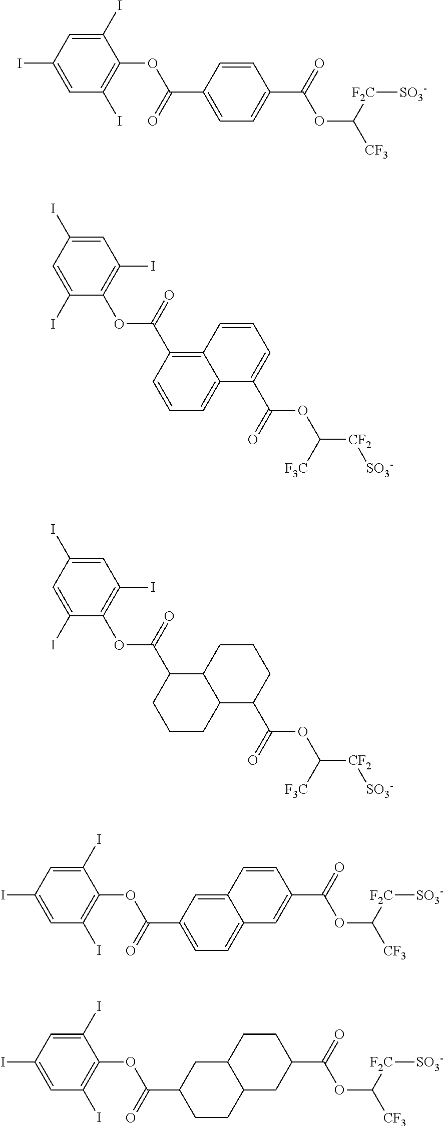

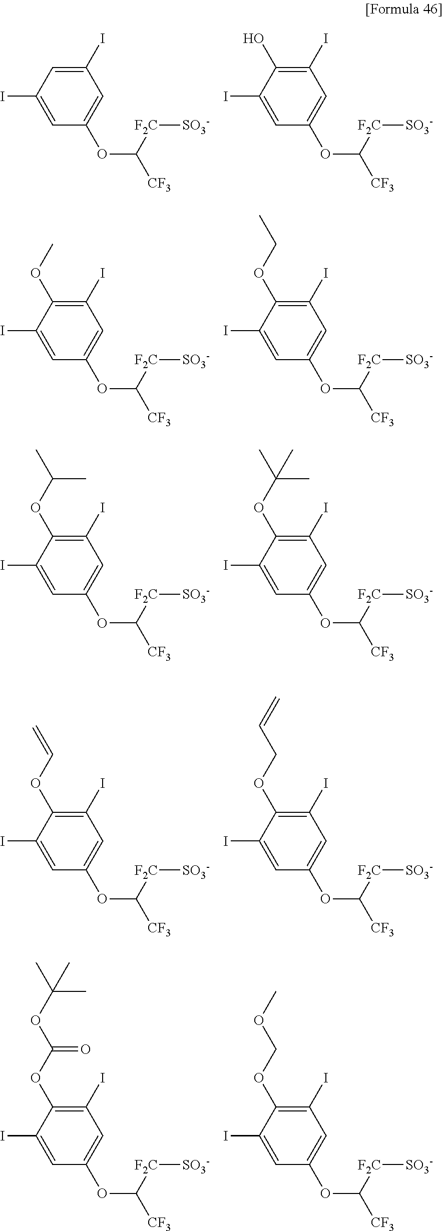

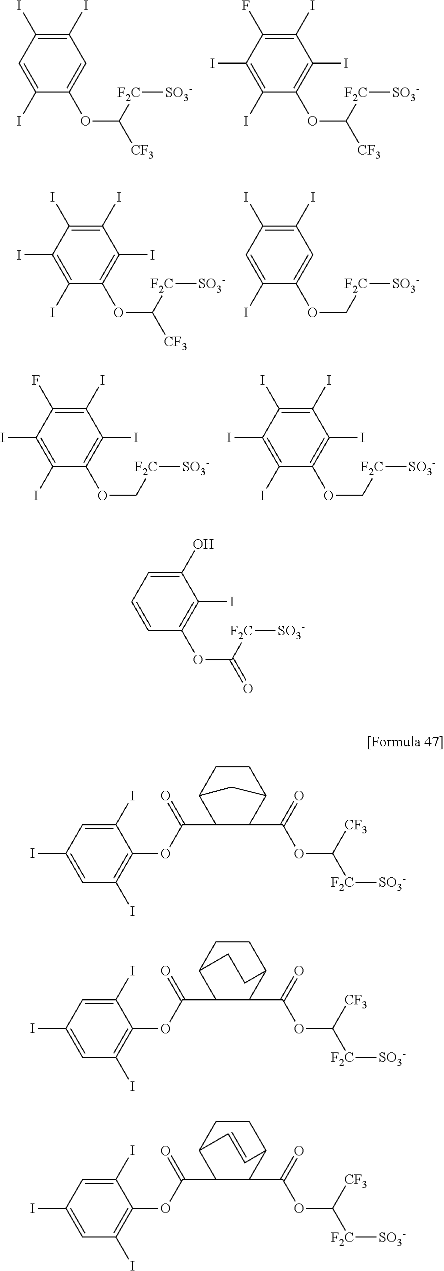

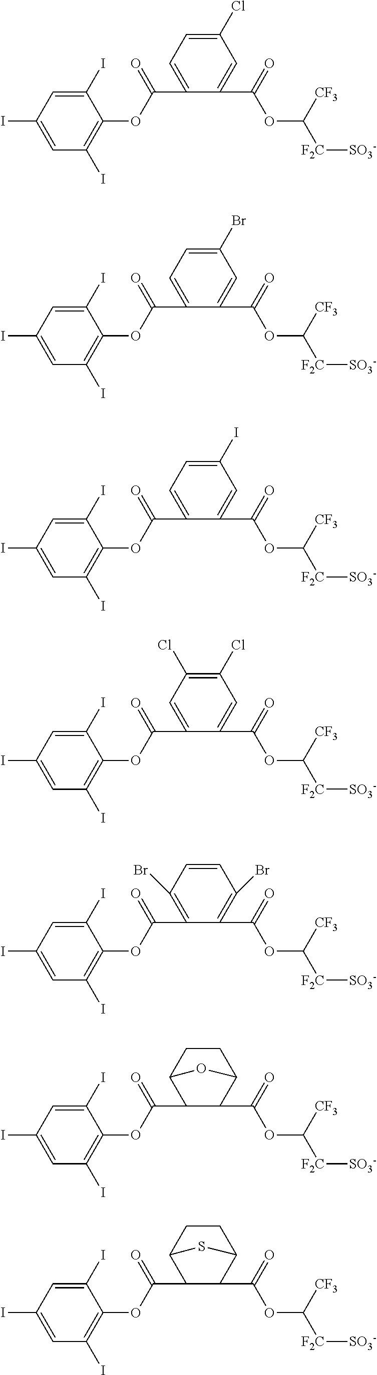

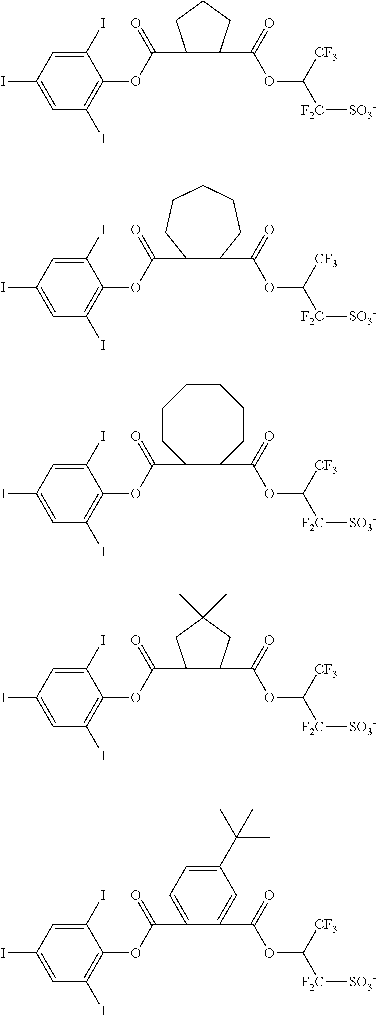

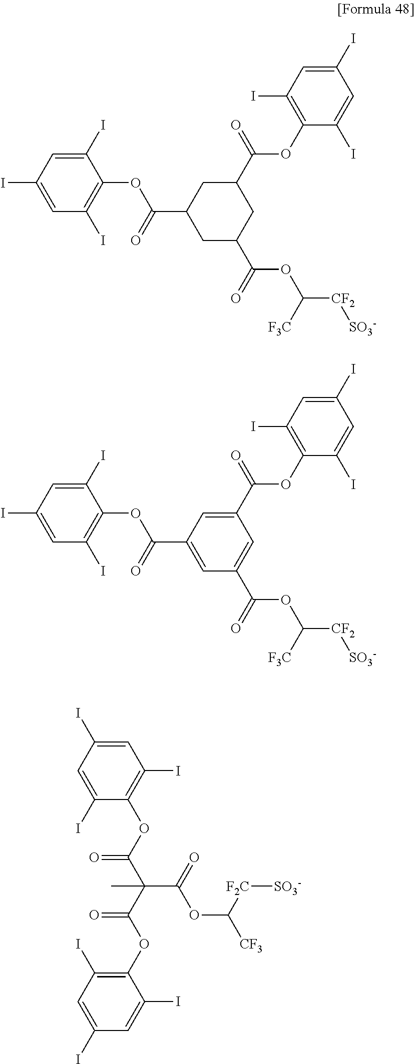

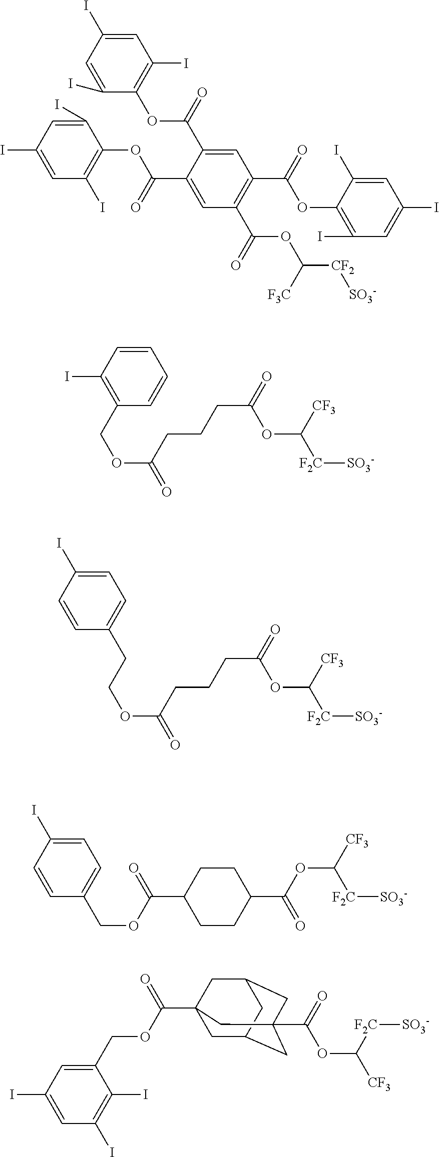

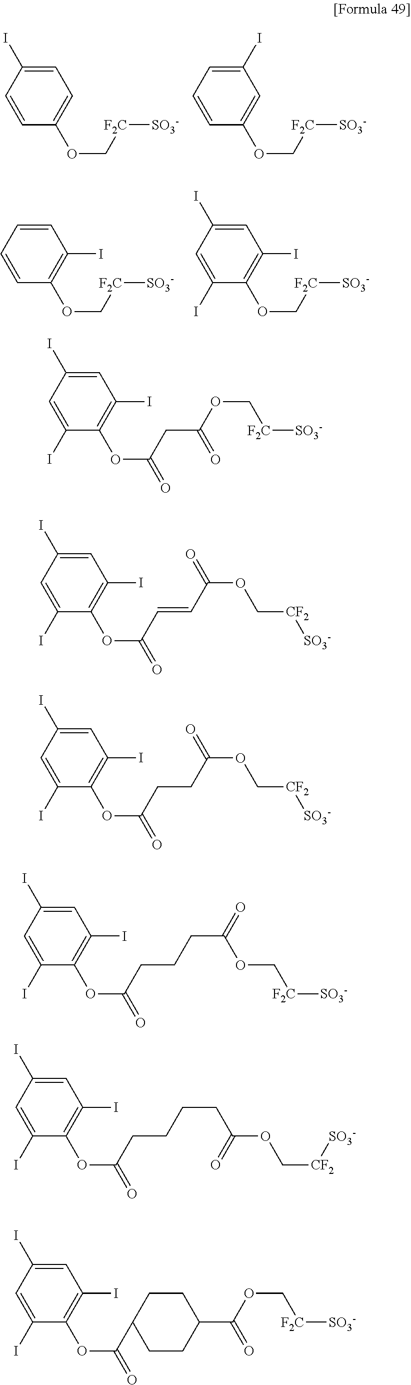

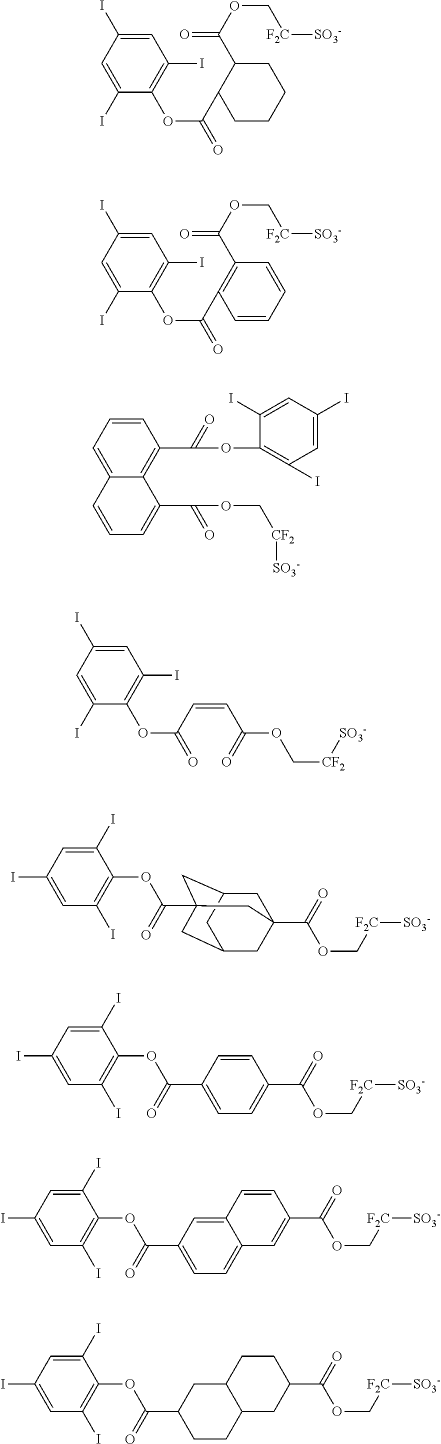

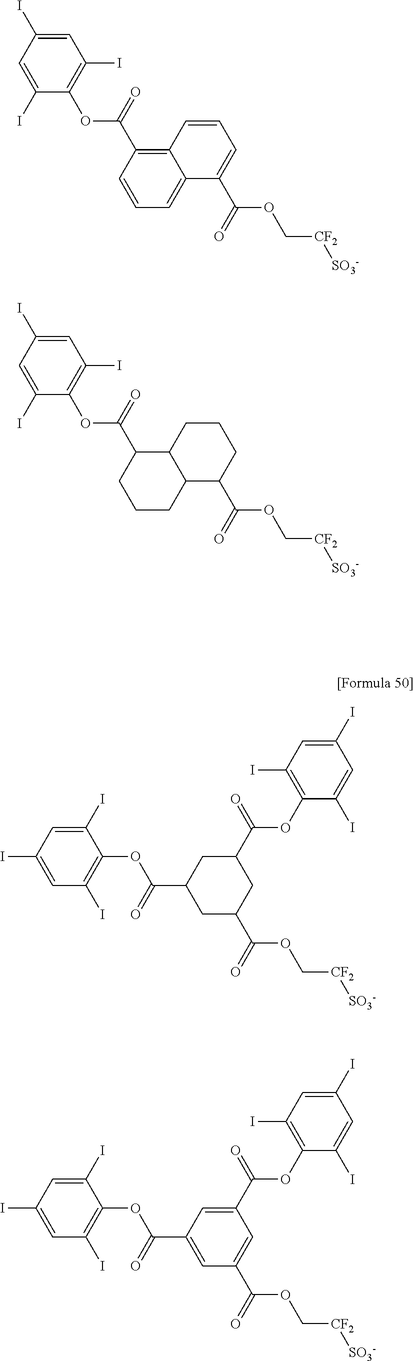

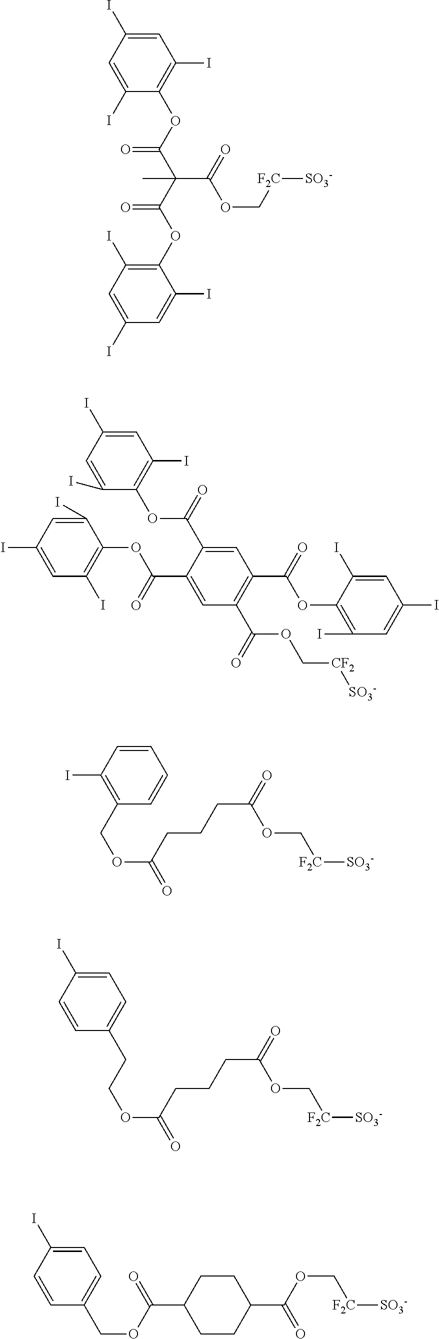

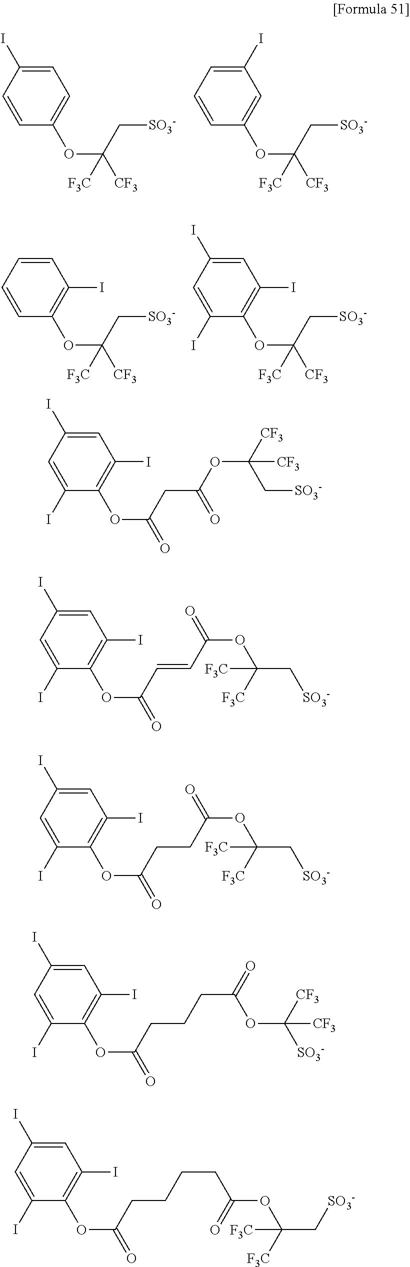

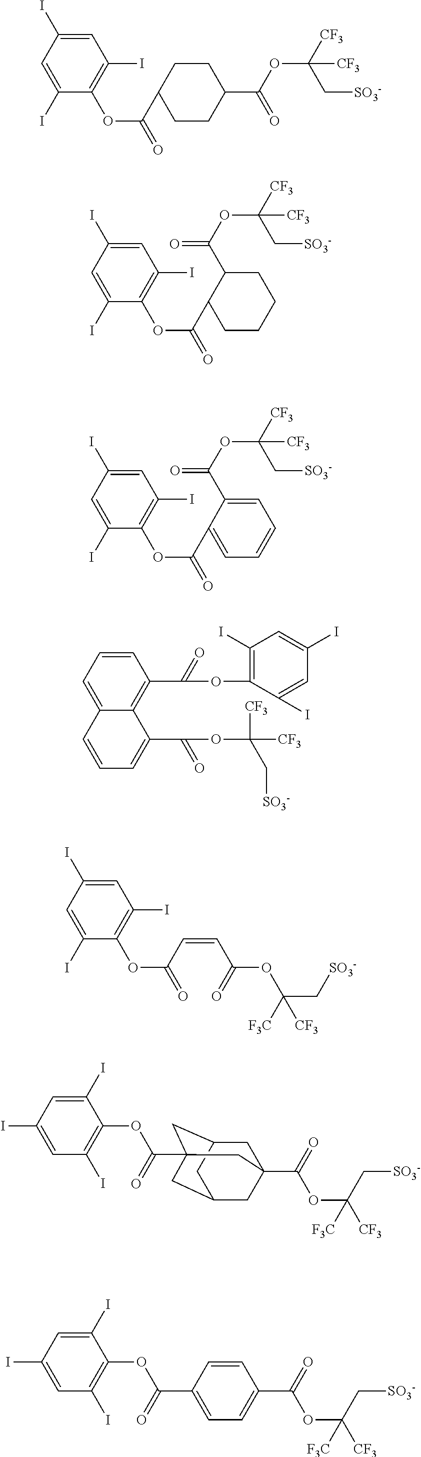

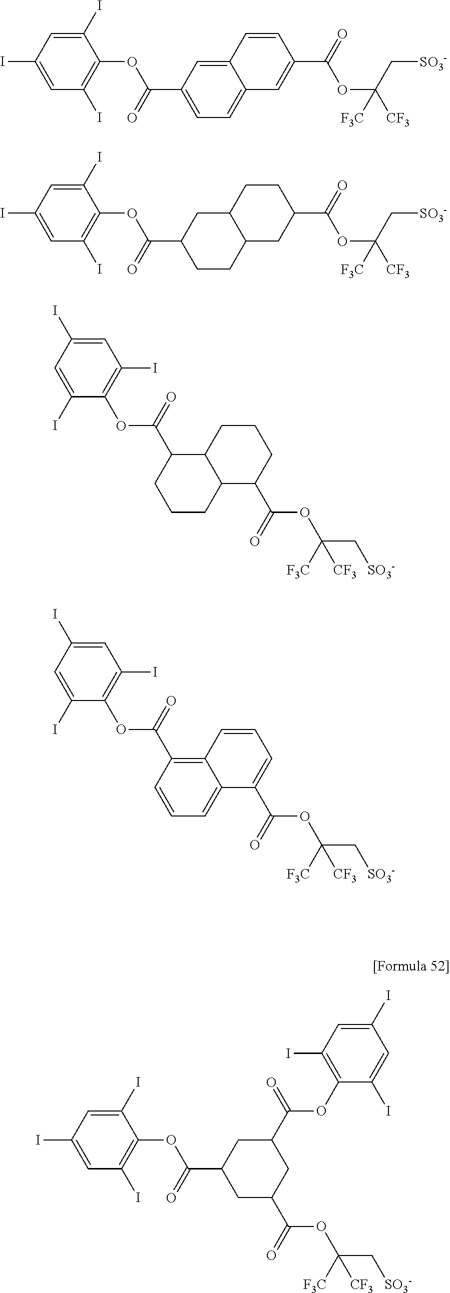

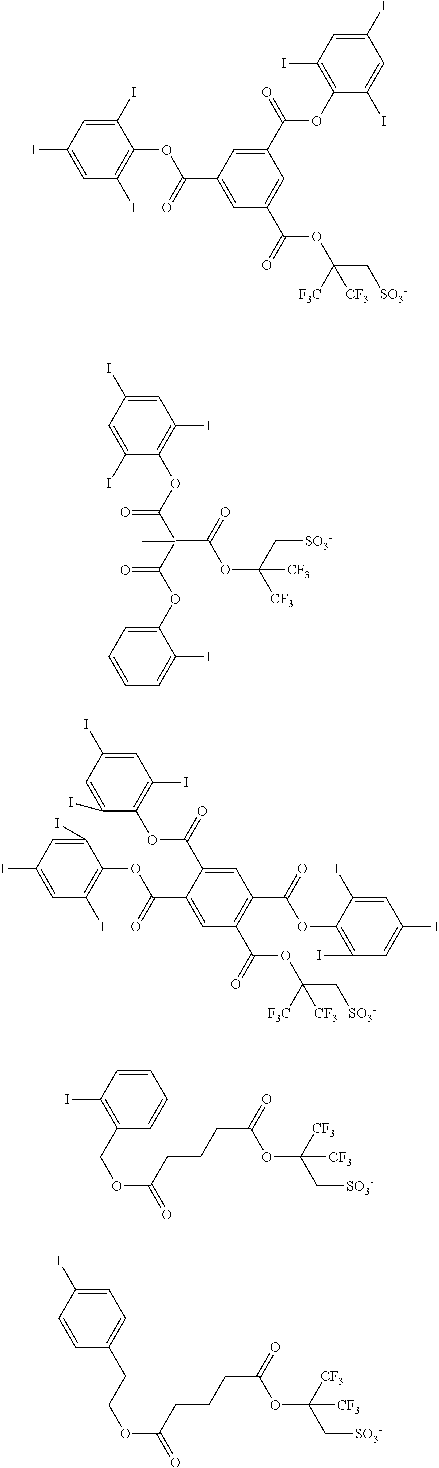

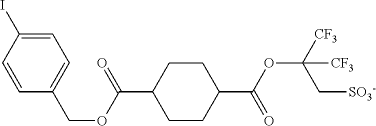

As the onium cation moieties in the radiation-sensitive acid generators represented by the formulas (A-1) and (A-2), an onium cation moiety in a structural unit a1 and a structural unit a2 of a radiation-sensitive acid generating resin can be suitably employed.

The radiation-sensitive acid generators represented by the above formulas (A-1) and (A-2) can also be synthesized by a known method, particularly by a salt exchange reaction. A known radiation-sensitive acid generator may also be used as long as the effect of the present invention is not impaired.

These radiation-sensitive acid generators may be used alone or in combination of two or more thereof. The content of the radiation-sensitive acid generator is preferably 3 parts by mass or more, more preferably 5 parts by mass or more, and still more preferably 7 parts by mass or more based on 100 parts by mass of the base resin (when a radiation-sensitive acid generating resin and a resin described below are contained, the total amount of them is taken as the basis). The content is preferably 20 parts by mass or less, more preferably 15 parts by mass or less, and still more preferably 13 parts by mass or less based on 100 parts by mass of the resin. This makes it possible to exhibit superior sensitivity or CDU performance when forming a resist pattern.

### <Acid Diffusion Controlling Agent>

The acid diffusion controlling agent contains an organic acid anion moiety and an onium cation moiety and generates an acid having a higher pKa than an acid to be generated from the radiation-sensitive acid generator through irradiation with radiation. The acid diffusion controlling agent is preferably represented by the following formula (S-1) or (S-2).

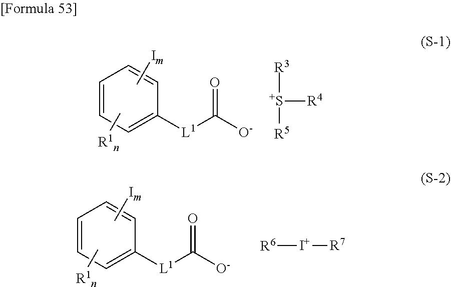

In the formulas (S-1) and (S-2), R¹ is a hydrogen atom, a hydroxy group, a fluorine atom, a chlorine atom, an amino group, a nitro group, or a cyano group; or an alkyl group having 1 to 6 carbon atoms, an alkoxy group having 1 to 6 carbon atoms, an acyloxy group having 2 to 6 carbon atoms, or an alkylsulfonyloxy group having 1 to 4 carbon atoms, which may be substituted with a halogen atom; or —NR^{1A}—c(═O)—R^{1B} or —NR^{1A}—C(═O)—O—R^{1B}. R^{1A} is a hydrogen atom or an alkyl group having 1 to 6 carbon atoms, and RIB is an alkyl group having 1 to 6 carbon atoms or an alkenyl group having 2 to 8 carbon atoms.

The alkyl group having 1 to 6 carbon atoms may be linear, branched, or cyclic, and examples thereof include a methyl group, an ethyl group, a n-propyl group, an isopropyl group, a cyclopropyl group, a n-butyl group, an isobutyl group, a sec-butyl group, a tert-butyl group, a cyclobutyl group, a n-pentyl group, a cyclopentyl group, a n-hexyl group, and a cyclohexyl group. Examples of the alkyl moiety of the alkoxy group having 1 to 6 carbon atoms, the acyloxy group having 2 to 7 carbon atoms, and the alkoxycarbonyl group having 2 to 7 carbon atoms include those the same as the examples of the alkyl group described above, and examples of the alkyl moiety of the alkylsulfonyloxy group having 1 to 4 carbon atoms include those having 1 to 4 carbon atoms among the examples of the alkyl group described above. The alkenyl group having 2 to 8 carbon atoms may be linear, branched, or cyclic, and examples thereof include a vinyl group, a 1-propenyl group, and a 2-propenyl group. Among them, a fluorine atom, a chlorine atom, a hydroxy group, an amino group, an alkyl group having 1 to 3 carbon atoms, an alkoxy group having 1 to 3 carbon atoms, an acyloxy group having 2 to 4 carbon atoms, —NR^{1A}—C(═O)—R^{1B}, and —NR^{1A}—C(═O)—O—R^{1B} are preferable as R¹.

R³, R⁴, R⁵, R⁶, and R⁷ are each independently a monovalent hydrocarbon group having 1 to 20 carbon atoms and optionally containing a heteroatom. When the onium cation moiety of the acid diffusion controlling agent has a fluorine atom, at least one of R³, R⁴, and R⁵ contains one or more fluorine atoms, and at least one of R⁶ and R⁷ contains one or more fluorine atoms. Any two of R³, R⁴, and R⁵ may be bonded to each other to form a ring together with the sulfur atom to which they are bonded. The monovalent hydrocarbon group may be linear, branched, or cyclic, and examples thereof include an alkyl group having 1 to 12 carbon atoms, an alkenyl group having 2 to 12 carbon atoms, an alkynyl group having 2 to 12 carbon atoms, an aryl group having 6 to 20 carbon atoms, and an aralkyl group having 7 to 12 carbon atoms. Some or all of the hydrogen atoms of these groups may be replaced by a hydroxy group, a carboxy group, a halogen atom, a cyano group, an amide group, a nitro group, a mercapto group, a sultone group, a sulfone group, or a sulfonium salt-containing group, and some of the carbon atoms of these groups may be replaced by an ether linkage, an ester linkage, a carbonyl group, a carbonate group, or a sulfonic acid ester linkage.

L¹ is a single bond or a divalent linking group having 1 to 20 carbon atoms, and may contain an ether linkage, a carbonyl group, an ester linkage, an amide linkage, a sultone ring, a lactam ring, a carbonate linkage, a halogen atom, a hydroxy group, or a carboxy group.

m and n are integers satisfying 0≤m≤5, 0≤n≤3, and 0≤m+n≤5, and preferably integers satisfying 1 m 3 and 0≤n≤2.

Examples of the organic acid anion moiety of the acid diffusion controlling agent represented by the above formula (S-1) or (S-2) include, but are not limited to, those shown below. While all of those shown below are organic acid anion moieties having an iodine-substituted aromatic ring structure, organic acid anion moieties having no iodine-substituted aromatic ring structure that can be suitably employed include structures in which the iodine atoms in the formulas shown below are replaced by an atom or group other than an iodine atom such as a hydrogen atom or other substituent.

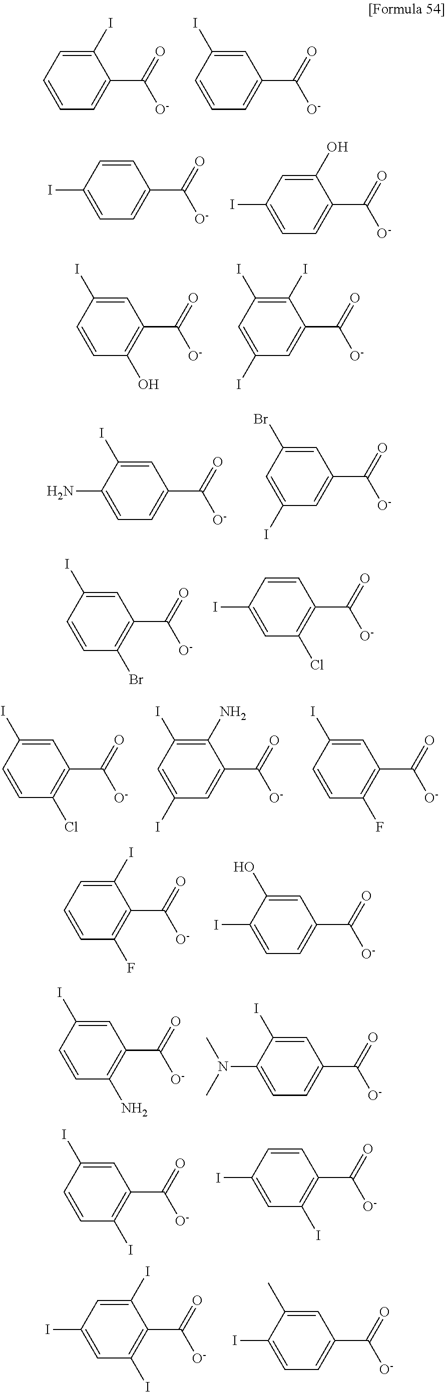

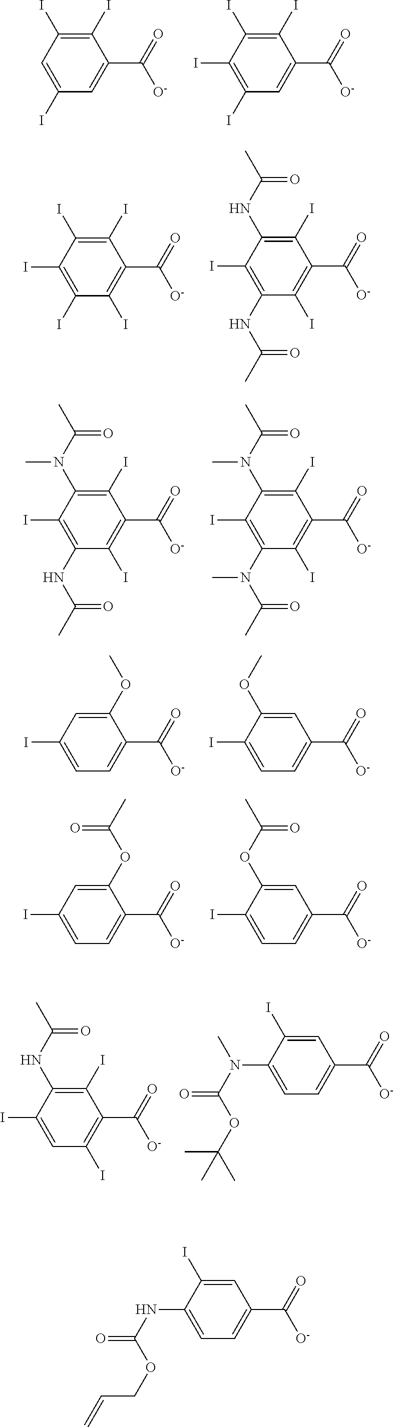

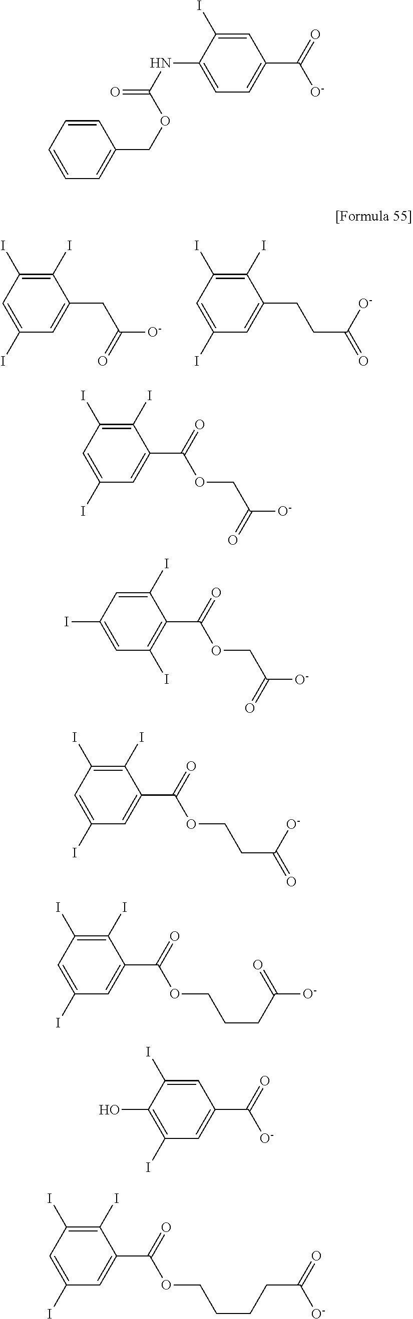

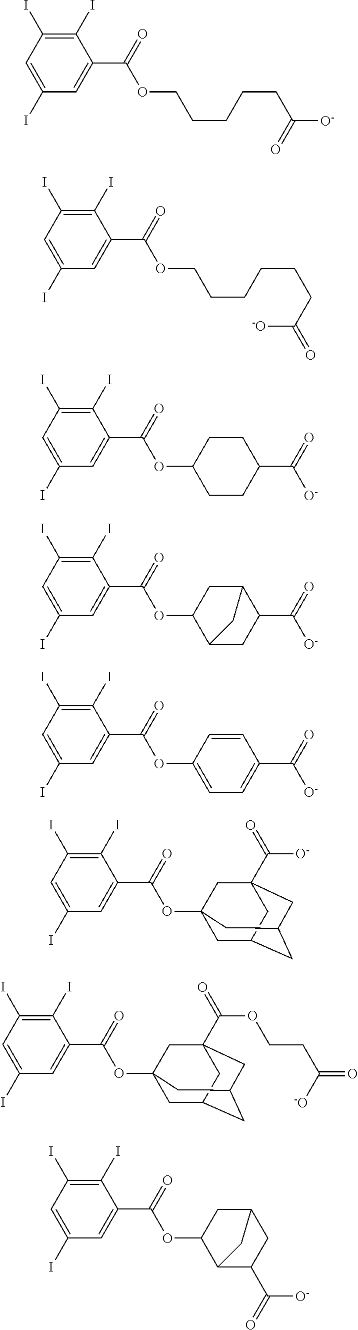

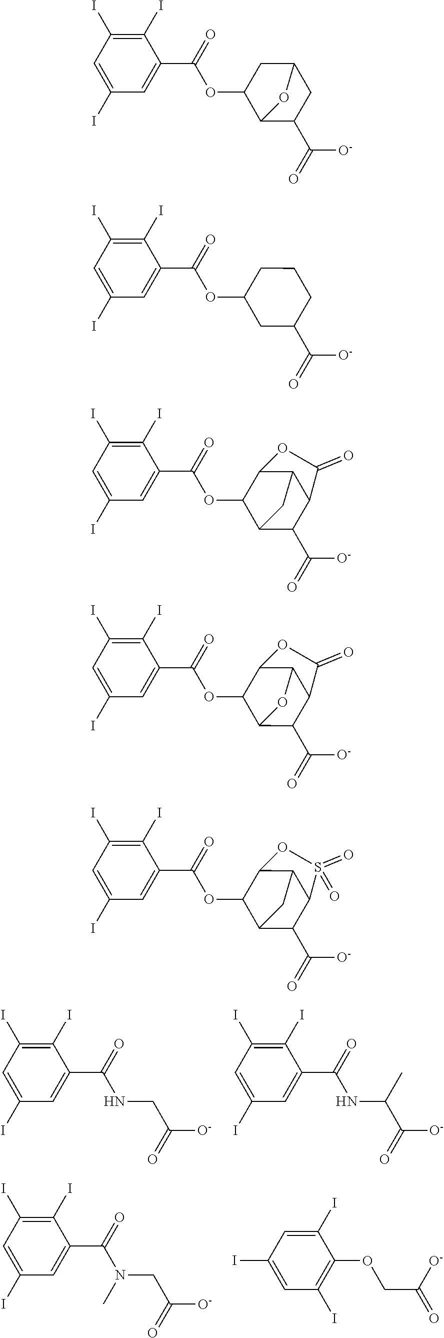

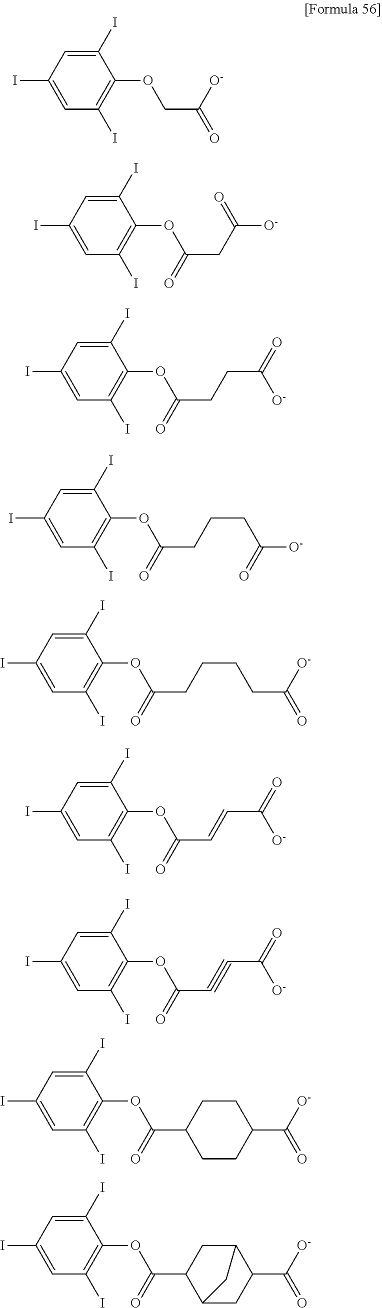

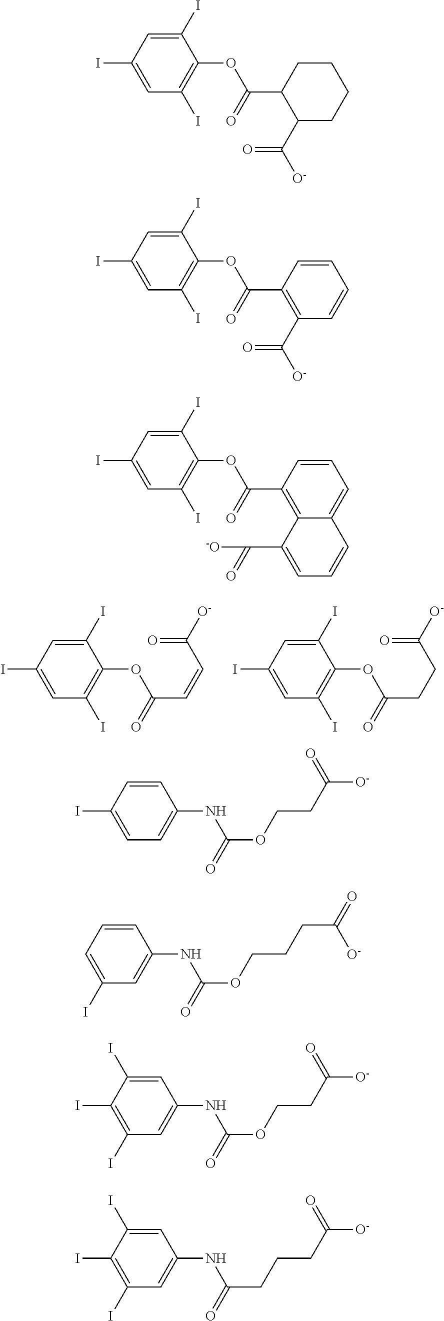

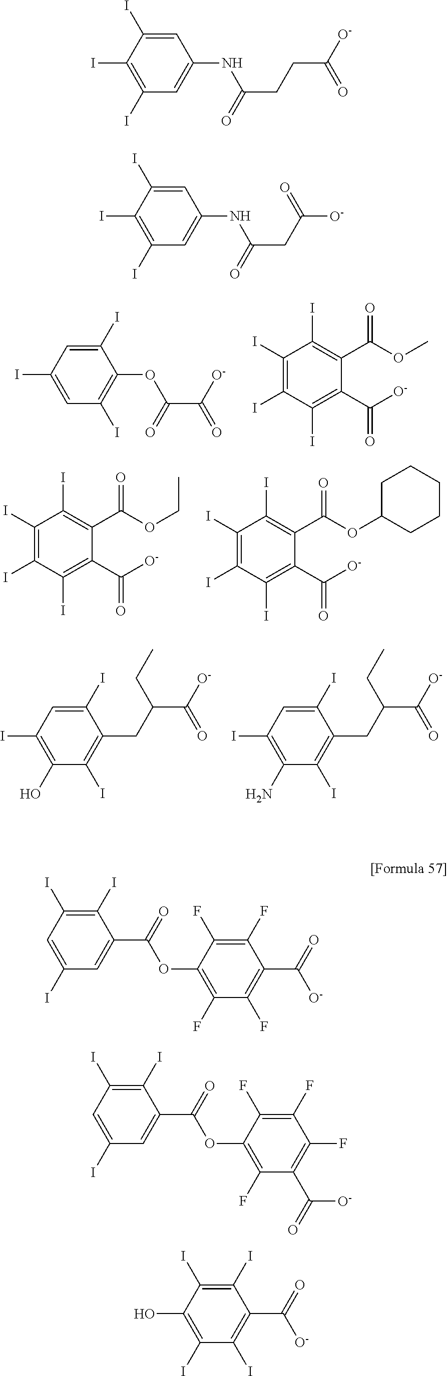

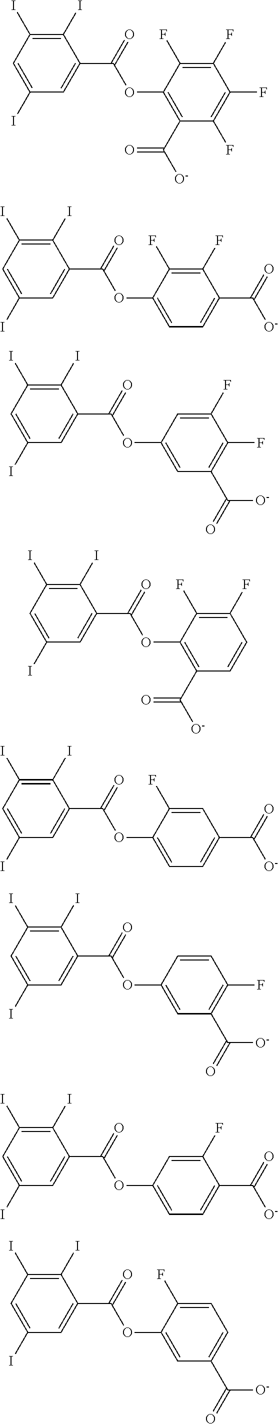

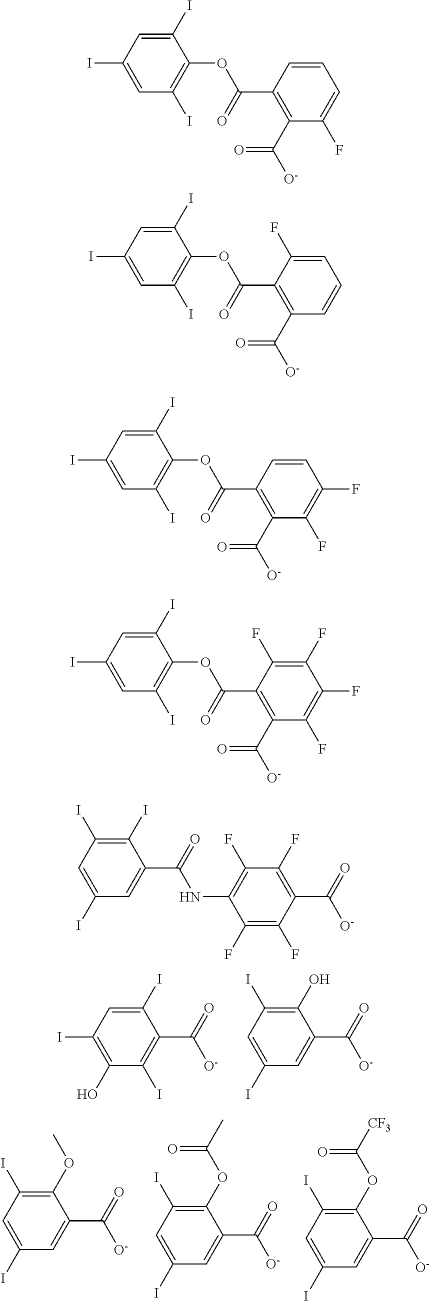

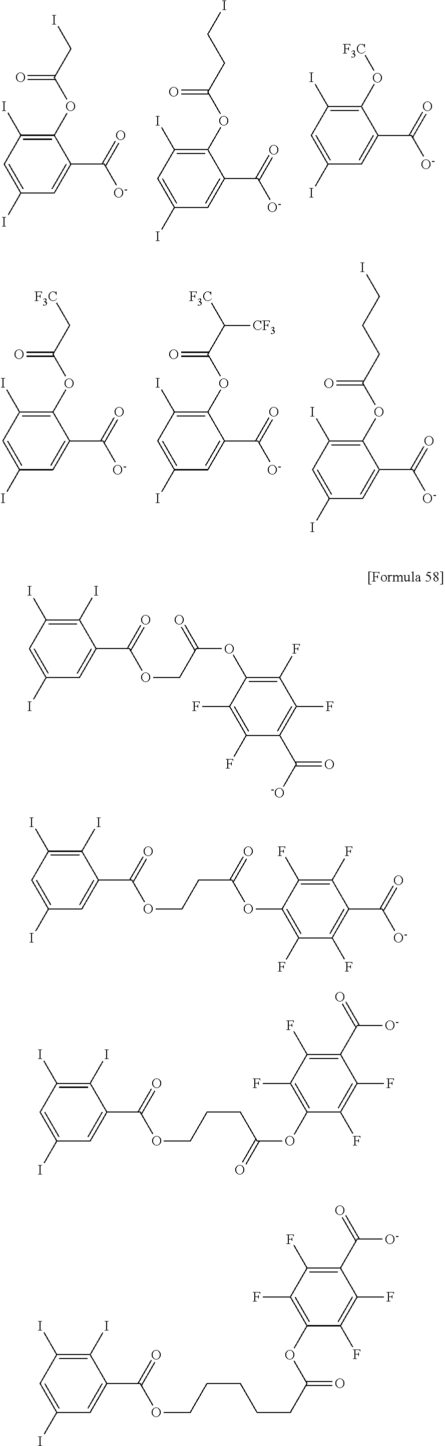

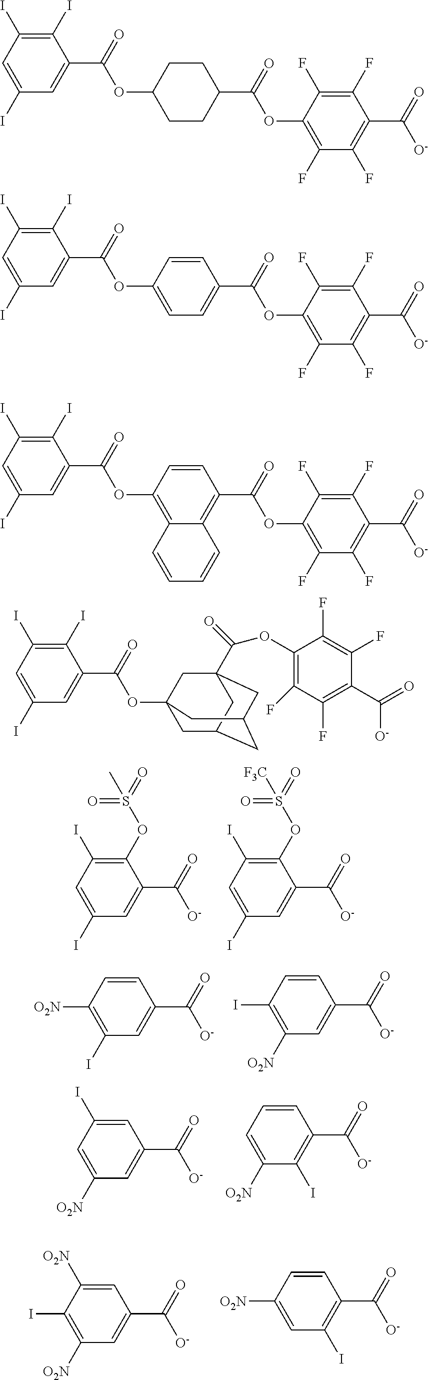

As the onium cation moieties in the acid diffusion controlling agents represented by the formulas (S-1) and (S-2), onium cation moieties in the structural unit a1 and the structural unit a2 of a radiation-sensitive acid generating resin can be suitably employed.

The acid diffusion controlling agents represented by the formulas (S-1) and (S-2) can also be synthesized by a known method, particularly by a salt exchange reaction. A known acid diffusion controlling agent may also be used as long as the effect of the present invention is not impaired.

These acid diffusion controlling agents may be used singly or two or more of them may be used in combination. The content of the acid diffusion controlling agent is preferably mass % or more, more preferably 15 mass % or more, and still more preferably 20 mass % or more based on the content of the radiation-sensitive acid generator (when a radiation-sensitive acid generating resin is contained, the total amount with the content of the structural units a1 and a2 in 100 parts by mass of the radiation-sensitive acid generating resin is taken as the basis). The content is preferably 100 mass % or less, more preferably 80 mass % or less, and still more preferably 60 mass % or less. This makes it possible to exhibit superior sensitivity or CDU performance when forming a resist pattern.

### <Resin>

The resin is a component contained in the radiation-sensitive resin composition as a base resin when the onium salt is at least one selected from the group consisting of a radiation-sensitive acid generator and an acid diffusion controlling agent. The resin contains a structural unit having a phenolic hydroxy group and a structural unit having an acid-dissociable group. Further, the resin may contain a structural unit containing a hydroxy group other than the phenolic hydroxy group, a carboxy group, a lactone ring, an ether group, an ester group, a carbonyl group, or a cyano group. Examples of the structural unit contained in the resin include structural units b1 and b2, a structural unit c, and a structural unit d other than the structural units a1 and a2 having an organic acid anion moiety and an onium cation moiety in the radiation-sensitive acid generating resin. The content of each structural unit in the resin is the same as the content of each structural unit in the radiation-sensitive acid generating resin except that the structural units a1 and a2 of the radiation-sensitive acid generating resin are not contained.

The content of the resin is preferably 70 mass % or more, more preferably 80 mass % or more, and still more preferably 85 mass % or more based on the amount of the radiation-sensitive resin composition excluding the solvent.

### (Method for Synthesizing Resin)

The resin can be synthesized by the same method as the method for synthesizing the radiation-sensitive acid generating resin as the base resin described above.

<Another Resin>

The radiation-sensitive resin composition according to the present embodiment may contain, as another resin, a resin having higher content by mass of fluorine atoms than the above-described base resin (hereinafter, also referred to as a “high fluorine-content resin”). When the radiation-sensitive resin composition contains the high fluorine-content resin, the high fluorine-content resin can be localized in the surface layer of a resist film compared to the base resin, which as a result makes it possible to control the state of the resist film surface and the component distribution in the resist film to a desired state.

The high fluorine-content resin preferably has, for example, a structural unit represented by the following formula (6) (hereinafter, also referred to as “structural unit e”), and may have the structural units b1, b2, c and d in the base resin as necessary.

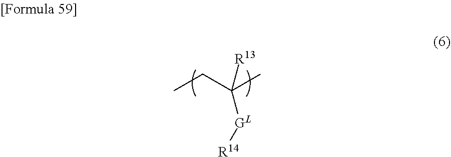

In the above formula (6), R¹³ is a hydrogen atom, a methyl group, or a trifluoromethyl group; G^{L} is a single bond, an oxygen atom, a sulfur atom, —COO—, —SO₂ONH—, —CONH—, or —OCONH—; R¹⁴ is a monovalent fluorinated chain hydrocarbon group having a carbon number of 1 to 20, or a monovalent fluorinated alicyclic hydrocarbon group having a carbon number of 3 to 20.

As R¹³ as described above, in terms of the copolymerizability of monomers resulting in the structural unit e, a hydrogen atom or a methyl group is preferred, and a methyl group is more preferred.

As G^{L} as described above, in terms of the copolymerizability of monomers resulting in the structural unit e, a single bond or —COO— is preferred, and —COO— is more preferred.

Example of the monovalent fluorinated chain hydrocarbon group having a carbon number of 1 to 20 represented by R¹⁴ as described above includes a group in which a part of or all of hydrogen atoms in the straight or branched chain alkyl group having a carbon number of 1 to 20 is/are substituted with a fluorine atom.

Example of the monovalent fluorinated alicyclic hydrocarbon group having a carbon number of 3 to 20 represented by R¹⁴ as described above includes a group in which a part of or all of hydrogen atoms in the monocyclic or polycyclic hydrocarbon group having a carbon number of 3 to 20 is/are substituted with a fluorine atom.

The R¹⁴ as described above is preferably a fluorinated chain hydrocarbon group, more preferably a fluorinated alkyl group, and further preferably 2,2,2-trifluoroethyl group, 1,1,1,3,3,3-hexafluoropropyl group, 5,5,5-trifluoro-1,1-diethylpentyl group and 1,1,1,2,2,3,3-heptafluoro-6-methylheptan-4-yl group.

When the high fluorine-content resin has the structural unit e, the content of the structural unit e is preferably 50 mol % or more, more preferably 60 mol % or more, even more preferably 70 mol % or more with respect to the total amount of all the structural units constituting the high fluorine-content resin. The content is preferably 100 mol % or less, more preferably 95 mol % or less, even more preferably 90 mol % or less. When the content of the structural unit e is set to fall within the above range, the content by mass of fluorine atoms of the high fluorine-content resin can more appropriately be adjusted to further promote the localization of the high fluorine-content resin in the surface layer of a resist film.

The high fluorine-content resin may have a fluorine atom-containing structural unit represented by the following formula (f-1) (hereinafter, also referred to as a “structural unit f”) other than the structural unit e. When the high fluorine-content resin has the structural unit f, solubility in an alkaline developing solution is improved, and therefore generation of development defects can be prevented.

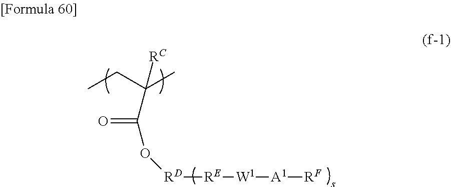

The structural unit f is classified into two groups: a unit having an alkali soluble group (x); and a unit having a group (y) in which the solubility into the alkaline developing solution is increased by the dissociation by alkali (hereinafter, simply referred as an “alkali-dissociable group”). In both cases of (x) and (y), R^{c} in the above formula (f-1) is a hydrogen atom, a fluorine atom, a methyl group, or a trifluoromethyl group; RD is a single bond, a hydrocarbon group having a carbon number of 1 to 20 with the valency of (s+1), a structure in which an oxygen atom, a sulfur atom, —NR^{dd}—, a carbonyl group, —COO— or —CONH— is connected to the terminal on R^{E} side of the hydrocarbon group, or a structure in which a part of hydrogen atoms in the hydrocarbon group is substituted with an organic group having a hetero atom; R^{dd} is a hydrogen atom, or a monovalent hydrocarbon group having a carbon number of 1 to 10; and s is an integer of 1 to 3.

When the structural unit f has the alkali soluble group (x), R^{F} is a hydrogen atom; A¹ is an oxygen atom, —COO—* or —SO₂O—*; * refers to a bond to R^{F}; W¹ is a single bond, a hydrocarbon group having a carbon number of 1 to 20, or a divalent fluorinated hydrocarbon group. When A¹ is an oxygen atom, W¹ is a fluorinated hydrocarbon group having a fluorine atom or a fluoroalkyl group on the carbon atom connecting to A¹. R^{E} is a single bond, or a divalent organic group having a carbon number of 1 to 20. When s is 2 or 3, a plurality of R^{E}, W¹, A¹ and R^{F} may be each identical or different. The affinity of the high fluorine-content resin into the alkaline developing solution can be improved by including the structural unit f having the alkali soluble group (x), and thereby prevent from generating the development defect. As the structural unit f having the alkali soluble group (x), particularly preferred is a structural unit in which A¹ is an oxygen atom and W¹ is a 1,1,1,3,3,3-hexafluoro-2,2-methanediyl group.

When the structural unit f has the alkali-dissociable group (y), R^{F} is a monovalent organic group having carbon number of 1 to 30; A¹ is an oxygen atom, —NR^{aa}—, —COO—*, or —SO₂O—*; R aa is a hydrogen atom, or a monovalent hydrocarbon group having a carbon number of 1 to 10; * refers to a bond to R^{F}; W¹ is a single bond, or a divalent fluorinated hydrocarbon group having a carbon number of 1 to 20; R^{E} is a single bond, or a divalent organic group having a carbon number of 1 to 20. When A¹ is —COO—* or —SO₂O—*, W¹ or R^{F} has a fluorine atom on the carbon atom connecting to A¹ or on the carbon atom adjacent to the carbon atom. When A¹ is an oxygen atom, W¹ and R^{E} are a single bond; RD is a structure in which a carbonyl group is connected at the terminal on R^{E} side of the hydrocarbon group having a carbon number of 1 to 20; and R^{F} is an organic group having a fluorine atom. When s is 2 or 3, a plurality of R^{E}, W¹, A¹ and R^{F} may be each identical or different. The surface of the resist film is changed from hydrophobic to hydrophilic in the alkaline developing step by including the structural unit f having the alkali-dissociable group (y). As a result, the affinity of the high fluorine-content resin into the alkaline developing solution can be significantly improved, and thereby prevent from generating the development defect more efficiently. As the structural unit f having the alkali-dissociable group (y), particularly preferred is a structural unit in which A¹ is —COO—*, and R^{F} or W¹, or both is/are a fluorine atom.

In terms of the copolymerizability of monomers resulting in the structural unit f, R^{c} is preferably a hydrogen atom or a methyl group, and more preferably a methyl group.

When R^{E} is a divalent organic group, R^{E} is preferably a group having a lactone structure, more preferably a group having a polycyclic lactone structure, and further preferably a group having a norbornane lactone structure.

When the high fluorine-content resin has the structural unit f, the content of the structural unit f is preferably 10 mol % or more, more preferably 20 mol % or more, even more preferably 30 mol % or more, and particularly preferably 35 mol % or more with respect to the total amount of all the structural units constituting the high fluorine-content resin. The content is preferably 90 mol % or less, more preferably 75 mol % or less, even more preferably 60 mol % or less. When the content of the structural unit f is set to fall within the above range, water repellency of a resist film during immersion exposure can further be improved.

The Mw of the high fluorine-containing resin is preferably 1,000 or more, more preferably 2,000 or more, still more preferably 3,000 or more, and particularly preferably or more. The Mw of the high fluorine-containing resin is preferably 50,000 or less, more preferably 30,000 or less, still more preferably 20,000 or less, and particularly preferably 15,000 or less.

The Mw/Mn of the high fluorine-containing resin is usually 1 or more, and more preferably 1.1 or more. The Mw/Mn of the high fluorine-containing resin is usually 5 or less, preferably 3 or less, more preferably 2 or less, and still more preferably 1.9 or less.

The content of the high fluorine-containing resin is preferably 1 parts by mass or more, more preferably 2 parts by mass or more, still more preferably 3 part by mass or more based on 100 parts by mass of the base resin (total amount when a radiation-sensitive acid-generating resin and a resin are included). The content of the high fluorine-containing resin is preferably 20 parts by mass or less, more preferably parts by mass or less, still more preferably 10 parts by mass or less. When the content of the high fluorine-content resin is set to fall within the above range, the high fluorine-content resin can more effectively be localized in the surface layer of a resist film, which as a result makes it possible to suppress elution of the upper portion of the pattern during development and enhance the rectangularity of the pattern. The radiation-sensitive resin composition may contain one kind of high fluorine-content resin or two or more kinds of high fluorine-content resins.

### (Method for Synthesizing High Fluorine-Content Resin)

The high fluorine-content resin can be synthesized by a method similar to the above-described method for synthesizing a base resin.

### <Compound>

The radiation-sensitive resin composition preferably contains, as a quencher, a compound having a structure in which an alkoxycarbonyl group is bonded to a nitrogen atom. Thanks to containing this compound, the diffusion length of a generated acid can be appropriately controlled and pattern-forming performance and CDU performance can be improved.

The compound is preferably represented by the following formula (1),

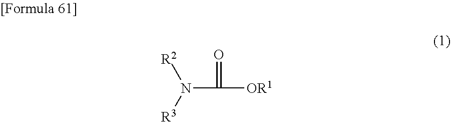

in the formula (1), R¹ is a branched alkyl group having 4 to 20 carbon atoms;

R² and R³ are each independently a hydrocarbon group having 1 to 20 carbon atoms, or R² and R³ are combined with each other and represent a heterocyclic ring having 3 to 20 ring members together with the nitrogen atom to which they are bonded.

As the branched alkyl group having 4 to 20 carbon atoms represented by R¹, a tertiary alkyl group having 4 to 10 carbon atoms is preferable, and a t-butyl group and a t-pentyl group are more preferable.

Examples of the hydrocarbon group having 1 to 20 carbon atoms represented by R² and R³ include a chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the chain hydrocarbon group having 1 to 20 carbon atoms include a linear or branched saturated hydrocarbon group having 1 to 20 carbon atoms and a linear or branched unsaturated hydrocarbon group having 1 to 20 carbon atoms.

Examples of the monovalent alicyclic hydrocarbon group having 3 to 20 carbon atoms include a monocyclic or polycyclic saturated hydrocarbon group and a monocyclic or polycyclic unsaturated hydrocarbon group. Preferred examples of the monocyclic saturated hydrocarbon groups include a cyclopentyl group, a cyclohexyl group, a cycloheptyl group, and a cyclooctyl group. Preferred examples of the polycyclic cycloalkyl groups include bridged alicyclic hydrocarbon groups such as a norbornyl group, an adamantyl group, a tricyclodecyl group, and a tetracyclododecyl group. It is to be noted that the bridged alicyclic hydrocarbon group refers to a polycyclic alicyclic hydrocarbon group in which two carbon atoms that constitute an alicyclic ring and not adjacent to each other are bonded by a bonding chain containing one or more carbon atoms.

Examples of the monovalent aromatic hydrocarbon groups having 6 to 20 carbon atoms include: aryl groups such as a phenyl group, a tolyl group, a xylyl group, a naphthyl group, and an anthryl group; and aralkyl groups such as a benzyl group, a phenethyl group, and a naphthylmethyl group.

The heterocyclic ring having 3 to 20 ring members represented by the combined R² and R³ together with the nitrogen atom to which the combined R² and R³ are bonded may be either saturated or unsaturated and examples thereof include an aziridine ring, an azirine ring, a diaziridine ring, an azetidine ring, a diazetidine ring, a pyrrolidine ring, a pyrrole ring, an imidazolidine ring, a pyrazolidine ring, an imidazole ring, a pyrazole ring, an oxazolidine ring, an oxazole ring, an isoxazole ring, a thiazolidine ring, an isothiazole ring, a piperidine ring, a pyridine ring, a piperazine ring, a diazine ring, a morpholine ring, an oxazine ring, a thiomorpholine ring, an azepane ring, an azepine ring, an indole ring, a benzimidazole ring, a benzotriazole ring, a quinoline ring, an isoquinoline ring, an acridine ring, and a carbazole ring.

Some or all of the hydrogen atoms of the heterocyclic ring may be replaced by a substituent. Examples of the substituent include halogen atoms such as a fluorine atom, a chlorine atom, a bromine atom, and an iodine atom; a hydroxy group; a carboxy group; a cyano group; a nitro group; an alkyl group, an alkoxy group, an alkoxycarbonyl group, an alkoxycarbonyloxy group, an acyl group, an acyloxy group, or a group in which a hydrogen atom of these groups has been replaced by a halogen atom; a hydroxyalkyl group; and an oxo group (═O).

Examples of the compound represented by the formula (1) include compounds represented by the following formulas (1-1) to (1-50).

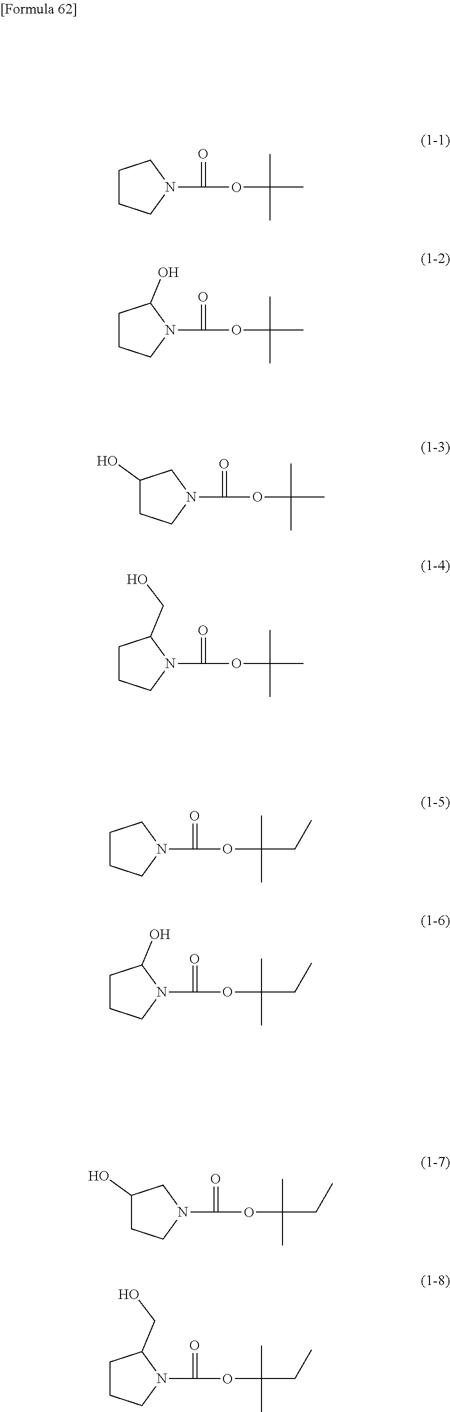

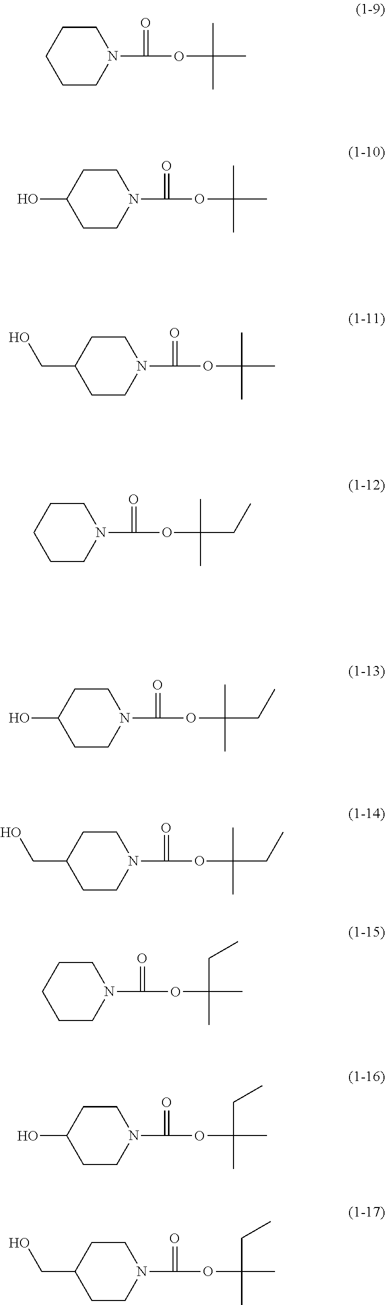

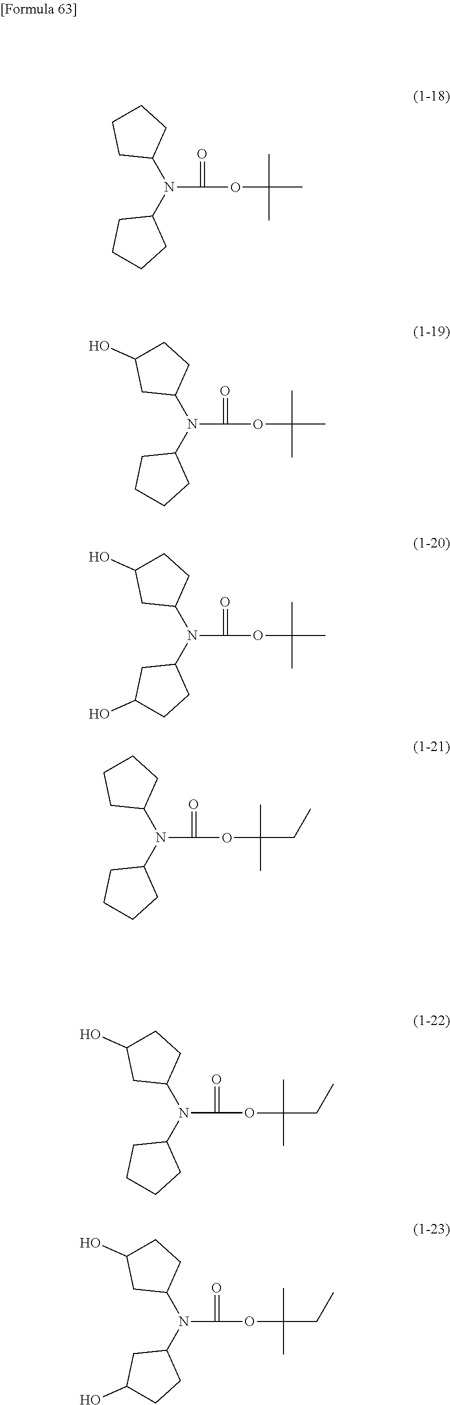

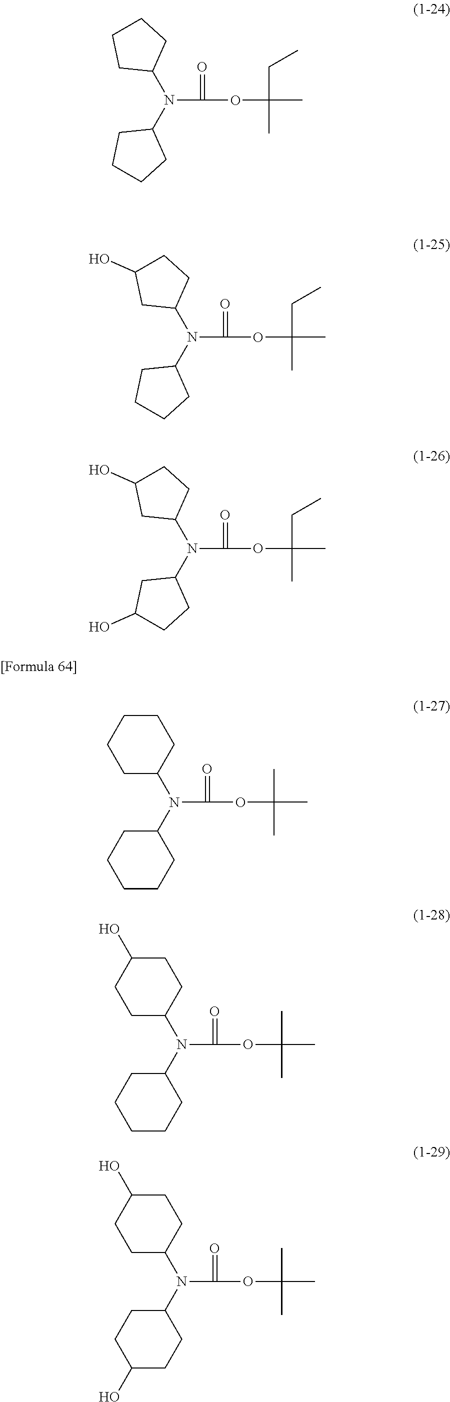

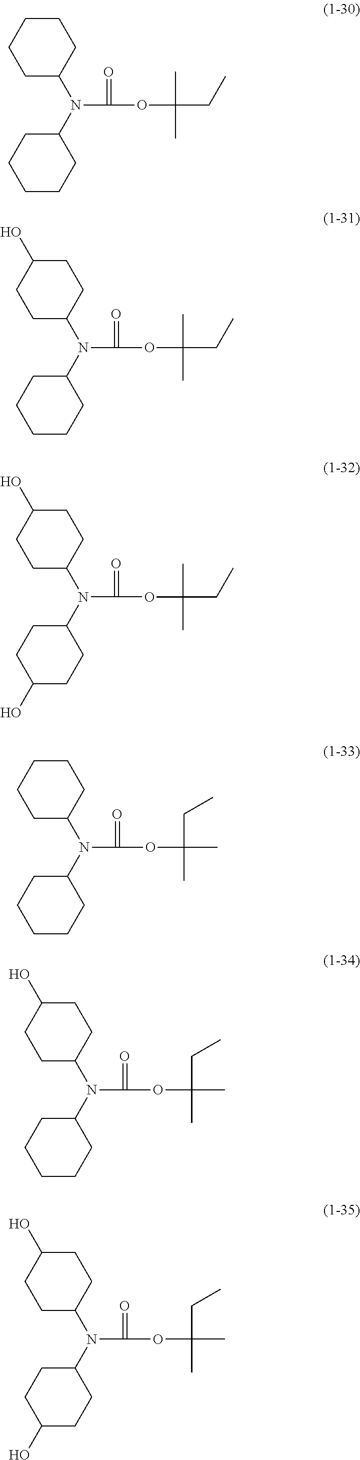

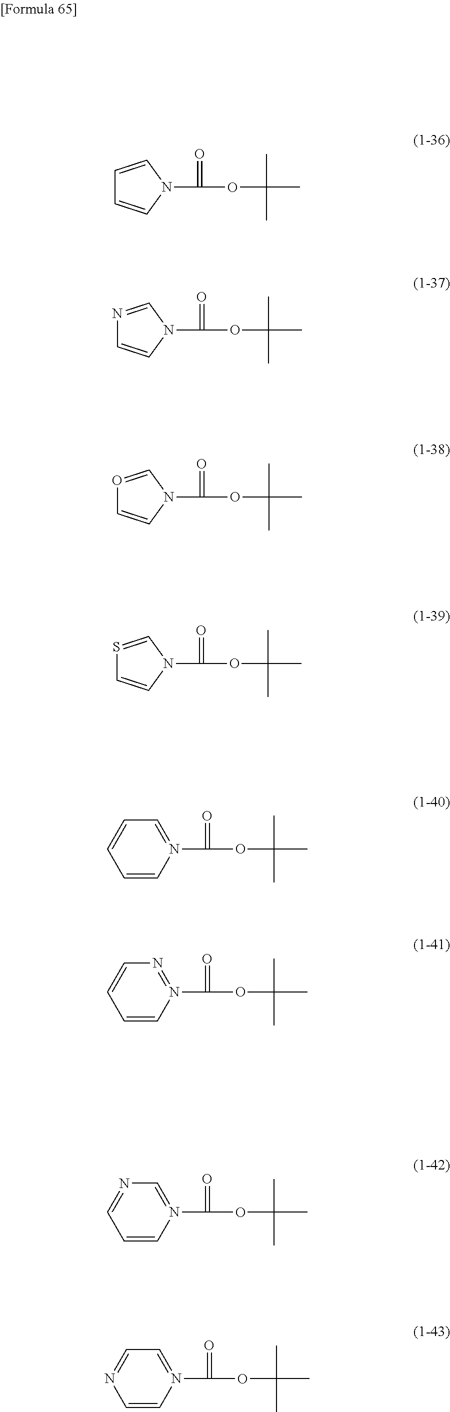

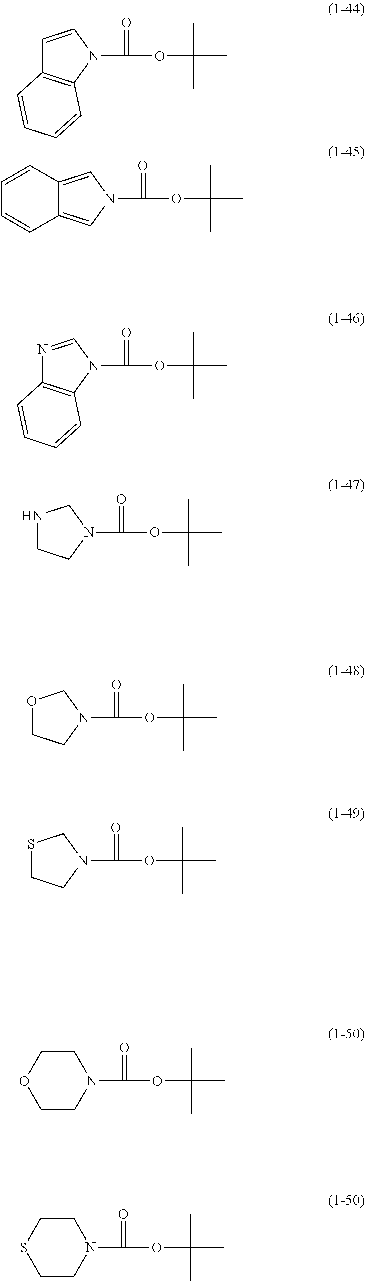

The content of the compound is preferably 5% by mass or more, more preferably 7% by mass or more, and still more preferably 10% by mass or more based on the content of the radiation-sensitive acid generator (when a radiation-sensitive acid generating resin is contained, the total amount with the content of the structural units a1 and a2 in 100 parts by mass of the radiation-sensitive acid generating resin is taken as the basis). The content is preferably 50 mass % or less, more preferably 40 mass % or less, and still more preferably 30 mass % or less. When the content of the compound is adjusted to within the above range, appropriate acid diffusion controllability is obtained, and CDU performance can be improved.

<Solvent>

The radiation-sensitive resin composition according to the present embodiment contains a solvent. The solvent is not particularly limited as long as it can dissolve or disperse the onium salt, the base resin (at least one of the radiation-sensitive acid generating resin and the resin), and an additive or the like contained if necessary.

Examples of the solvent include an alcohol-based solvent, an ether-based solvent, a ketone-based solvent, an amide-based solvent, an ester-based solvent, and a hydrocarbon-based solvent.

Examples of the alcohol-based solvent include:
a monoalcohol-based solvent having a carbon number of 1 to 18, including iso-propanol, 4-methyl-2-pentanol, 3-methoxybutanol, n-hexanol, 2-ethylhexanol, furfuryl alcohol, cyclohexanol, 3,3,5-trimethylcyclohexanol, and diacetone alcohol;
a polyhydric alcohol having a carbon number of 2 to 18, including ethylene glycol, 1,2-propylene glycol, 2-methyl-2,4-pentanediol, 2,5-hexanediol, diethylene glycol, dipropylene glycol, triethylene glycol, and tripropylene glycol; and
a partially etherized polyhydric alcohol-based solvent in which a part of hydroxy groups in the polyhydric alcohol-based solvent is etherized.

Examples of the ether-based solvent include:
a dialkyl ether-based solvent, including diethyl ether, dipropyl ether, and dibutyl ether;
a cyclic ether-based solvent, including tetrahydrofuran and tetrahydropyran;
an ether-based solvent having an aromatic ring, including diphenylether and anisole (methyl phenyl ether); and
an etherized polyhydric alcohol-based solvent in which a hydroxy group in the polyhydric alcohol-based solvent is etherized.

Examples of the ketone-based solvent include:
a chain ketone-based solvent, including acetone, butanone, and methyl-iso-butyl ketone;
a cyclic ketone-based solvent, including cyclopentanone, cyclohexanone, and methylcyclohexanone; and
2,4-pentanedione, acetonylacetone, and acetophenone.

Examples of the amide-based solvent include:
a cyclic amide-based solvent, including N,N′-dimethyl imidazolidinone and N-methylpyrrolidone; and
a chain amide-based solvent, including N-methylformamide, N,N-dimethylformamide, N,N-diethylformamide, acetamide, N-methylacetamide, N,N-dimethylacetamide, and N-methylpropionamide.

Examples of the ester-based solvent include:
a monocarboxylate ester-based solvent, including n-butyl acetate and ethyl lactate;
a partially etherized polyhydric alcohol acetate-based solvent, including diethylene glycol mono-n-butyl ether acetate, propylene glycol monomethyl ether acetate, and dipropylene glycol monomethyl ether acetate;
a lactone-based solvent, including y-butyrolactone and valerolactone;
a carbonate-based solvent, including diethyl carbonate, ethylene carbonate, and propylene carbonate; and
a polyhydric carboxylic acid diester-based solvent, including propylene glycol diacetate, methoxy triglycol acetate, diethyl oxalate, ethyl acetoacetate, ethyl lactate, and diethyl phthalate.

Examples of the hydrocarbon-based solvent include:
an aliphatic hydrocarbon-based solvent, including n-hexane, cyclohexane, and methylcyclohexane;
an aromatic hydrocarbon-based solvent, including benzene, toluene, di-iso-propylbenzene, and n-amylnaphthalene.

Among them, the ester-based solvent or the ketone-based solvent is preferred. The partially etherized polyhydric alcohol acetate-based solvent, the cyclic ketone-based solvent, or the lactone-based solvent is more preferred. Propylene glycol monomethyl ether acetate, cyclohexanone, or γ-butyrolactone is still more preferred. The radiation-sensitive resin composition may include one type of the solvent, or two or more types of the solvents in combination.

<Other Optional Components>

The radiation-sensitive resin composition may contain other optional components other than the above-descried components. Examples of other optional components include a cross-linking agent, a localization enhancing agent, a surfactant, an alicyclic backbone-containing compound, and a sensitizer. These other optional components may be used singly or in combination of two or more of them.

<Method for Preparing Radiation-Sensitive Resin Composition>

The radiation-sensitive resin composition can be prepared by, for example, mixing the compound (1), the resin, the radiation-sensitive acid generator, and optionally the high fluorine-content resin, as well as the solvent added in a predetermined ratio. The radiation-sensitive resin composition is preferably filtered through, for example, a filter having a pore diameter of about 0.05 μm to 0.20 μm after mixing. The solid matter concentration of the radiation-sensitive resin composition is usually 0.1 mass % to 50 mass %, preferably 0.5 mass % to 30 mass %, more preferably 1 mass % to 20 mass %.

### <Method for Forming Pattern>

A pattern forming method according to an embodiment of the present invention includes:
a step (1) of applying the radiation-sensitive resin composition directly or indirectly on a substrate to form a resist film (hereinafter, also referred to as a “resist film forming step”);
a step (2) of exposing the resist film (hereinafter, also referred to as an “exposure step”); and
a step (3) of developing the exposed resist film (hereinafter, also referred to as a “developing step”).

The method for forming a pattern uses the above-described radiation-sensitive resin composition excellent in sensitivity in the exposure step, LWR performance, and CDU performance, and therefore a high-quality resist pattern can be formed. Hereinbelow, each of the steps will be described.

[Resist Film Forming Step]

In this step (the above mentioned step (1)), a resist film is formed with the radiation-sensitive resin composition. Examples of the substrate on which the resist film is formed include one traditionally known in the art, including a silicon wafer, silicon dioxide, and a wafer coated with aluminum. An organic or inorganic antireflection film may be formed on the substrate, as disclosed in JP-B-06-12452 and JP-A-59-93448. Examples of the applicating method include a rotary coating (spin coating), flow casting, and roll coating. After applicating, a prebake (PB) may be carried out in order to evaporate the solvent in the film, if needed. The temperature of PB is typically from 60° C. to 140° C., and preferably from 80° C. to 120° C. The duration of PB is typically from 5 seconds to 600 seconds, and preferably from 10 seconds to 300 seconds. The thickness of the resist film formed is preferably from 10 nm to 1,000 nm, and more preferably from 10 nm to 500 nm.

When the immersion exposure is carried out, irrespective of presence of a water repellent polymer additive such as the high fluorine-content resin in the radiation-sensitive resin composition, the formed resist film may have a protective film for the immersion which is not soluble into the immersion liquid on the film in order to prevent a direct contact between the immersion liquid and the resist film. As the protective film for the immersion, a solvent-removable protective film that is removed with a solvent before the developing step (for example, see JP-A-2006-227632); or a developer-removable protective film that is removed during the development of the developing step (for example, see WO2005-069076 and WO2006-035790) may be used. In terms of the throughput, the developer-removable protective film is preferably used.

When the next step, the exposure step, is performed with radiation having a wavelength of 50 nm or less, it is preferable to use, as the base resin in the composition, a resin having the structural units b1, b2, the structural unit c, and, if necessary, the structural unit d.

[Exposing Step]

In this step (the above mentioned step (2)), the resist film formed in the resist film forming step as the step (1) is exposed by irradiating with a radioactive ray through a photomask (optionally through an immersion medium such as water). Examples of the radioactive ray used for the exposure include visible ray, ultraviolet ray, far ultraviolet ray, extreme ultraviolet ray (EUV); an electromagnetic wave including X ray and y ray; an electron beam; and a charged particle radiation such as a ray. Among them, far ultraviolet ray, an electron beam, or EUV is preferred. ArF excimer laser light (wavelength is 193 nm), KrF excimer laser light (wavelength is 248 nm), an electron beam, or EUV is more preferred. An electron beam or EUV having a wavelength of 50 nm or less which is identified as the next generation exposing technology is further preferred.

When the exposure is carried out by immersion exposure, examples of the immersion liquid include water and fluorine-based inert liquid. The immersion liquid is preferably a liquid which is transparent with respect to the exposing wavelength, and has a minimum temperature factor of the refractive index so that the distortion of the light image reflected on the film becomes minimum. However, when the exposing light source is ArF excimer laser light (wavelength is 193 nm), water is preferably used because of the ease of availability and ease of handling in addition to the above considerations. When water is used, a small proportion of an additive that decreases the surface tension of water and increases the surface activity may be added. Preferably, the additive cannot dissolve the resist film on the wafer and can neglect an influence on an optical coating at an under surface of a lens. The water used is preferably distilled water.

After the exposure, post exposure bake (PEB) is preferably carried out to promote the dissociation of the acid-dissociable group in the resin by the acid generated from the radiation-sensitive acid generator with the exposure in the exposed part of the resist film. The difference of solubility into the developer between the exposed part and the non-exposed part is generated by the PEB. The temperature of PEB is typically from 50° C. to 180° C., and preferably from 80° C. to 130° C. The duration of PEB is typically from 5 seconds to 600 seconds, and preferably from 10 seconds to 300 seconds.

[Developing Step]

In this step (the above mentioned step (3)), the resist film exposed in the exposing step as the step (2) is developed. By this step, the predetermined resist pattern can be formed. After the development, the resist pattern is washed with a rinse solution such as water or alcohol, and the dried, in general.

Examples of the developer used for the development include, in the alkaline development, an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, 1,5-diazabicyclo-[4.3.0]-5-nonene. Among them, an aqueous TMAH solution is preferred, and 2.38% by mass of aqueous TMAH solution is more preferred.

In the case of the development with organic solvent, examples of the solvent include an organic solvent, including a hydrocarbon-based solvent, an ether-based solvent, an ester-based solvent, a ketone-based solvent, and an alcohol-based solvent; and a solvent containing an organic solvent. Examples of the organic solvent include one, two or more solvents listed as the solvent for the radiation-sensitive resin composition. Among them, an ester-based solvent or a ketone-based solvent is preferred. The ester-based solvent is preferably an acetate ester-based solvent, and more preferably n-butyl acetate or amyl acetate. The ketone-based solvent is preferably a chain ketone, and more preferably 2-heptanone. The content of the organic solvent in the developer is preferably not less than 80% by mass, more preferably not less than 90% by mass, further preferably not less than 95% by mass, and particularly preferably not less than 99% by mass. Examples of the ingredient other than the organic solvent in the developer include water and silicone oil.

Examples of the developing method include a method of dipping the substrate in a tank filled with the developer for a given time (dip method); a method of developing by putting and leaving the developer on the surface of the substrate with the surface tension for a given time (paddle method); a method of spraying the developer on the surface of the substrate (spray method); and a method of injecting the developer while scanning an injection nozzle for the developer at a constant rate on the substrate rolling at a constant rate (dynamic dispense method).

### EXAMPLES

Hereinafter, the present invention will be specifically described with reference to Examples, but the present invention is not limited to these Examples. Methods for measuring various physical property values will be described below.

The structures 1 to 15 of the onium salts as the radiation-sensitive acid generator (PAG) used in the radiation-sensitive resin compositions are shown below (hereinafter, the onium salts are each also referred to as “PAG1” and the like). PAG 1 to 15 were each synthesized by ion exchange between an ammonium salt of an iodinated aromatic ring structure-containing fluorinated sulfonic acid that is to afford the organic acid anion moiety shown below and sulfonium chloride or iodonium chloride that is to afford the onium cation moiety shown below.

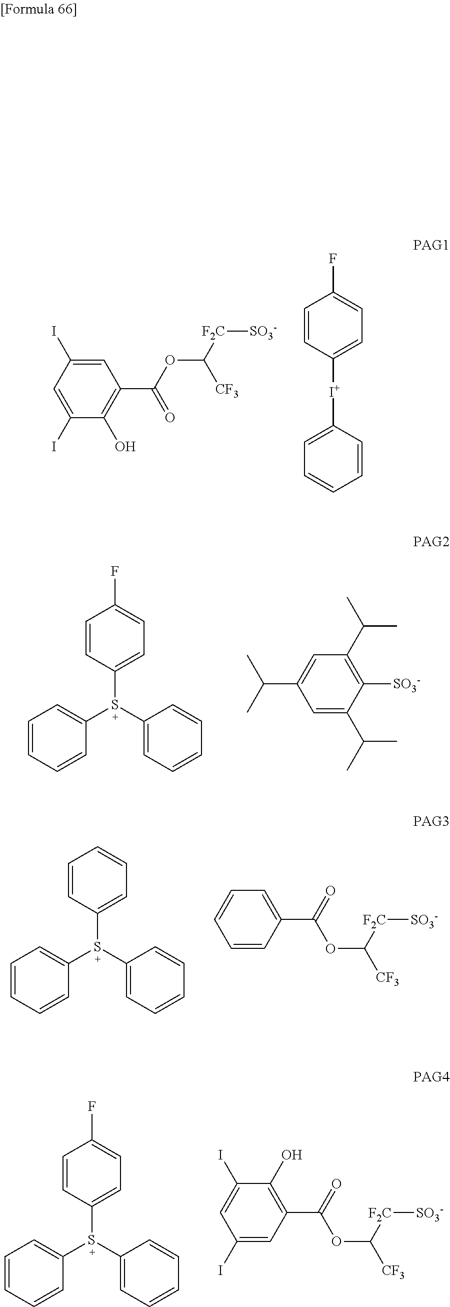

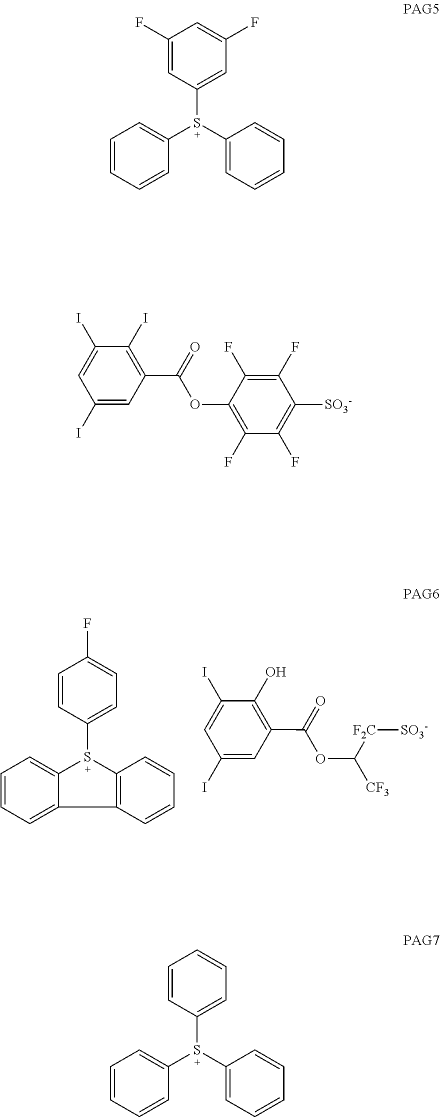

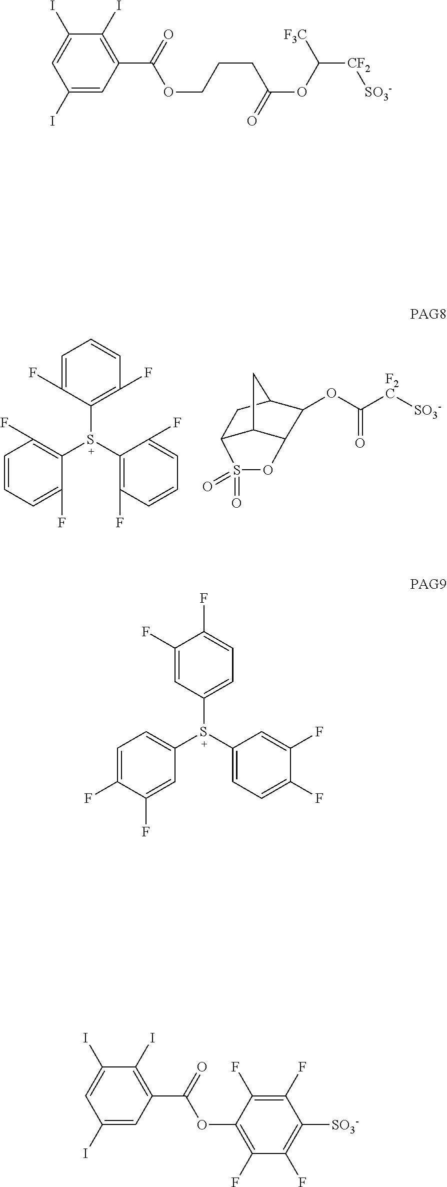

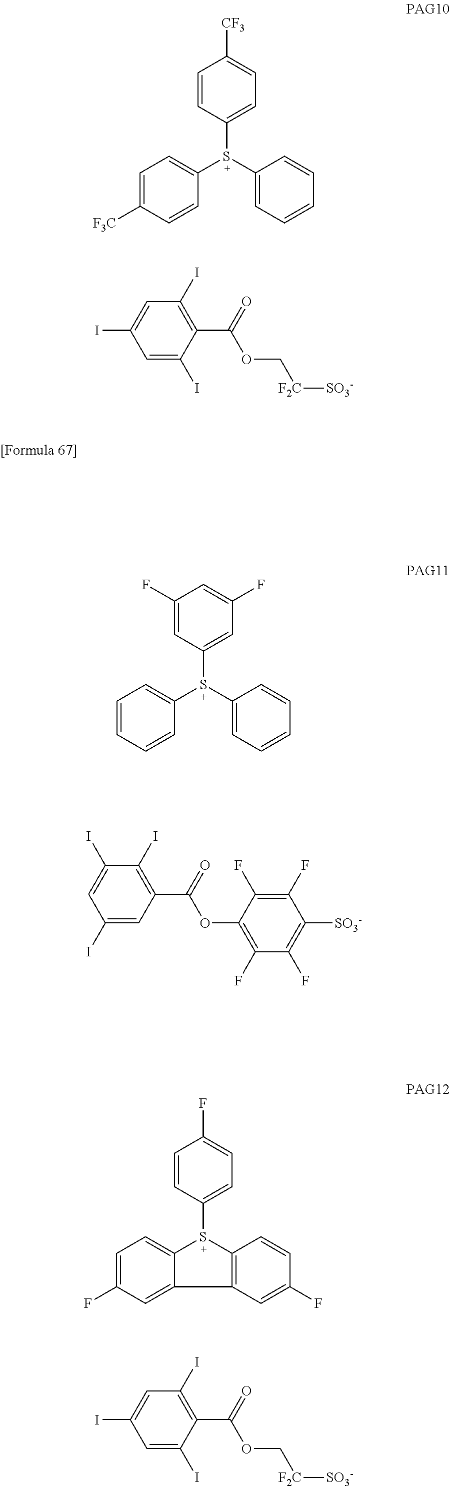

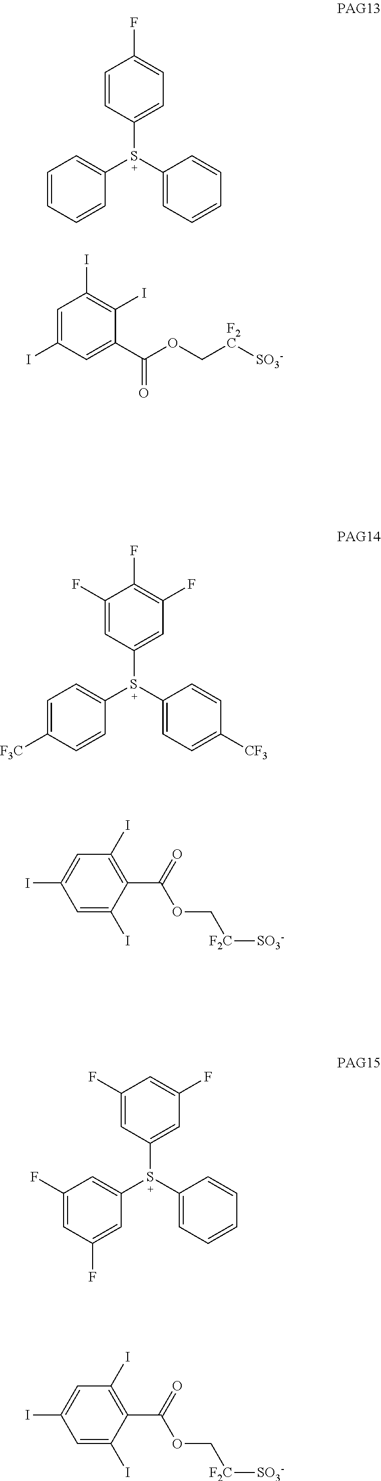

### [Synthesis Example] Synthesis of Base Resins (P-1 to P-7)

The respective monomers were combined and subjected to a copolymerization reaction in a tetrahydrofuran (THF) solvent, and the reaction products were crystallized in methanol, and washed repeatedly with hexane, then isolated, and dried. Thus, P-1 to P-7 as the base polymers having the compositions shown below were obtained. The composition of the obtained base polymers was confirmed by ¹H-NMR, and the Mw and the dispersion degree (Mw/Mn) were confirmed by GPC (solvent: THF, standard: polystyrene). In the following formulas, the number attached to each structural unit is the content of the structural unit (molar ratio; the sum total is 1).
P-1: Mw=7,600, Mw/Mn=1.7
P-2: Mw=7,600, Mw/Mn=1.7
P-3: Mw=8,600, Mw/Mn=1.7
P-4: Mw=9,300, Mw/Mn=1.8
P-5: Mw=8,000, Mw/Mn=1.7
P-6: Mw=7,600, Mw/Mn=1.7
P-7: Mw=7,600, Mw/Mn=1.7

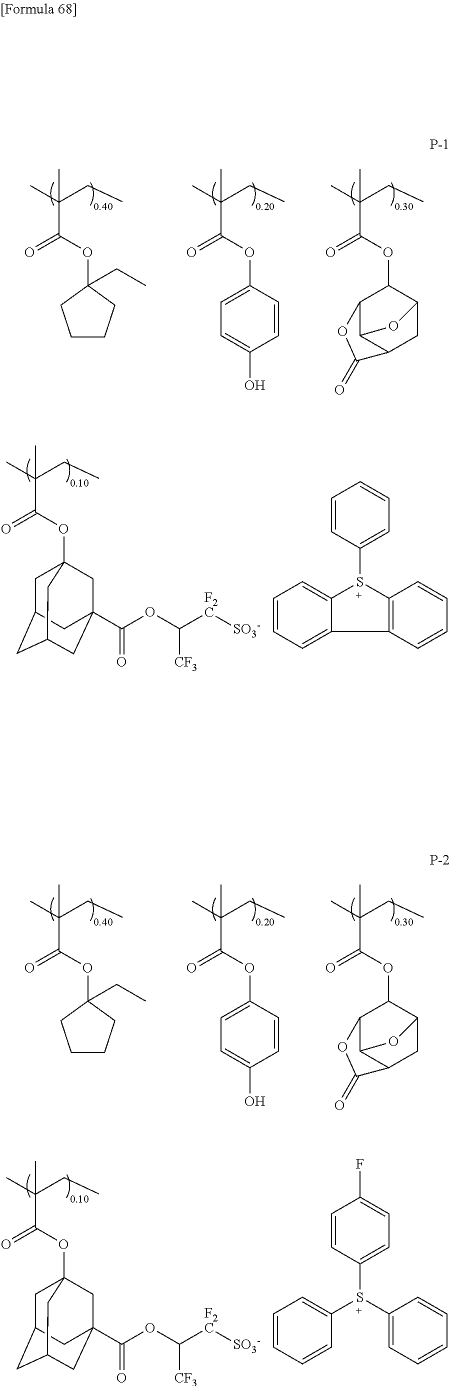

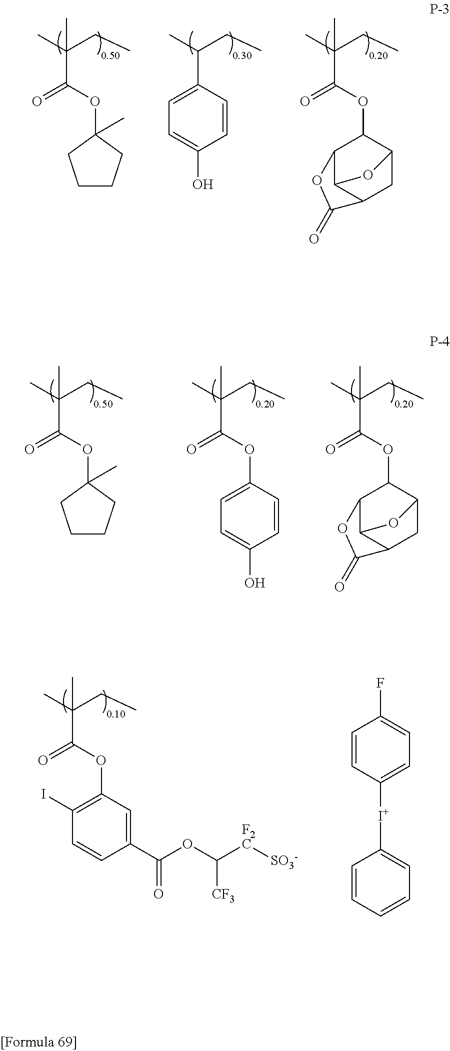

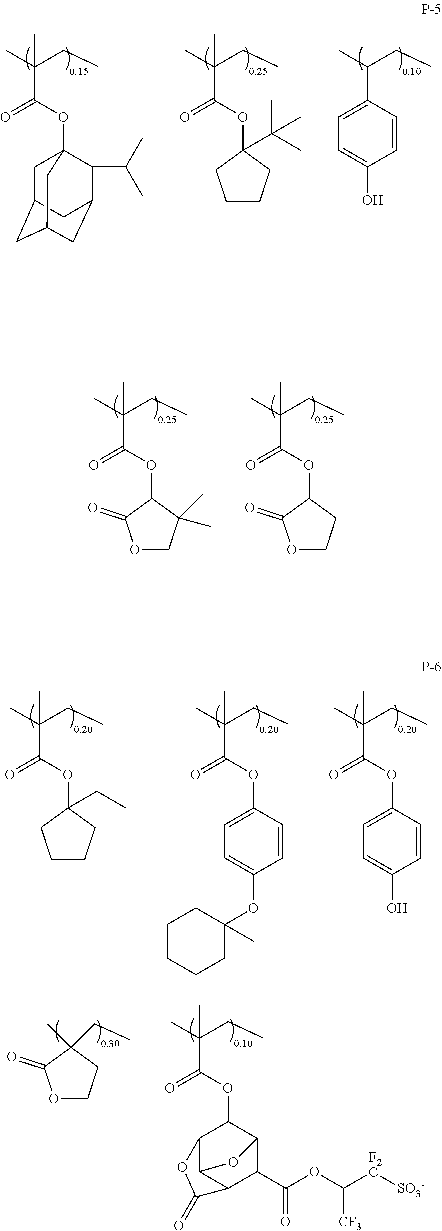

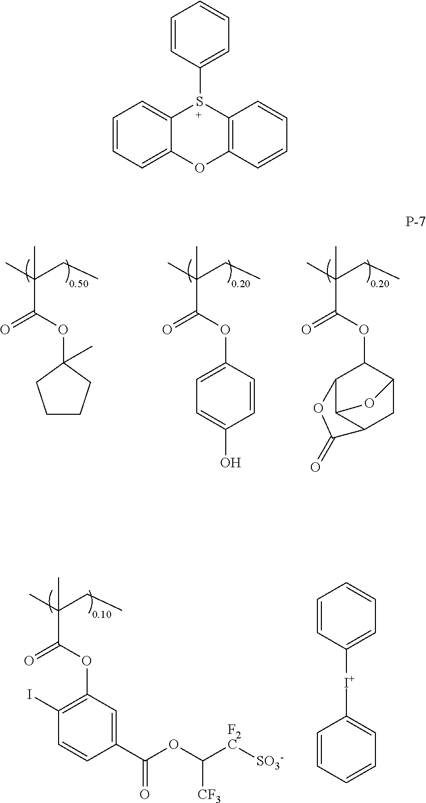

### Examples and Comparative Examples

A radiation-sensitive resin composition was prepared by filtering a solution obtained by dissolving components in the composition given in Table 1 in a solvent obtained by dissolving 100 ppm of FC-4430 manufactured by 3M as a surfactant through a 0.2 μm-sized filter. In Table 1, the components are as follows.

Organic solvent:
PGMEA (propylene glycol monomethyl ether acetate)
GBL (y-butyrolactone)
CHN (cyclohexanone)
PGME (propylene glycol monomethyl ether)
DAA (diacetone alcohol)
Acid diffusion controlling agents Q-1 to Q-11

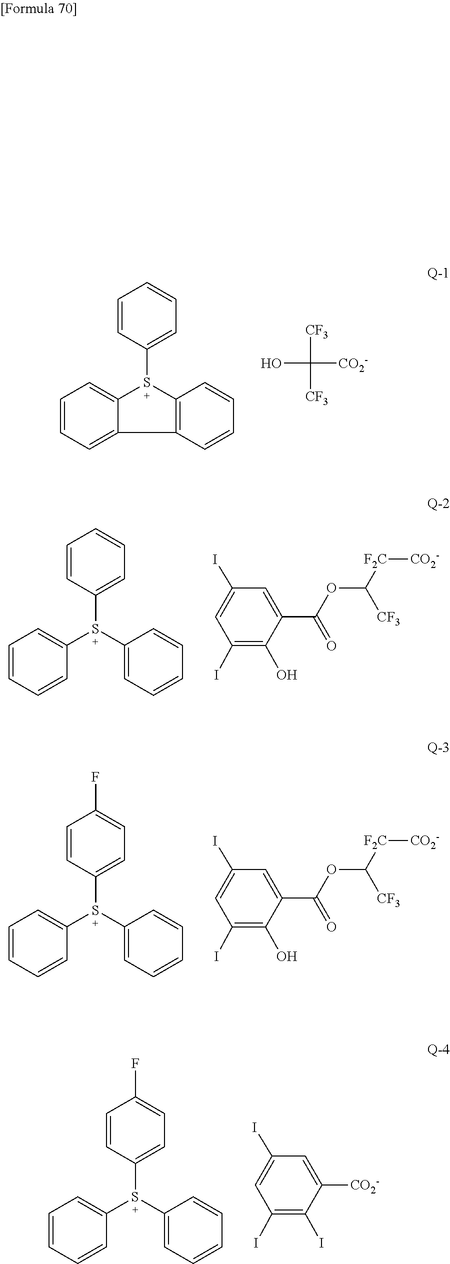

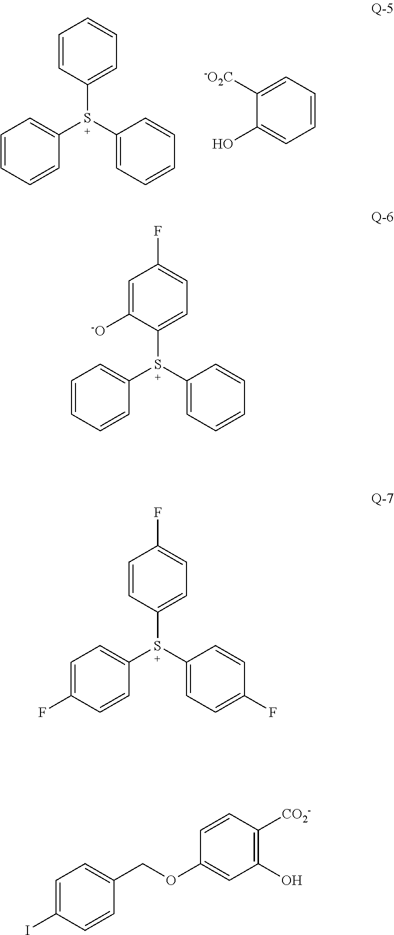

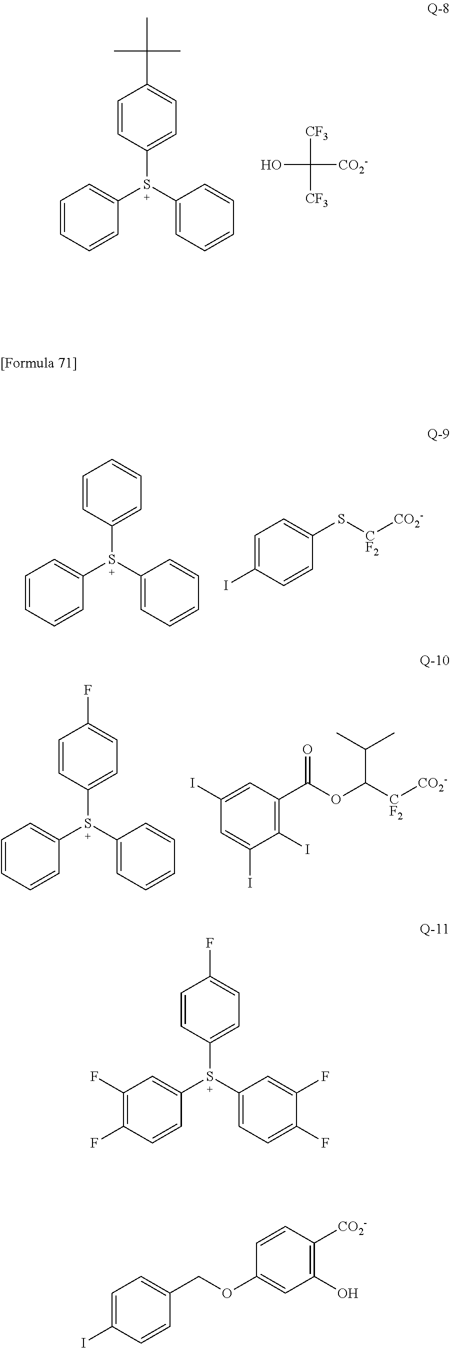

Compounds B-1 to B-7

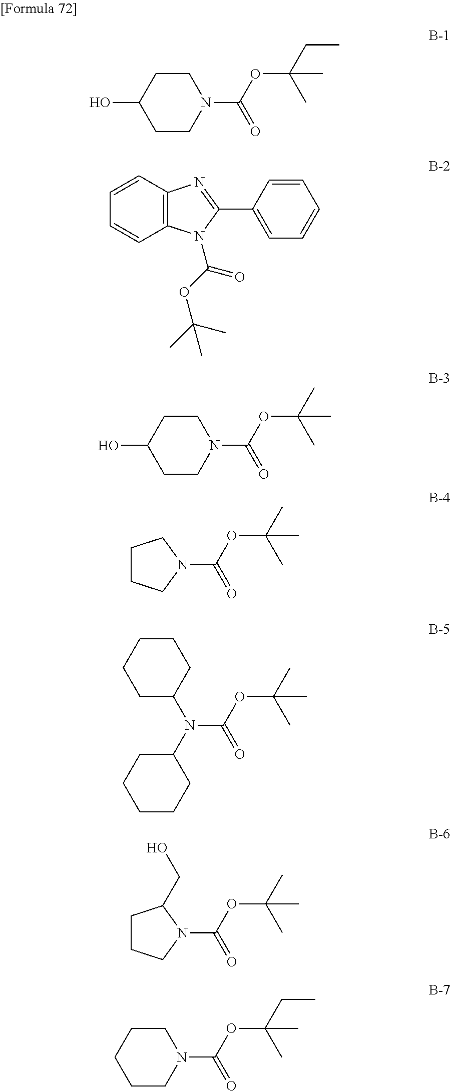

High fluorine-containing resin F-1: Mw=8,900, Mw/Mn=2.0

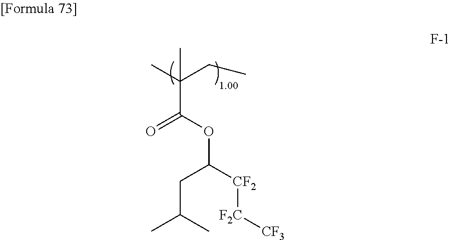

### [EUV Exposure Evaluation]

### Examples 1 to 17 and Comparative Examples 1 to 7

Each of the radiation-sensitive resin compositions shown in Table 1 was spin-coated on a Si substrate on which a film having a thickness of 20 nm was formed from a silicon-containing spin-on hard mask SHB-A940 (silicon content: 43 mass %) manufactured by Shin-Etsu Chemical Co., Ltd. Prebaking was carried out at 105° C. for 60 seconds using a hot plate to prepare a resist film having a thickness of 60 nm. This was exposed to light using an EUV scanner NXE3300 (NA 0.33, σquadrupole illumination, hole pattern mask with a pitch of 46 nm on wafer and a bias of +20%) manufactured by ASML. PEB was carried out on a hot plate at 100° C. for 60 seconds. Development was carried out with a 2.38 mass % aqueous TMAH solution for 30 seconds, affording a hole pattern having a dimension of 23 nm. The exposure dose applied when a pattern was formed with a hole dimension of 23 nm was measured and taken as sensitivity. In addition, dimensions of 50 holes were measured using a critical dimension-SEM (CG5000) manufactured by Hitachi High-Technologies Corporation to determine CDU (dimensional variation 36). The results are shown in Table 1.

TABLE 1

| | | | Acid diffusion | | | | | |
|---|---|---|---|---|---|---|---|---|
| | | | controlling | | | | | |
| | Base resin | PAG | agent | Compound | | Additive | | |
| | (parts by | (parts by | (parts by | (parts by | Solvent | (parts by | Sensitivity | CDU |
| | mass) | mass) | mass) | mass) | (parts by mass) | mass) | (mJ/cm²) | (nm) |
| Example 1 | P-1 | PAG1 | Q-1 | B-1 | PGMEA/DAA | — | 14 | 2.4 |
| | (100) | (8.0) | (4.0) | (2.0) | (2,000/500) | | | |
| Example 2 | P-1 | PAG2 | Q-2 | B-1 | PGMEA/DAA | — | 14 | 2.4 |
| | (100) | (8.0) | (4.0) | (2.0) | (2,000/500) | | | |
| Example 3 | P-1 | PAG3 | Q-3 | B-1 | PGMEA/DAA | — | 14 | 2.4 |
| | (100) | (8.0) | (4.0) | (2.0) | (2,000/500) | | | |
| Example 4 | P-2 | PAG3 | Q-2 | B-1 | PGMEA/DAA | — | 14 | 2.4 |
| | (100) | (8.0) | (4.0) | (2.0) | (2,000/500) | | | |
| Example 5 | P-3 | PAG4 | Q-4 | B-2 | PGMEA/DAA | — | 13 | 2.2 |
| | (100) | (10.0) | (5.0) | (3.0) | (2,000/500) | | | |
| Example 6 | P-3 | PAG5 | Q-5 | B-3 | PGMEA/DAA | — | 13 | 2.4 |
| | (100) | (10.0) | (5.0) | (3.0) | (2,000/500) | | | |
| Example 7 | P-3 | PAG6 | Q-5 | B-3 | PGMEA/DAA | — | 13 | 2.4 |
| | (100) | (10.0) | (5.0) | (3.0) | (2,000/500) | | | |
| Example 8 | P-3 | PAG7 | Q-6 | B-3 | PGMEA/DAA | — | 14 | 2.5 |
| | (100) | (10.0) | (5.0) | (3.0) | (2,000/500) | | | |
| Example 9 | P-7 | PAG8 | Q-5 | B-3 | PGMEA/DAA | — | 12 | 2.4 |
| | (100) | (8.0) | (5.0) | (3.0) | (2,000/500) | | | |
| Example 10 | P-1 | PAG9 | Q-7 | B-4 | PGMEA/DAA | — | 12 | 2.3 |
| | (100) | (8.0) | (4.0) | (2.0) | (2,000/500) | | | |
| Example 11 | P-4 | — | Q-1 | B-5 | PGMEA/DAA | — | 24 | 2.0 |
| | (100) | | (5.0) | (3.0) | (2,000/500) | | | |
| Example 12 | P-4 | PAG10 | Q-7 | B-5 | PGMEA/DAA | — | 23 | 2.0 |
| | (100) | (8.0) | (4.0) | (2.0) | (2,000/500) | | | |
| Example 13 | P-5 | PAG11 | Q-8 | B-6 | PGMEA/GBL | F-1 | 27 | 2.3 |
| | (100) | (10.0) | (5.0) | (3.0) | (2,200/300) | (3.0) | | |
| Example 14 | P-5 | PAG12 | Q-9 | B-6 | PGMEA/GBL | F-1 | 25 | 2.3 |
| | (100) | (10.0) | (5.0) | (3.0) | (2,200/300) | (3.0) | | |
| Example 15 | P-6 | PAG13 | Q-10 | B-7 | PGMEA/CHN/PGME | — | 14 | 2.3 |
| | (100) | (8.0) | (4.0) | (2.0) | (400/2,000/100) | | | |
| Example 16 | P-6 | PAG14 | Q-11 | B-7 | PGMEA/CHN/PGME | — | 13 | 2.3 |
| | (100) | (8.0) | (4.0) | (2.0) | (400/2,000/100) | | | |
| Example 17 | P-6 | PAG15 | Q-10 | B-7 | PGMEA/CHN/PGME | — | 13 | 2.3 |
| | (100) | (8.0) | (4.0) | (2.0) | (400/2,000/100) | | | |
| Comparative | P-1 | PAG1 | Q-1 | — | PGMEA/DAA | — | 14 | 2.6 |
| Example 1 | (100) | (8.0) | (4.0) | | (2,000/500) | | | |
| Comparative | P-4 | — | Q-1 | — | PGMEA/DAA | — | 24 | 2.2 |
| Example 2 | (100) | | (5.0) | | (2,000/500) | | | |
| Comparative | P-5 | PAG11 | Q-8 | — | PGMEA/GBL | F-1 | 27 | 2.5 |
| Example 3 | (100) | (10.0) | (5.0) | | (2,200/300) | (3.0) | | |
| Comparative | P-6 | PAG13 | Q-10 | — | PGMEA/CHN/PGME | — | 14 | 2.5 |
| Example 4 | (100) | (8.0) | (4.0) | | (400/2,000/100) | | | |
| Comparative | P-1 | PAG2 | Q-1 | B-1 | PGMEA/DAA | — | 14 | 2.5 |
| Example 5 | (100) | (8.0) | (4.0) | (2.0) | (2,000/500) | | | |
| Comparative | P-1 | PAG7 | Q-1 | B-1 | PGMEA/DAA | — | 16 | 2.4 |
| Example 6 | (100) | (8.0) | (4.0) | (2.0) | (2,000/500) | | | |
| Comparative | P-1 | — | Q-1 | B-1 | PGMEA/DAA | — | 17 | 2.4 |
| Example 7 | (100) | | (5.0) | (3.0) | (2,000/500) | | | |

The evaluation conducted for the resist patterns formed through the EUV exposure revealed that the radiation-sensitive resin compositions of Examples had good sensitivity and CDU performance.

### INDUSTRIAL APPLICABILITY

According to the radiation-sensitive resin composition and the method for forming a resist pattern described above, a resist pattern having good sensitivity to exposure light and superior CDU performance can be formed. Therefore, these can be suitably used for a machining process and the like of a semiconductor device in which micronization is expected to further progress in the future.

1. A radiation-sensitive resin composition comprising:
one or more onium salts each comprising an organic acid anion moiety and an onium cation moiety;
a compound having a structure in which an alkoxycarbonyl group is bonded to a nitrogen atom; and
a solvent;
wherein at least part of the organic acid anion moiety in the onium salt comprises an iodine-substituted aromatic ring structure, and at least part of the onium cation moiety comprises a fluorine-substituted aromatic ring structure.

2. The radiation-sensitive resin composition according to claim 1, wherein
the onium salt is at least one selected from the group consisting of:
a radiation-sensitive acid generating resin comprising a structural unit which comprises the organic acid anion moiety and the onium cation moiety,
a radiation-sensitive acid generator comprising the organic acid anion moiety and the onium cation moiety; and
an acid diffusion controlling agent comprising the organic acid anion moiety and the onium cation moiety.

3. The radiation-sensitive resin composition according to claim 2, wherein the radiation-sensitive acid generating resin further comprises a structural unit comprising a phenolic hydroxy group and a structural unit comprising an acid-dis sociable group.

4. The radiation-sensitive resin composition according to claim 2, wherein when the onium salt is at least one selected from the group consisting of the radiation-sensitive acid generator and the acid diffusion controlling agent, the radiation-sensitive resin composition further comprises a resin comprising a structural unit which comprises a phenolic hydroxy group and a structural unit which comprises an acid-dis sociable group.

5. The radiation-sensitive resin composition according to claim 2, wherein
the organic acid anion moiety in at least one selected from the group consisting of the radiation-sensitive acid generating resin, the radiation-sensitive acid generator, and the acid diffusion controlling agent comprises the iodine-substituted aromatic ring structure, and
the onium cation moiety in at least one selected from the group consisting of the radiation-sensitive acid generating resin, the radiation-sensitive acid generator, and the acid diffusion controlling agent comprises the fluorine-substituted aromatic ring structure.

6. The radiation-sensitive resin composition according to claim 1, wherein the organic acid anion moiety comprises at least one anion selected from the group consisting of a sulfonate anion, a carboxylate anion, and a sulfonimide anion.

7. The radiation-sensitive resin composition according to claim 1, wherein the onium cation is at least one selected from the group consisting of a sulfonium cation and an iodonium cation.

8. The radiation-sensitive resin composition according to claim 2, wherein
the organic acid anion moiety in a case where the onium salt is at least one selected from the group consisting of the radiation-sensitive acid generating resin and the radiation-sensitive acid generator comprises a sulfonate anion, and
a fluorine atom or a fluorinated hydrocarbon group is bonded to a carbon atom adjacent to the sulfonate anion.

9. The radiation-sensitive resin composition according to claim 2, wherein the organic anion moiety of the acid diffusion controlling agent comprises a sulfonate anion or a carboxylate anion, provided that when the organic acid anion comprises the sulfonate anion, neither a fluorine atom nor a fluorinated hydrocarbon group is bonded to a carbon atom adjacent to the sulfonate anion.

10. The radiation-sensitive resin composition according to claim 1, wherein
the compound is represented by the following formula (1): 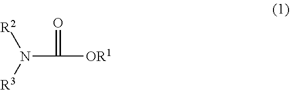
wherein, in the formula (1),
R¹ is a branched alkyl group having 4 to 20 carbon atoms;
R² and R³ are each independently a hydrocarbon group having 1 to 20 carbon atoms, or R² and R³ are taken together represent a heterocyclic ring having 3 to 20 ring members together with the nitrogen atom to which they are bonded.

11. A method for forming a pattern, comprising:
directly or indirectly applying the radiation-sensitive resin composition according to claim 1 to a substrate to form a resist film;
exposing the resist film to light; and
developing the exposed resist film with a developer.

12. The method for forming a pattern according to claim 11, wherein the exposure is performed using an extreme ultraviolet ray or an electron beam.
